(19) United States
(12) Patent Application Publication
(10) Pub. No.: US 2022/0271072 A1
(43) Pub. Date: Aug. 25, 2022

(54) SOLID-STATE IMAGE PICKUP DEVICE, ELECTRONIC APPARATUS, AND METHOD FOR MANUFACTURING SOLID-STATE IMAGE PICKUP DEVICE

(71) Applicant: SONY SEMICONDUCTOR SOLUTIONS CORPORATION, KANAGAWA (JP)

(72) Inventor: SATOE MIYATA, KANAGAWA (JP)

(21) Appl. No.: 17/627,388

(22) PCT Filed: Jun. 19, 2020
(86) PCT No.: PCT/JP2020/024129

§ 371 Date: Jan. 14, 2022

(30) Foreign Application Priority Data
Jul. 24, 2019 (JP) 2019-136277

(51) Int. Cl. H01L 27/146

(52) U.S. Cl. CPC H01L 27/14603; H01L 27/14621; H01L 27/14683; H01L 27/1463

(57) ABSTRACT

Provided are a solid-state image pickup device capable of improving heat dissipation property, and an electronic apparatus including the solid-state image pickup device. A solid-state image pickup device according to the present technology includes: at least one photoelectric converter formed in a semiconductor substrate; and a thermal conductive layer that is arranged on one surface side and/or another surface side of the semiconductor substrate and includes a material having a thermal conductivity higher than that of SiO₂. In the solid-state image pickup device according to the present technology, the heat generated, for example, in the at least one photoelectric converter is conveyed to the thermal conductive layer. At least a part of the heat transferred to the thermal conductive layer moves toward the end surface of the thermal conductive layer along the thermal conductive layer in the thermal conductive layer and is released from the end surface to the outside.

### TECHNICAL FIELD

A technology according to the present disclosure (hereinafter also referred to as “the present technology”) relates to a solid-state image pickup device, an electronic apparatus, and a method for manufacturing a solid-state image pickup device. More specifically, the present technology relates to a solid-state image pickup device and the like that images a subject.

### BACKGROUND ART

Patent Document 1 discloses a chemical sensor (solid-state image pickup device) including a photoelectric converter formed in a semiconductor substrate.

### CITATION LIST

### Patent Document

Patent Document 1: Japanese Patent Application Laid-open No. 2013-88378

### SUMMARY OF THE INVENTION

### Problems to be Solved by the Invention

In the chemical sensor disclosed in Patent Document 1, there is room for improvement for improvement of a heat dissipation property.

Thus, a main object of the present technology is to provide a solid-state image pickup device capable of improving a heat dissipation property, an electronic apparatus including the solid-state image pickup device, and a method for manufacturing the solid-state image pickup device.

### Solutions to Problems

The present technology provides a solid-state image pickup device including:

at least one photoelectric converter formed in a semiconductor substrate; and

a thermal conductive layer that is arranged on one surface side and/or another surface side of the semiconductor substrate and includes a material having a thermal conductivity higher than that of SiO₂.

In the solid-state image pickup device according to the present technology, the heat generated, for example, in the at least one photoelectric converter is conveyed to the thermal conductive layer. At least a part of the heat conveyed to the thermal conductive layer moves toward the end surface of the thermal conductive layer along the thermal conductive layer in the thermal conductive layer and is released from the end surface.

The thermal conductive layer can have a thermal conductivity that is equal to or higher than a thermal conductivity of Si.

The at least one photoelectric converter can have a PN junction.

The at least one photoelectric converter can have an electron multiplication region.

Light can be incident on the at least one photoelectric converter from the one surface side, and the thermal conductive layer can have a light transmission property and can be arranged on the one surface side.

The solid-state image pickup device according to the present technology further includes an insulating layer having a light transmission property on the one surface side, and at least a part of the insulating layer can be arranged between the semiconductor substrate and the thermal conductive layer.

The thermal conductive layer can include a material containing any one of indium tin oxide, SiN, Al₂O₃, ZnO—Al, AlN, SiC, fullerene, graphene, titanium oxide, MgO, and ZnO.

Light can be incident on the at least one photoelectric converter from the one surface side, and the solid-state image pickup device according to the present technology can further include a logic substrate that is arranged on the another surface side and includes another semiconductor substrate.

The thermal conductive layer can be arranged between the semiconductor substrate and the another semiconductor substrate.

In the solid-state image pickup device according to the present technology, an insulating layer can be arranged between the semiconductor substrate and the another semiconductor substrate, and the thermal conductive layer can be arranged in the insulating layer.

The thermal conductive layer can include a carbon nanomaterial or a material containing fullerene.

The thermal conductive layer can include a material containing graphene.

The thermal conductive layer can include a material containing any one of Ti, Sn, Pt, Fe, Ni, Zn, Mg, Si, W, Al, Au, Cu, and Ag.

The at least one photoelectric converter can include a plurality of photoelectric converters, and can include a partition wall that separates adjacent photoelectric converters of the plurality of photoelectric converters.

The partition wall can be in contact with the thermal conductive layer.

The partition wall can include a material containing a metal.

The partition wall can penetrate the thermal conductive layer.

A tip of the partition wall that penetrates the thermal conductive layer can be exposed to an outside.

The at least one photoelectric converter can include a plurality of photoelectric converters, and the thermal conductive layer can be provided to extend across at least two photoelectric converters of the plurality of photoelectric converters.

The thermal conductive layer can extend across the one surface side and the another surface side of the semiconductor substrate.

The thermal conductive layer can constitute at least a surface layer.

The thermal conductive layer can constitute at least an inner layer.

The solid-state image pickup device according to the present technology can further include a lens layer immediately below the thermal conductive layer.

The solid-state image pickup device according to the present technology can further include a color filter layer arranged between the lens layer and the insulating layer.

The solid-state image pickup device according to the present technology can further include a color filter layer immediately below the thermal conductive layer.

The solid-state image pickup device according to the present technology can further include a lens layer as a surface layer, and the thermal conductive layer can be arranged between the lens layer and the insulating layer.

The solid-state image pickup device according to the present technology can further include a lens layer as a surface layer, and the thermal conductive layer can be arranged in the insulating layer.

The insulating layer can be arranged immediately below the lens layer.

The solid-state image pickup device according to the present technology can further include a color filter layer as a surface layer, and the thermal conductive layer can be arranged between the color filter layer and the insulating layer.

The solid-state image pickup device according to the present technology can further include a color filter layer as a surface layer, and the thermal conductive layer can be arranged in the insulating layer.

The solid-state image pickup device according to the present technology can further include a lens layer as a surface layer; and a color filter layer arranged between the lens layer and the insulating layer, and the thermal conductive layer is arranged between the lens layer and the color filter layer.

The solid-state image pickup device according to the present technology can further include: a lens layer as a surface layer; and a color filter layer arranged between the lens layer and the insulating layer, and the thermal conductive layer can be arranged between the insulating layer and the color filter layer.

The solid-state image pickup device according to the present technology can further include: a lens layer as a surface layer; and a color filter layer arranged between the lens layer and the insulating layer, and the thermal conductive layer can be arranged in the insulating layer.

The insulating layer can be arranged immediately below the thermal conductive layer.

At least a part of the insulating layer can be a surface layer.

The thermal conductive layer can be arranged in the insulating layer.

The present technology also provides an electronic apparatus including the solid-state image pickup device.

The present technology also provides a method for manufacturing a solid-state image pickup device, including the steps of:

forming an opening in a semiconductor substrate in which a photoelectric converter is to be formed;

embedding an insulating material in a peripheral part in the opening;

arranging an insulating film on the semiconductor substrate;

forming another opening that communicates with a central part in the opening in the insulating film;

embedding a metal material in the central part in the opening and the another opening; and

arranging a thermal conductive film on a side opposite to the semiconductor substrate of the insulating film.

In the step of arranging a thermal conductive film, the thermal conductive film can be arranged to be connected to the metal material embedded in the another opening directly or via another metal material.

### BRIEF DESCRIPTION OF DRAWINGS

FIG. 1 is a block diagram illustrating a configuration example of a camera apparatus as an electronic apparatus according to a first embodiment.

FIG. 2A is a diagram illustrating a size of one pixel of the solid-state image pickup device according to the first embodiment, and FIG. 2B is a diagram illustrating arrangement of pixels in a pixel region of the solid-state image pickup device according to the first embodiment.

FIG. 3 is a cross section schematically illustrating an overall configuration of the solid-state image pickup device according to the first embodiment.

FIG. 4 is a cross section schematically illustrating a configuration of each pixel of the solid-state image pickup device according to the first embodiment.

FIG. 5 is a first half of a flowchart illustrating the method for manufacturing a solid-state image pickup device according to the first embodiment.

FIG. 6 is a second half of a flowchart illustrating the method for manufacturing a solid-state image pickup device according to the first embodiment.

FIGS. 7A to 7D are step cross sections (No. 1 to No. 4) illustrating the method for manufacturing a solid-state image pickup device according to the first embodiment.

FIGS. 8A and 8B are step cross sections (No. 5 and No. 6) illustrating the method for manufacturing a solid-state image pickup device according to the first embodiment.

FIGS. 9A to 9C are step cross sections (No. 7 to No. 9) illustrating the method for manufacturing a solid-state image pickup device according to the first embodiment.

FIGS. 10A and 10B are step cross sections (No. 9 and No. 10) illustrating the method for manufacturing a solid-state image pickup device according to the first embodiment.

FIGS. 11A and 11B are step cross sections (No. 11 and No. 12) illustrating the method for manufacturing a solid-state image pickup device according to the first embodiment.

FIGS. 12A and 12B are step cross sections (No. 13 and No. 14) illustrating the method for manufacturing a solid-state image pickup device according to the first embodiment.

FIG. 13 is a cross section schematically illustrating a configuration of the solid-state image pickup device according to a second embodiment.

FIGS. 14A and 14B are step cross sections (No. 1 and No. 2) illustrating the method for manufacturing a solid-state image pickup device according to the second embodiment.

FIGS. 15A and 15B are step cross sections (No. 3 and No. 4) illustrating the method for manufacturing a solid-state image pickup device according to the second embodiment.

FIG. 16 is a cross section schematically illustrating a configuration of the solid-state image pickup device according to a third embodiment.

FIGS. 17A and 17B are step cross sections (No. 1 and No. 2) illustrating the method for manufacturing a solid-state image pickup device according to the third embodiment.

FIGS. 18A and 18B are step cross sections (No. 3 and No. 4) illustrating the method for manufacturing a solid-state image pickup device according to the third embodiment.

FIG. 19 is a step cross section (No. 5) illustrating the method for manufacturing a solid-state image pickup device according to the third embodiment.

FIG. 20 is a cross section schematically illustrating a configuration of the solid-state image pickup device according to a fourth embodiment.

FIGS. 21A to 21C are step cross sections (No. 1 to No. 3) illustrating the method for manufacturing a solid-state image pickup device according to the fourth embodiment.

FIGS. 22A to 22C are step cross sections (No. 4 to No. 6) illustrating the method for manufacturing a solid-state image pickup device according to the fourth embodiment.

FIGS. 23A and 23B are step cross sections (No. 7 and No. 8) illustrating the method for manufacturing a solid-state image pickup device according to the fourth embodiment.

FIGS. 24A and 24B are step cross sections (No. 9 and No. 10) illustrating the method for manufacturing a solid-state image pickup device according to the fourth embodiment.

FIG. 25 is a step cross section (No. 11) illustrating the method for manufacturing a solid-state image pickup device according to the fourth embodiment.

FIG. 26 is a cross section schematically illustrating a configuration of the solid-state image pickup device according to a fifth embodiment.

FIG. 27 is a cross section schematically illustrating a configuration of the solid-state image pickup device according to a sixth embodiment.

FIG. 28 is a cross section schematically illustrating a configuration of the solid-state image pickup device according to a seventh embodiment.

FIG. 29 is a cross section schematically illustrating a configuration of the solid-state image pickup device according to an eighth embodiment.

FIG. 30 is a cross section schematically illustrating a configuration of the solid-state image pickup device according to a ninth embodiment.

FIG. 31 is a cross section schematically illustrating a configuration of the solid-state image pickup device according to a 10th embodiment.

FIG. 32 is a cross section schematically illustrating a configuration of the solid-state image pickup device according to an 11th embodiment.

FIG. 33 is a cross section schematically illustrating a configuration of the solid-state image pickup device according to a 12th embodiment.

FIG. 34 is a cross section schematically illustrating a configuration of the solid-state image pickup device according to a 13th embodiment.

FIG. 35 is a cross section schematically illustrating a configuration of the solid-state image pickup device according to a 14th embodiment.

FIG. 36 is a cross section schematically illustrating a configuration of the solid-state image pickup device according to a 15th embodiment.

FIG. 37 is a cross section schematically illustrating a configuration of the solid-state image pickup device according to a 16th embodiment.

FIG. 38 is a cross section schematically illustrating a configuration of the solid-state image pickup device according to a 17th embodiment.

FIG. 39 is a cross section schematically illustrating a configuration of the solid-state image pickup device according to an 18th embodiment.

FIG. 40 is a cross section schematically illustrating a configuration of the solid-state image pickup device according to a 19th embodiment.

FIG. 41 is a cross section schematically illustrating a configuration of the solid-state image pickup device according to a 20th embodiment.

FIG. 42 is a cross section schematically illustrating a configuration of the solid-state image pickup device according to a 21st embodiment.

FIG. 43 is a cross section schematically illustrating a configuration of the solid-state image pickup device according to a 22nd embodiment.

FIG. 44 is a cross section schematically illustrating a configuration of the solid-state image pickup device according to a 23rd embodiment.

FIG. 45 is a cross section schematically illustrating a configuration of the solid-state image pickup device according to a 24th embodiment.

FIG. 46 is a cross section schematically illustrating a configuration of the solid-state image pickup device according to a 25th embodiment.

FIGS. 47A to 47C are step cross sections (No. 1 to No. 3) illustrating the method for manufacturing a solid-state image pickup device according to the 25th embodiment.

FIGS. 48A to 48C are step cross sections (No. 4 to No. 6) illustrating the method for manufacturing a solid-state image pickup device according to the 25th embodiment.

FIGS. 49A and 49B are step cross sections (No. 5 and No. 6) illustrating the method for manufacturing a solid-state image pickup device according to the 25th embodiment.

FIG. 50 is a cross section schematically illustrating a configuration of the solid-state image pickup device according to a 26th embodiment.

FIGS. 51A and 51B are step cross sections (No. 1 and No. 2) illustrating the method for manufacturing a solid-state image pickup device according to the 26th embodiment.

FIG. 52 is a step cross section (No. 3) illustrating the method for manufacturing a solid-state image pickup device according to the 26th embodiment.

FIG. 53 is a diagram illustrating an example in which a thermal conductive layer is provided for each pixel.

FIG. 54 is a diagram illustrating an example in which a thermal conductive layer is commonly provided for four pixels.

FIG. 55 is a diagram illustrating an example in which a thermal conductive layer is commonly provided for eight pixels.

FIG. 56 is a cross section schematically illustrating a configuration of the solid-state image pickup device according to a 27th embodiment.

FIG. 57 is a cross section schematically illustrating a configuration of the solid-state image pickup device according to a 28th embodiment.

FIG. 58 is a cross section schematically illustrating a configuration of the solid-state image pickup device according to a 29th embodiment.

FIG. 59 is a cross section schematically illustrating a configuration of the solid-state image pickup device according to a 30th embodiment.

FIG. 60 is a cross section schematically illustrating a configuration of the solid-state image pickup device according to a 31st embodiment.

FIG. 61 is a cross section schematically illustrating a configuration of the solid-state image pickup device according to a 32nd embodiment.

FIG. 62 is a cross section schematically illustrating a configuration of the solid-state image pickup device according to a 33rd embodiment.

FIG. 63 is a cross section schematically illustrating a configuration of the solid-state image pickup device according to a 34th embodiment.

FIG. 64 is a cross section schematically illustrating a configuration of the solid-state image pickup device according to a 35th embodiment.

FIG. 65 is a cross section schematically illustrating a configuration of the solid-state image pickup device according to a 36th embodiment.

FIG. 66 is a cross section schematically illustrating a configuration of the solid-state image pickup device according to a 37th embodiment.

FIG. 67 is a cross section schematically illustrating a configuration of the solid-state image pickup device according to a 38th embodiment.

FIG. 68 is a cross section schematically illustrating a configuration of the solid-state image pickup device according to a 39th embodiment.

FIG. 69 is a cross section schematically illustrating a configuration of the solid-state image pickup device according to a 40th embodiment.

FIG. 70 is a cross section schematically illustrating a configuration of the solid-state image pickup device according to a 41st embodiment.

FIGS. 71A to 71G are diagrams illustrating variations 1 to 7 of how the thermal conductive layer is provided to the semiconductor substrate.

FIGS. 72A to 72G are diagrams illustrating variations 8 to 14 of how the thermal conductive layer is provided to the semiconductor substrate.

FIGS. 73A to 73G are diagrams illustrating variations 15 to 21 of how the thermal conductive layer is provided to the semiconductor substrate.

FIGS. 74A to 74G are diagrams illustrating variations 22 to 28 of how the thermal conductive layer is provided to the semiconductor substrate.

FIGS. 75A to 75G are diagrams illustrating variations 29 to 35 of how the thermal conductive layer is provided to the semiconductor substrate.

FIG. 76 is a cross section schematically illustrating an overall configuration of the solid-state image pickup device according to a modification example.

FIG. 77 is a diagram illustrating use examples of the solid-state image pickup device according to the first to 41st embodiments to which the present technology is applied.

FIG. 78 is a functional block diagram of an example of the electronic apparatus according to a 42nd embodiment to which the present technology is applied.

FIG. 79 is a block diagram illustrating an example of a schematic configuration of a vehicle control system.

FIG. 80 is an explanatory diagram illustrating an example of installation positions of a vehicle exterior information detection part and an imaging unit.

FIG. 81 is a diagram illustrating an example of schematic configurations of an endoscopic surgery system.

FIG. 82 is a block diagram illustrating an example of functional configurations of a camera head and a CCU.

### MODE FOR CARRYING OUT THE INVENTION

Hereinafter, suitable embodiments of the present technology will be described in detail with reference to the accompanying drawings. Note that, in the present specification and the drawings, components having substantially the same functional configuration are denoted by the same reference numerals to omit redundant description. The embodiments described below illustrate representative embodiments of the present technology, and the scope of the present technology should not be narrowly interpreted by these embodiments. In the present specification, even in a case where it is described that each of the solid-state image pickup device and the electronic apparatus according to the present technology exhibits multiple effects, each of the solid-state image pickup device and the electronic apparatus according to the present technology may only exhibit at least one effect. The effects described in the present specification are merely examples and are not limiting, and other effects can be exhibited.

Furthermore, description will be given in the following order.

1. Overall configuration of camera apparatus according to first embodiment of present technology

2. Introduction

3. Solid-state image pickup device according to first embodiment of present technology

(1) Configuration of solid-state image pickup device

(2) Operation of solid-state image pickup device

(3) Effect of solid-state image pickup device

(4) Method for manufacturing solid-state image pickup device

4. Solid-state image pickup device according to second embodiment of present technology

5. Solid-state image pickup device according to third embodiment of present technology

6. Solid-state image pickup device according to fourth embodiment of present technology

7. Solid-state image pickup device according to fifth embodiment of present technology

8. Solid-state image pickup device according to sixth embodiment of present technology

9. Solid-state image pickup device according to seventh embodiment of present technology

10. Solid-state image pickup device according to eighth embodiment of present technology

11. Solid-state image pickup device according to ninth embodiment of present technology

12. Solid-state image pickup device according to 10th embodiment of present technology

13. Solid-state image pickup device according to 11th embodiment of present technology

14. Solid-state image pickup device according to 12th embodiment of present technology

15. Solid-state image pickup device according to 13th embodiment of present technology

16. Solid-state image pickup device according to 14th embodiment of present technology

17. Solid-state image pickup device according to 15th embodiment of present technology

18. Solid-state image pickup device according to 16th embodiment of present technology

19. Solid-state image pickup device according to 17th embodiment of present technology

20. Solid-state image pickup device according to 18th embodiment of present technology

21. Solid-state image pickup device according to 19th embodiment of present technology

22. Solid-state image pickup device according to 20th embodiment of present technology

23. Solid-state image pickup device according to 21st embodiment of present technology

24. Solid-state image pickup device according to 22nd embodiment of present technology

25. Solid-state image pickup device according to 23rd embodiment of present technology

26. Solid-state image pickup device according to 24th embodiment of present technology

27. Solid-state image pickup device according to 25th embodiment of present technology

28. Solid-state image pickup device according to 26th embodiment of present technology

29. Solid-state image pickup device according to 27th embodiment of present technology

30. Solid-state image pickup device according to 28th embodiment of present technology

31. Solid-state image pickup device according to 29th embodiment of present technology

32. Solid-state image pickup device according to 30th embodiment of present technology

33. Solid-state image pickup device according to 31st embodiment of present technology

34. Solid-state image pickup device according to 32nd embodiment of present technology

35. Solid-state image pickup device according to 33rd embodiment of present technology

36. Solid-state image pickup device according to 34th embodiment of present technology

37. Solid-state image pickup device according to 35th embodiment of present technology

38. Solid-state image pickup device according to 36th embodiment of present technology

39. Solid-state image pickup device according to 37th embodiment of present technology

40. Solid-state image pickup device according to 38th embodiment of present technology

41. Solid-state image pickup device according to 39th embodiment of present technology

42. Solid-state image pickup device according to 40th embodiment of present technology

43. Solid-state image pickup device according to 41st embodiment of present technology

44. Solid-state image pickup device according to modification example of present technology

45. Layout of thermal conductive layer in entire solid-state image pickup device

46. 42nd Embodiment (example of electronic apparatus)

47. Use example of solid-state image pickup device to which present technology is applied

48. Another use example of solid-state image pickup device to which present technology is applied

49. Application example to movable object

50. Application example to endoscopic surgery system

<1. Overall Configuration of Camera Apparatus According to First Embodiment of Present Technology>

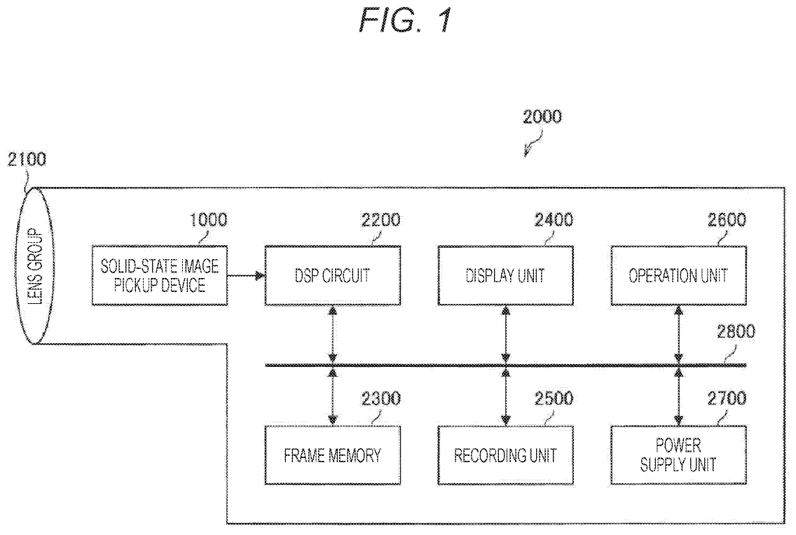

FIG. 1 is a block diagram illustrating a configuration example of a camera apparatus 2000 (an example of an electronic apparatus) according to the first embodiment of the present technology. A camera apparatus 2000 illustrated in FIG. 1 includes an optical unit 2100 including a lens group and the like, a solid-state image pickup device 1000 (image sensor), and a DSP circuit 2200 which is a camera signal processing device. The camera apparatus 2000 also includes a frame memory 2300, a display unit (display device) 2400, a recording unit 2500, an operation unit 2600, and a power supply unit 2700. The DSP circuit 2200, the frame memory 2300, the display unit 2400, the recording unit 2500, the operation unit 2600, and the power supply unit 2700 are connected each other via a bus line 2800.

The optical unit 2100 takes in incident light (image light) from a subject and forms an image on an imaging surface of the solid-state image pickup device 1000. The solid-state image pickup device 1000 converts the light amount of the incident light that is formed into an image on the imaging surface by the optical unit 2100 into an electrical signal on a pixel-by-pixel basis and outputs the electrical signal as a pixel signal.

The display unit 2400 includes, for example, a panel type display device such as a liquid crystal panel and an organic electro luminescence (EL) panel, and displays a moving image or a still image imaged by the solid-state image pickup device 1000. The DSP circuit 2200 receives the pixel signal output from the solid-state image pickup device 1000 and performs processing to display the pixel signal on the display unit 2400. The recording unit 2500 records the moving image or the still image imaged by the solid-state image pickup device 1000 in a recording medium such as a video tape and a Digital Versatile Disk (DVD).

The operation unit 2600 issues operation commands for various functions of the solid-state image pickup device 1000 under operation by a user. The power supply unit 2700 appropriately supplies various power sources that serve as operation power sources of the DSP circuit 2200, the frame memory 2300, the display unit 2400, the recording unit 2500, and the operation unit 2600 to these supply targets.

<2. Introduction>

In a solid-state image pickup device such as an image sensor, if the heat generated in a circuit unit around a pixel region in which a plurality of pixels is arranged is transferred to a pixel, output accuracy of the pixel decreases due to an increase in temperature of the pixel, and image quality deteriorates.

For example, Patent Document 1 discloses technology for preventing the heat generated in a circuit unit from being transferred to pixels.

However, in recent years, a solid-state image pickup device in which a pixel itself generates heat has been developed, and there is an increasing need to develop technology for releasing not only the heat generated in a circuit unit but also the heat generated in a pixel to the outside of a pixel region.

<3. Solid-State Image Pickup Device According to First Embodiment of Present Technology>

(1) Configuration of Solid-State Image Pickup Device

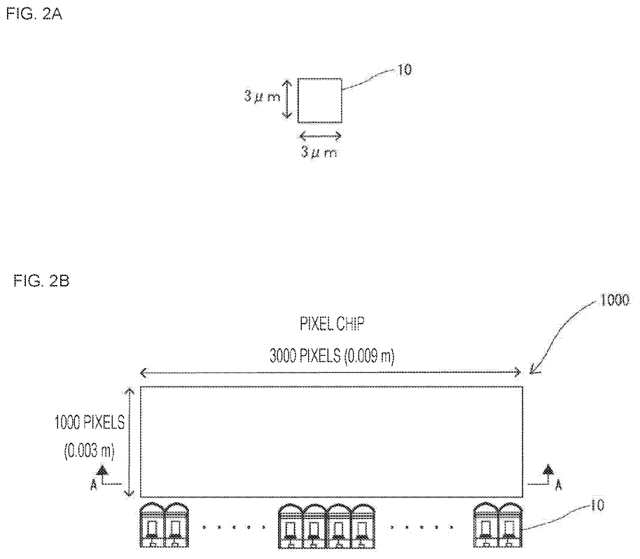

As illustrated in FIG. 2B, the solid-state image pickup device 1000 includes a plurality of pixels 10 arranged two-dimensionally (for example, arranged in a matrix). The solid-state image pickup device 1000 is generally called an “image sensor”.

Each pixel 10 has a square shape having a side length of 5 μm or less in plan view (as an example, a square shape of 3 μm×3 μm is illustrated in this figure) as illustrated in FIG. 2A, and has a stacked structure in side view as illustrated in the lower diagram of FIG. 2B (a cross section taken along line A-A in the upper diagram of FIG. 2B).

That is, the solid-state image pickup device 1000 is an area image sensor in which a plurality of pixels 10 is two-dimensionally arranged in series. A region (pixel region) in which a plurality of pixels 10 is integrally arranged is also referred to as a pixel chip.

As illustrated in the upper diagram of FIG. 2B, the total number of pixels 10 in the pixel chip is the number of vertical pixels (for example, 3000)×the number of horizontal pixels (for example, 1000), and is, for example, 3×10⁶.

That is, here, the pixel chip has a rectangular outer shape in plan view having a vertical length of 0.003 m and a horizontal length of 0.009 m.

Although the pixel chip (pixel region) of the solid-state image pickup device 1000 is described by taking a rectangular shape in plan view as an example here, the pixel chip can have a shape other than the rectangular shape in plan view, such as a square shape in plan view.

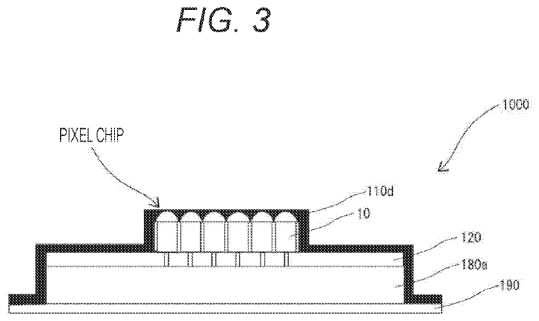

FIG. 3 is a cross section illustrating an overall configuration of the solid-state image pickup device 1000.

As can be seen from FIG. 3, the solid-state image pickup device 1000 has a chip-on-wafer structure (COW structure) in which a pixel chip in which a plurality of pixels 10 is arranged is arranged on a semiconductor substrate 180a that constitutes a part of a logic substrate 180 described later.

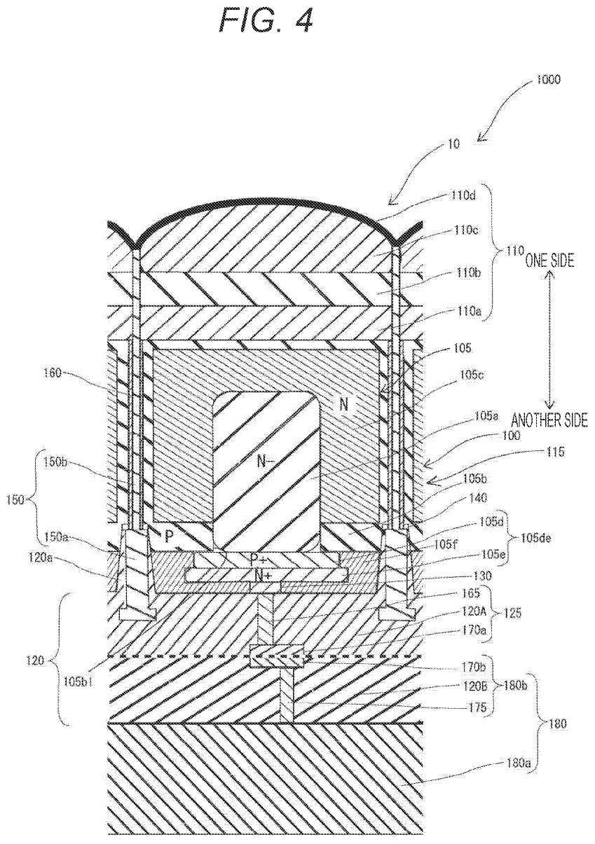

FIG. 4 is a cross section schematically illustrating each pixel 10 of the solid-state image pickup device 1000.

Each pixel 10 is a back-illuminated pixel, and as illustrated in FIG. 4, includes at least one photoelectric converter 105 formed in a semiconductor substrate 100, a stacked part 110 arranged on the back surface side (one surface side) of the semiconductor substrate 100, that is, the light incident side and having a light transmission property (light transparency), and a wiring layer 125 arranged on the surface side (another surface side) of the semiconductor substrate 100, that is, the side opposite to the light incident side.

The at least one photoelectric converter 105 photoelectrically converts light received via the stacked part 110. The electrical signal (analog signal) photoelectrically converted by the at least one photoelectric converter 105 is output to the logic substrate 180 described later via the wiring layer 125.

Hereinafter, a substrate having a two-layer structure formed by stacking the semiconductor substrate 100 and the wiring layer 125 will be appropriately referred to as a “pixel sensor substrate 115”.

In the following description, for convenience, the upper side in FIG. 4 and the like is referred to as “one side” or “upper side”, and the lower side in FIG. 4 and the like is referred to as “another side” or “lower side”. For example, in FIG. 4 and the like, the back surface side of the semiconductor substrate 100 is one side (upper side) of the semiconductor substrate 100, and the surface side of the semiconductor substrate 100 is the another side (lower side) of the semiconductor substrate 100.

The semiconductor substrate 100 is, for example, a silicon substrate. The thickness of the semiconductor substrate 100 is, for example, 5 μm or less (here, as an example, 4 μm).

On the surface side (the another side) of the semiconductor substrate 100, the wiring layer 125 and the logic substrate 180 are arranged in this order from the side closer to the semiconductor substrate 100.

That is, in the solid-state image pickup device 1000, the pixel sensor substrate 115 and the logic substrate 180 are stacked.

In FIG. 4, a joint part between the pixel sensor substrate 115 and the logic substrate 180 is indicated by a broken line.

The wiring layer 125 includes an insulating layer 120A, a metal member 165 that extends in the film thickness direction in the insulating layer 120A, and a wiring member 170a formed on a surface layer on the another side (lower side) of the insulating layer 120A. The wiring member 170a includes Cu and is connected to the semiconductor substrate 100 via the metal member 165. The metal member 165 includes, for example, a metal such as Cu, Al, and W.

The logic substrate 180 processes an electrical signal output from the pixel sensor substrate 115 (an electric signal photoelectrically converted by the at least one photoelectric converter 105 and output via the wiring layer 125).

The logic substrate 180 includes a wiring layer 180b arranged on the another side (lower side) of the wiring layer 125, and a semiconductor substrate 180a which is arranged on the another side (lower side) of the wiring layer 180b and in which a circuit element such as a transistor that constitutes a logic circuit (digital circuit) is formed.

The wiring layer 180b includes an insulating layer 120B, a metal member 175 that extends in the film thickness direction in the insulating layer 120B, and a wiring member 170b formed on a surface layer on one side (upper side) of the insulating layer 120B. The wiring member 170b includes Cu and is joined to the wiring member 170a. That is, the wiring member 170a and the wiring member 170b are metal-bonded (Cu—Cu joining). The metal member 175 includes, for example, a metal such as Cu, Al, and W.

The semiconductor substrate 180a of the logic substrate 180 is supported by the support substrate 190 from the another side (lower side) (see FIG. 3).

A first insulating layer 120 (insulating layer) includes the insulating layer 120A of the wiring layer 125, and the insulating layer 120B of the wiring layer 180b.

Here, the materials of the two wiring members 170a and 170b are both Cu, but can be Al, W, or the like.

As can be seen from the above description, the semiconductor substrate 100 of the pixel sensor substrate 115 and the semiconductor substrate 180a of the logic substrate 180 are connected via the metal member 165, the two wiring members 170a and 170b, and the metal member 175. Therefore, the electrical signal photoelectrically converted by the at least one photoelectric converter 105 is transmitted to the logic circuit.

Note that, as an example, in addition to the logic circuit that processes the signal from the at least one photoelectric converter 105, at least one of a control circuit that integrally controls each component part of the solid-state image pickup device 1000 or a storage unit (for example, a memory) that stores the signal from the at least one photoelectric converter 105 can be formed on the logic substrate 180.

Here, the at least one photoelectric converter 105 is, for example, a Single Photon Avalanche Diode (SPAD). The SPAD is a photodiode having readout sensitivity of one photon level by electron multiplication.

More specifically, the at least one photoelectric converter 105 is a back-illuminated SPAD in which light is irradiated from the back surface side (one surface side) of the semiconductor substrate 100.

The at least one photoelectric converter 105, which is a SPAD, has an electron multiplication region 105de including a PN junction to which a reverse bias of a relatively high voltage is applied and which generates heat during photoelectric conversion.

The at least one photoelectric converter 105 includes an N− layer 105a (low-concentration N-type layer), a P layer 105b (P-type layer) holding the N-layer 105a, a P+ layer 105d (high-concentration P-type layer) arranged on the another side of the N− layer 105a, and an N+ layer 105e (high-concentration N-type layer) arranged on the another side of the P+ layer 105d.

The P layer 105b has a box shape having an opening part 105b1 on the another side. An N layer 105c (N-type layer) is provided between the N− layer 105a and the P layer 105b.

The N− layer 105a has a columnar shape that extends in the thickness direction of the semiconductor substrate 100 and constitutes a sensitive region. For the N− layer 105a, a part on one side is positioned in the P layer 105b and the N layer 105c, and an end on the another side is fitted into the opening part 105b1 of the P layer 105b.

The P+ layer 105d and the N+ layer 105e constitute the electron multiplication region 105de. The P+ layer 105d has a flat plate shape substantially parallel to the surface of the semiconductor substrate 100, the peripheral part is in contact with the P layer 105b, and the central part (a part surrounded by the peripheral part) is in contact with the N− layer 105a.

The N+ layer 105e has a flat plate shape substantially parallel to the surface of the semiconductor substrate 100, the surface on one side is in contact with the P+ layer 105d, and the surface on the another side is in contact with the cathode electrode 130 which is an N-type impurity layer.

The surface on one side of the cathode electrode 130 is in contact with the N+ layer 105e, and the surface on the another side is in contact with the first insulating layer 120.

An N layer 105f (N-type layer) is provided around the P+ layer 105d, the N+ layer 105, and the cathode electrode 130. Note that the concentration of the N layer 105f can be the same as or different from that of the N layer 105c.

The cathode electrode 130 is connected to the semiconductor substrate 180a of the logic substrate 180 via the metal member 165, the two wiring members 170a and 170b, and the metal member 175 arranged in the first insulating layer 120.

The stacked part 110 includes a second insulating layer 110a having a light transparency (light transmission property) arranged on the back surface (one surface) of the semiconductor substrate 100, a color filter layer 110b arranged on the second insulating layer 110a, a lens layer 110c (on-chip lens) arranged on the color filter layer 110b, and a thermal conductive layer 110d having a light transparency arranged on the lens layer 110c.

Note that the stacked part 110 may only have at least one layer having a light transparency, including the thermal conductive layer 110d. That is, the stacked part 110 may only include at least the thermal conductive layer 110d among the second insulating layer 110a, the color filter layer 110b, the lens layer 110c, and the thermal conductive layer 110d.

As can be seen from the above description, the thermal conductive layer 110d constitutes a surface layer of the stacked part 110 (a surface layer of the solid-state image pickup device 1000).

The thermal conductive layer 110d is preferably provided to extend across at least two photoelectric converters 105. That is, the thermal conductive layer 110d is preferably a layer common to at least two pixels 10.

Here, as illustrated in FIG. 3 as an example, the thermal conductive layer 110d is a layer (single layer) provided to extend across all the photoelectric converters 105 and common to all the pixels 10. As a whole, the thermal conductive layer 110d is provided to cover the pixel chip, the peripheral region of the pixel chip in the semiconductor substrate 180a of the logic substrate 180, and the peripheral region of the semiconductor substrate 180a of the logic substrate 180 in the support substrate 190 from above. The end surface of the thermal conductive layer 110d is positioned in substantially the same plane as the end surface of the support substrate 190.

Although in FIG. 3, the first insulating layer 120 is provided on the region corresponding to the pixel chip in the semiconductor substrate 180a of the logic substrate 180 and on the peripheral region thereof, it can be provided only on the region corresponding to the pixel chip in the semiconductor substrate 180a of the logic substrate 180.

Note that the thermal conductive layer 110d can be provided separately for each pixel 10.

TABLE 1

| | | Thermal | |
|---|---|---|---|
| | Thermal | conductivity | |
| | conductivity | (Normalized with | |
| Material | λ (W/m · K) | value of Si) | Light transparency |
| SiO₂ | 1.38 | 0.008625 | 90% - |
| Titanium | 12.6 | 0.07875 | 82% |
| oxide | | | |
| ZnO | 20 | 0.125 | Transparent |
| Titanium (Ti) | 21.9 | 0.136875 | — |
| SiN | 24 | 0.15 | 98% |
| MgO | 30 | 0.1875 | Transparent |
| Al₂O₃ | 37 | 0.23125 | Total luminous |
| | | | transmittance 83.66% |
| | | | Diffuse |
| | | | transmittance 54.38% |
| | | | Parallel |
| | | | transmittance 29.28% |
| ZnO—Al | 40 | — | 78% |
| Sn | 64 | 0.4 | — |
| Platinum (Pt) | 72 | 0.45 | — |
| Fe | 76 | 0.475 | — |
| Indium tin | 81.8 | 0.51 | Transparent |
| oxide | | | |
| Ni | 91 | 0.56875 | — |
| Zn | 116 | 0.725 | — |
| AlN | 155 | 0.96875 | Transparent |
| Mg | 159 | 0.99375 | — |
| Si | 160 | 1 | — |
| W | 174 | 1.0875 | — |
| SiC | 200 | 1.25 | Transparent |
| Al | 236 | 1.475 | — |
| Au | 318 | 1.9875 | — |
| Cu | 398 | 2.4875 | — |
| Ag | 429 | 2.68125 | — |
| Graphene | 1900 | 31.25 | 93% |
| Fullerene | 2000 | 12.5 | 80% - |

Table 1 shows the thermal conductivity λ (W/m·K) for each of various substances (materials). Note that the thermal conductivity λ in Table 1 indicates an average value for a substance whose thermal conductivity varies depending on the temperature.

Moreover, Table 1 shows values obtained by normalizing the thermal conductivity λ with the value of Si (thermal conductivity).

Therefore, the relative thermal conductive property of each substance with respect to the thermal conductive property of Si, which is a material generally used for the semiconductor substrate 100, is obvious at a glance.

Note that the values of the thermal conductivity and the light transparency shown in Table 1 are examples, and can vary depending on the measurement method or the like.

Although any material of a conductor, a semiconductor, and an insulator can be used for the thermal conductive layer 110d, a material having a higher thermal conductivity λ is more preferable.

Here, for example, silicon dioxide (SiO₂) is used as a material of the first insulating layer 120 and the second insulating layer 110a.

Meanwhile, as the material of the thermal conductive layer 110d, a material having a thermal conductivity λ higher than that of SiO₂, that is, a material having a thermal conductivity λ of λ>1.38 W/m·K is used.

That is, the thermal conductive layer 110d has a higher thermal conductivity λ than the first insulating layer 120 and the second insulating layer 110a.

Examples of the material that is used for the thermal conductive layer 110d and satisfies λ>1.38 W/m·K include a material containing one or more types of substances of, for example, titanium oxide, ZnO, Ti, silicon nitride (SiN), MgO, alumina (Al₂O₃), ZnO—Al (aluminum-doped zinc oxide), Sn, Pt, Fe, indium tin oxide (ITO), Ni, Zn, AlN (aluminum nitride), Mg, Si, W, SiC (silicon carbide), Al, Au, Cu, Ag, a carbon nanomaterial, fullerene, and the like.

Moreover, the material of the thermal conductive layer 110d more preferably satisfies λ≥50 W/m·K. Examples of the material that satisfies λ≥50 W/m·K include Sn, Pt, Fe, indium tin oxide (ITO), Ni, Zn, AlN (aluminum nitride), Mg, Si, W, SiC (silicon carbide), Al, Au, Cu, Ag, s carbon nanomaterial, and fullerene.

Moreover, the material of the thermal conductive layer 110d more preferably satisfies λ≥100 W/m·K. Examples of the material that satisfies λ≥100 W/m·K include Zn, AlN (aluminum nitride), Mg, Si, W, SiC (silicon carbide), Al, Au, Cu, Ag, a carbon nanomaterial, and fullerene.

Moreover, the material of the thermal conductive layer 110d more preferably satisfies λ≥150 W/m·K. Examples of the material that satisfies λ≥150 W/m·K include AlN (aluminum nitride), Mg, Si, W, SiC (silicon carbide), Al, Au, Cu, Ag, a carbon nanomaterial, and fullerene.

In particular, the material of the thermal conductive layer 110d more preferably has a thermal conductivity λ equal to or higher than that of Si, which is generally used as a material of a semiconductor substrate. Examples of the material having a thermal conductivity λ equal to or higher than that of Si include Mg, Si, W, SiC (silicon carbide), Al, Au, Cu, Ag, a carbon nanomaterial, and fullerene.

Moreover, the material of the thermal conductive layer 110d more preferably satisfies λ≥200 W/m·K. Examples of the material that satisfies λ≥200 W/m·K include SiC (silicon carbide), Al, Au, Cu, Ag, a carbon nanomaterial, and fullerene.

Moreover, the material of the thermal conductive layer 110d more preferably satisfies λ≥300 W/m·K. Examples of the material that satisfies λ≥300 W/m·K include Au, Cu, Ag, a carbon nanomaterial, and fullerene.

Moreover, the material of the thermal conductive layer 110d more preferably satisfies λ≥400 W/m·K. Examples of the material that satisfies λ≥400 W/m·K include Ag, a carbon nanomaterial, and fullerene.

Moreover, the material of the thermal conductive layer 110d more preferably satisfies λ≥1000 W/m·K. Examples of the material that satisfies λ≥1000 W/m·K include a carbon nanomaterials and fullerenes.

Specific examples of the carbon nanomaterial include carbon nanotubes, carbon nanowalls, and carbon nanosheets.

Among the carbon nanosheets, graphene is particularly suitable.

The thermal conductivity of graphene is about 31 times that of Si, which is outstandingly high (see Table 1).

Although, as described above, the material suitable for the thermal conductive layer 110d has been described mainly from the viewpoint of thermal conductive property, the thermal conductive layer 110d desirably has a high light transparency because the thermal conductive layer 110d is provided on the back surface side (light incident side) of the semiconductor substrate 100.

That is, the thermal conductive layer 110d desirably has both a high thermal conductive property and a high light transparency.

This also applies to another embodiment described later, an embodiment in which the thermal conductive layer is provided on the back surface side (light incident side) of the semiconductor substrate.

Meanwhile, in another embodiment described later in which the thermal conductive layer is provided on the surface side (the side opposite to the light incident side) of the semiconductor substrate, a light transparency is not required for the thermal conductive layer, and thus preferably, a material having high thermal conductive property is selected without considering a light transparency.

Table 1 shows the light transparency (light transmission property) of some materials (SiO₂, titanium oxide, ZnO, SiN, MgO, Al₂O₃, ZnO—Al, indium tin oxide, AlN, SiC, graphene, fullerene).

Among the materials listed in Table 1 and having a higher thermal conductivity than SiO₂, examples of materials more suitable for the thermal conductive layer 110d include titanium oxide, ZnO, SiN, MgO, Al₂O₃, ZnO—Al, indium tin oxide, AlN, SiC, graphene, and fullerene from the viewpoint of a light transparency.

Thus, in the first embodiment, any one of titanium oxide, ZnO, SiN, MgO, Al₂O₃, ZnO—Al, indium tin oxide, AlN, SiC, graphene, and fullerene is particularly preferably used as the material of the thermal conductive layer 110d. The same discussion holds in another embodiment described later in which the thermal conductive layer is provided on the back surface side (incident side) of the semiconductor substrate.

Returning to FIG. 4, the first insulating layer 120 has a protruding part 120a that protrudes to one side (upper side) to surround the P+ layer 105d and the N+ layer 105e from four sides and enters the semiconductor substrate 100.

That is, the protruding part 120a has a substantially square frame shape in plan view (as viewed from the thickness direction of the semiconductor substrate 100).

The part surrounded by the protruding part 120a (here, a central part) of the first insulating layer 120 is in contact with the cathode electrode 130. The height of the protruding part 120a is, for example, about 1 μm.

That is, the cathode electrode 130 is positioned near the base end part of the protruding part 120a in the thickness direction of the semiconductor substrate 100.

The side surface of a part on one side (upper side) of the protruding part 120a is in contact with the P layer 105b.

On an outer peripheral part of a tip surface (end surface on one side) of the protruding part 120a, an anode electrode 140 which is a P-type impurity layer and has a frame shape in plan view is provided to be in contact with the P layer 105b. That is, the solid-state image pickup device 1000 has a configuration in which the anode electrode 140 is in contact with the side surface of the at least one photoelectric converter 105 (also referred to as “side surface contact”).

A reverse bias having a relatively high voltage value (for example, 18 V) is applied between the anode electrode 140 and the cathode electrode 130.

Thus, in the at least one photoelectric converter 105, an electron avalanche occurs at the PN junction of the electron multiplication region 105de at the time of light reception (at the time of photoelectric conversion), and electron multiplication occurs. Therefore, a large current flows through the electron multiplication region 105de, and heat is generated.

Note that as described above, the anode electrode 140 and the cathode electrode 130 are provided at positions away from each other in the thickness direction of the semiconductor substrate 100, and thus the anode electrode 140 and the cathode electrode 130 are not close to each other even if the distance between the anode electrode 140 and the cathode electrode 130 in the in-plane direction (direction orthogonal to the thickness direction) of the semiconductor substrate 100 is shortened due to miniaturization. Therefore, the occurrence of unintended electron multiplication (edge breakdown) between the anode electrode 140 and the cathode electrode 130 can be suppressed. Note that the edge breakdown causes a decrease in sensitivity and an increase in direct current resistance (DCR).

Note that the conductivity type and concentration of the impurity layer described above is one example, and the conductivity type can be one in which P and N are switched and the anode and the cathode are switched. Furthermore, various other methods can be considered as a method of making the electron multiplication region 105de having a high electric field. Moreover, an impurity implantation region for separating the electron multiplication region 105de can be provided.

On the protruding part 120a of the first insulating layer 120 and a part on the another side of the protruding part 120a, a base end part 150a of a partition wall 150 that separates adjacent pixels 10 is embedded. The upper surface of the base end part 150a of the partition wall 150 is flush with the frame-shaped upper surface of the protruding part 120a in plan view. The partition wall 150 functions as a pixel isolation part (Sallow Trench Isolation (STI)) that isolates the adjacent pixels 10 from each other.

The partition wall 150 further has an extending part 150b that extends from the upper surface of the base end part 150a to the one side through the inside of the anode electrode 140.

The extending part 150b is narrower in width than the base end part 150a.

The extending part 150b extends from the another side to the one side along the side wall part of the P layer 105b from the base end part 150a, and passes through the side parts of the second insulating layer 110a, the color filter layer 110b, and the lens layer 110c, and the tip reaches (is in contact with) the thermal conductive layer 110d. An insulating film 160 is provided between the extending part 150b and the side wall part of the P layer 105b.

In each pixel 10, the partition wall 150 has a shape that surrounds the at least one photoelectric converter 105 from four sides (substantially square shape in plan view).

That is, as the entire solid-state image pickup device 1000, the partition wall 150 is provided in a two-dimensional lattice shape in plan view (for example, a square lattice shape).

Here, the partition wall 150 preferably has, in addition to the light shielding property for suppressing the crosstalk between the adjacent pixels 10, high thermal conductive property (thermal conductivity) so that the heat generated in the electron multiplication region 105de of the at least one photoelectric converter 105 and the heat generated in the logic substrate 180 can be quickly conveyed to the thermal conductive layer 110d.

Thus, the material of the partition wall 150 is preferably a material containing one or more types of metals, Si, and the like having a higher thermal conductivity than SiO₂, which is a material used for the first insulating layer 120 and the second insulating layer 110a. Examples of such a metal include Ti, Sn, Pt, Fe, Ni, Zn, Mg, W, Al, Au, Cu, and Ag, as shown in Table 1. Examples of the material containing such a metal or Si include Al₂O₃ (alumina), PolySi (polysilicon), and W (tungsten).

Moreover, the material of the partition wall 150 preferably contains one or more types of metals, Si, or the like having a thermal conductivity equal to or higher than that of Si, which is a material used for the semiconductor substrate 100. Examples of such a metal include Mg, W, Al, Au, Cu, and Ag, as shown in Table 1.

Note that although the partition wall 150 need not necessarily be in contact with the thermal conductive layer 110d, the partition wall 150 preferably extends as close as possible to the thermal conductive layer 110d from the viewpoint of efficiently transferring heat to the thermal conductive layer 110d.

(2) Operation of Solid-State Image Pickup Device

Light (image light) from a subject is incident on each pixel 10 of the solid-state image pickup device 1000. The incident light on each pixel 10 passes through the thermal conductive layer 110d and is incident on the lens layer 110c. The light incident on the lens layer 110c is condensed by the lens layer 110c. The light condensed by the lens layer 110c is incident on the color filter layer 110b. The light that passed through the color filter layer 110b passes through the second insulating layer 110a and is incident on the at least one photoelectric converter 105.

The at least one photoelectric converter 105 photoelectrically converts the incident light. The current (electrical signal) photoelectrically converted by the at least one photoelectric converter 105 is sent to the logic circuit of the logic substrate 180, and predetermined processing and calculation are performed.

During photoelectric conversion, electron multiplication occurs in the electron multiplication region 105de to generate heat, and the logic circuit of the logic substrate 180 also generates heat.

The heat generated in the at least one photoelectric converter 105 and the logic substrate 180 is conveyed to the thermal conductive layer 110d mainly via the partition wall 150. A part of the heat conveyed to the thermal conductive layer 110d is released from the surface of the thermal conductive layer 110d to the outside, and the remaining part moves along the thermal conductive layer 110d in the thermal conductive layer 110d and is released from the end surface of the thermal conductive layer 110d to the outside.

(3) Effect of Solid-State Image Pickup Device

A solid-state image pickup device 1000 of the first embodiment includes at least one photoelectric converter 105 formed in a semiconductor substrate 100; and a thermal conductive layer 110d that is arranged on the back surface side (one surface side) of the semiconductor substrate 100 and includes a material having a thermal conductivity higher than that of SiO₂.

In the solid-state image pickup device 1000 of the first embodiment, for example, the heat generated in the at least one photoelectric converter 105 is conveyed to the thermal conductive layer 110d. At least a part of the heat conveyed to the thermal conductive layer 110d moves toward the end surface of the thermal conductive layer 110d along the thermal conductive layer 110d in the thermal conductive layer 110d, and is released from the end surface to the outside.

As a result, according to the solid-state image pickup device 1000, a heat dissipation property can be improved.

Meanwhile, in a conventional solid-state image pickup device (for example, a chemical sensor described in Patent Document 1), a layer having a relatively high thermal conductivity, such as the thermal conductive layer 110d, is not provided, and the heat dissipation property is low. Thus, there is a possibility that the temperature of the photoelectric converter increases. The temperature increase in the photoelectric converter can cause not only a decrease in output accuracy of the photoelectric converter but also destruction of the photoelectric converter.

In a case where the thermal conductivity of the thermal conductive layer 110d is equal to or higher than the thermal conductivity of Si which is the material of the semiconductor substrate 100, for example, the heat generated in the at least one photoelectric converter 105 formed in the semiconductor substrate 100 can be quickly released to the outside.

Therefore, the temperature increase in the at least one photoelectric converter 105 can be more reliably suppressed.

The at least one photoelectric converter 105 has the electron multiplication region 105de that generates heat during photoelectric conversion, and thus, provision of the thermal conductive layer 110d is particularly effective.

Light is incident on the at least one photoelectric converter 105 from the back surface side (one surface side), and the thermal conductive layer 110d has a light transparency and is arranged on the back surface side. In this case, even if the thermal conductive layer 110d is arranged on the back surface side (light incident side), the heat dissipation property can be improved without hindering incidence of light on the photoelectric converter 105.

The solid-state image pickup device 1000 includes a second insulating layer 110a having a light transparency on the back surface side (one surface side), and the second insulating layer 110a is arranged between the semiconductor substrate 100 and the thermal conductive layer 110d. In this case, even if the second insulating layer 110a is arranged on the back surface side, the insulating property can be obtained without hindering the incidence of light on the at least one photoelectric converter 105.

In a case where the thermal conductive layer 110d includes a material containing any one of indium tin oxide, SiN, Al₂O₃, ZnO—Al, AlN, SiC, fullerene, graphene, titanium oxide, MgO, and ZnO, both a thermal conductive property and a light transparency can be achieved in a high level.

Light is incident on the at least one photoelectric converter 105 from the back surface side (one surface side), and the solid-state image pickup device 1000 includes a logic substrate 180 including a semiconductor substrate 180a arranged on the surface side (the another surface side) of the semiconductor substrate 100.

Although Patent Document 1 discloses a configuration in which the heat generated in a circuit unit (corresponding to a logic circuit of the logic substrate 180) is less likely to be directly conveyed to a pixel, there is room for improvement with respect to the heat dissipation property for releasing the heat generated in the circuit unit to the outside.

That is, in Patent Document 1, there is a possibility that the heat generated in the circuit unit remains in the chemical sensor (solid-state image pickup device) and the temperature of the photoelectric converter increases.

In the solid-state image pickup device 1000, the heat generated in the logic substrate 180 can also be quickly released to the outside via the thermal conductive layer 110d, and thus the temperature increase of the at least one photoelectric converter 105 can be suppressed.

In a case where the thermal conductive layer 110d includes a material containing a carbon nanomaterial or fullerene, the thermal conductive property of the thermal conductive layer 110d can be sufficiently improved.

In a case where the thermal conductive layer 110d includes a material containing graphene, the thermal conductive property of the thermal conductive layer 110d can be remarkably improved.

In a case where the thermal conductive layer 110d includes a material containing any one of Ti, Sn, Pt, Fe, Ni, Zn, Mg, Si, W, Al, Au, Cu, and Ag, the thermal conductive property of the thermal conductive layer 110d can be sufficiently improved.

The at least one photoelectric converter 105 includes a plurality of photoelectric converters 105, and the solid-state image pickup device 1000 includes a partition wall 150 that separates adjacent photoelectric converters 105 of the plurality of photoelectric converters 105. In this case, at least a part of the heat generated in the electron multiplication region 105de and the logic substrate 180 can be transferred to the thermal conductive layer 110d via the partition wall 150.

That is, heat can be efficiently transferred from the electron multiplication region 105de and the logic substrate 180 to the thermal conductive layer 110d.

In a case where the partition wall 150 is in contact with the thermal conductive layer 110d, heat can be more efficiently transferred from the electron multiplication region 105de and the logic substrate 180 to the thermal conductive layer 110d.

In a case where the partition wall 150 includes a material containing a metal, the light shielding property can be improved, and heat can be more efficiently transferred from the electron multiplication region 105de and the logic substrate 180 to the thermal conductive layer 110d.

In a case where the thermal conductive layer 110d is provided to extend across at least two photoelectric converters 105 of the plurality of photoelectric converters 105, film formation of the thermal conductive layer 110d is easier as compared with a case where the thermal conductive layer 110d is provided for each photoelectric converter 105.

Because the thermal conductive layer 110d is a surface layer, heat can be released from the surface and the end surface of the thermal conductive layer 110d to the outside.

The solid-state image pickup device 1000 further includes a lens layer 110c immediately below the thermal conductive layer 110d. Therefore, a light condensing property on the photoelectric converter 105 can be obtained.

The solid-state image pickup device 1000 further includes a color filter layer 110b arranged between the lens layer 110c and the second insulating layer 110a. Therefore, the color information of the incident light can be obtained.

According to a camera (electronic apparatus) including the solid-state image pickup device 1000, a decrease in output accuracy of the at least one photoelectric converter 105 and destruction of the at least one photoelectric converter 105 can be suppressed because the solid-state image pickup device 1000 is excellent in the heat dissipation property.

As a result, a camera in which deterioration in image quality is suppressed and which is less likely to fail can be provided.

(4) Method for Manufacturing Solid-State Image Pickup Device

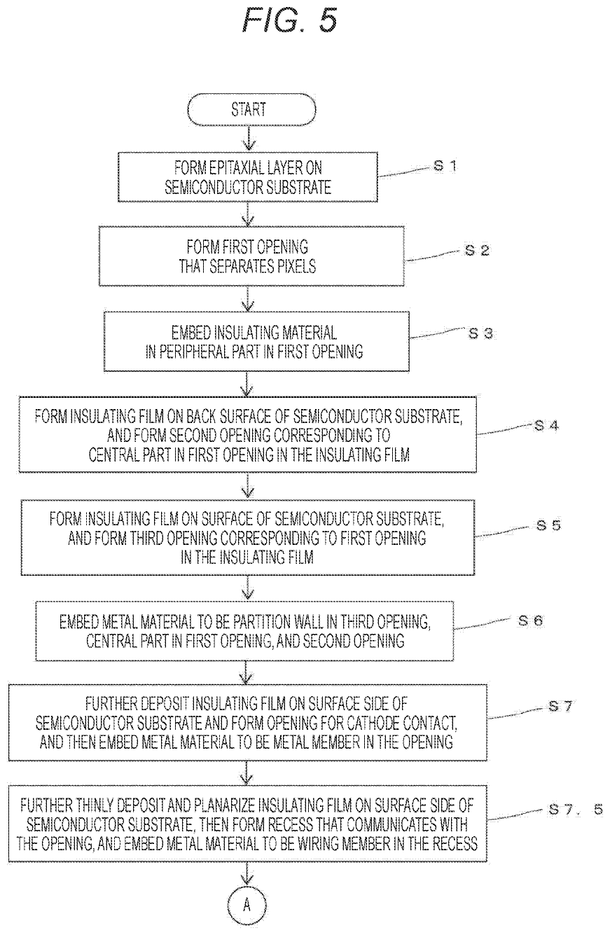

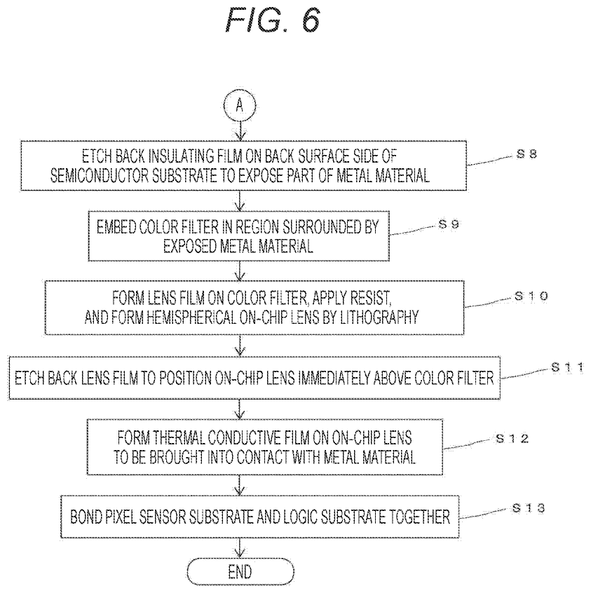

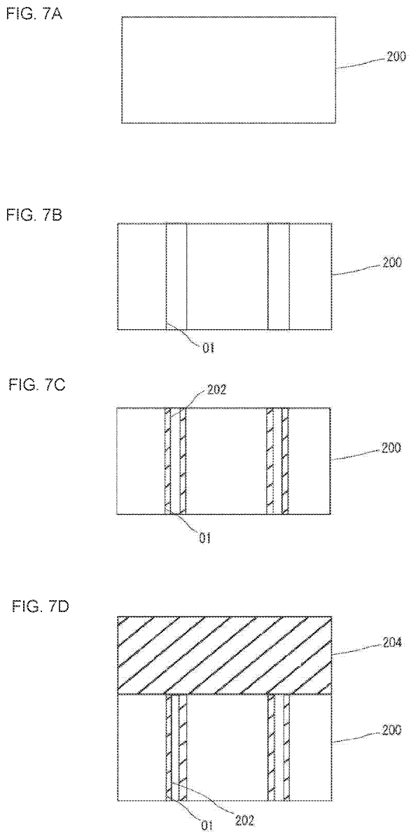

Hereinafter, a method for manufacturing the solid-state image pickup device 1000 will be described with reference to FIGS. 5 to 12B. FIGS. 5 and 6 are flowcharts illustrating a flow of the method for manufacturing the solid-state image pickup device 1000. FIGS. 7A to 12B are step cross sections illustrating manufacturing steps of the solid-state image pickup device 1000 in order of steps.

In the first step S1, as illustrated in FIG. 7A, an epitaxial layer to be the at least one photoelectric converter 105 (PD: photodiode) is formed on the upper part of the semiconductor substrate 200 (Si substrate) which is a base material of the semiconductor substrate 100, and the first half of the sensor formation process (Front End Of Line (FEOL)) is performed on the epitaxial layer. FEOL is the first half of a pre-semiconductor manufacturing step, and building of an element in a Si substrate by a transistor forming process, ion injection (implantation), annealing, or the like is mainly performed.

Note that the second half of the sensor formation process (Back End Of Line (BEOL)) is the second half of the pre-semiconductor manufacturing step, and refers to a wiring step, particularly from the formation of wiring to before joining.

In the next step S2, as illustrated in FIG. 7B, a first opening O1, which is a stepped opening for separating each pixel, is formed by two-stage etching in the epitaxial layer in the semiconductor substrate 200. Note that in FIG. 7B, the illustration of the step part of the first opening O1 is omitted.

In the next step S3, as illustrated in FIG. 7C, the insulating material 202 to be the insulating film 160 is embedded in the peripheral part in the first opening O1.

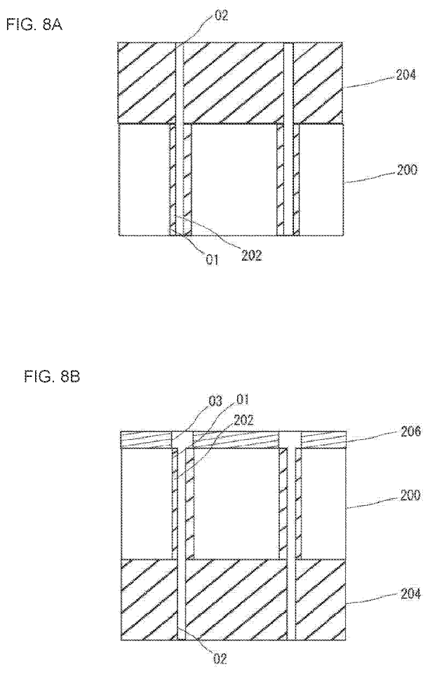

In the next step S4, as illustrated in FIG. 7D, an insulating film 204 to be the second insulating layer 110a is formed on the back surface of the semiconductor substrate 200, and as illustrated in FIG. 8A, a second opening O2 corresponding to the central part in the first opening O1 is formed in the insulating film 204 by etching.

In the next step S5, as illustrated in FIG. 8B, the insulating film 206 to be the insulating layer 120A of the wiring layer 125 is formed on the surface of the semiconductor substrate 200, and a third opening O3 corresponding to the first opening O1 is formed in the insulating film 206 by etching.

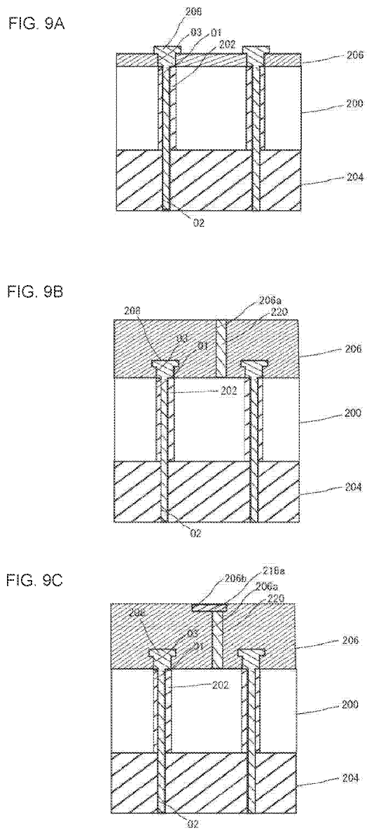

In the next step S6, as illustrated in FIG. 9A, the metal material 208 to be the partition wall 150 is embedded in the third opening O3, the central part in the first opening O1, and the second opening O2. Specifically, the metal material 208 is injected from the third opening O3.

Next, in step S7, as illustrated in FIG. 9B, the insulating film 206 is further deposited on the surface side of the semiconductor substrate 200, then an opening 206a for cathode contact is formed in the insulating film 206, and a metal material 220 to be the metal member 165 is embedded in the opening 206a.

In the next step S7.5, as illustrated in FIG. 9C, the insulating film 206 is further thinly deposited and planarized, a recess 206b that communicates with the opening 206a is formed in the insulating film 206, and a metal material 218a to be the wiring member 170a is embedded in the recess 206b. As a result, the cathode region of the epitaxial layer formed on the semiconductor substrate 200 and the metal material 218a are connected via the metal material 220.

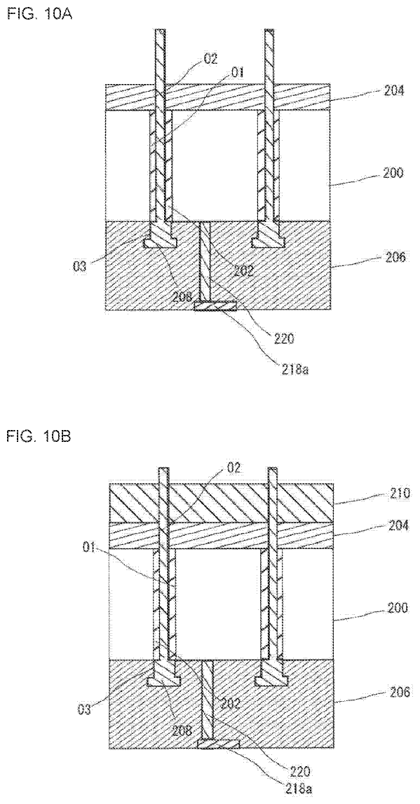

In the next step S8, as illustrated in FIG. 10A, the insulating film 204 on the back surface side of the semiconductor substrate 200 is etched back to expose a part of the metal material 208.

In the next step S9, as shown in FIG. 10B, a color filter 210 to be the color filter layer 110b is embedded in a region surrounded by the exposed metal material 208.

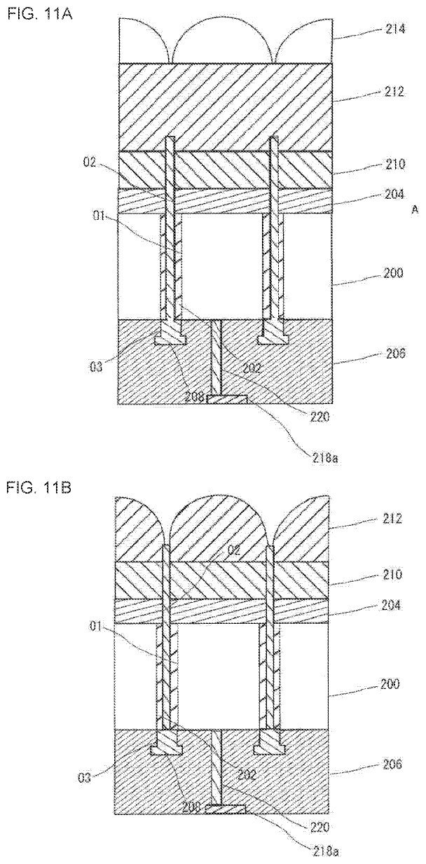

In the next step S10, as illustrated in FIG. 11A, a lens film 212 is formed on the color filter 210, and a resist 214 is applied onto the lens film 212. Then, a hemispherical on-chip lens to be the lens layer 110c is formed by lithography.

In the next step S11, as illustrated in FIG. 11B, the lens film 212 is etched back to position the on-chip lens immediately above the color filter 210.

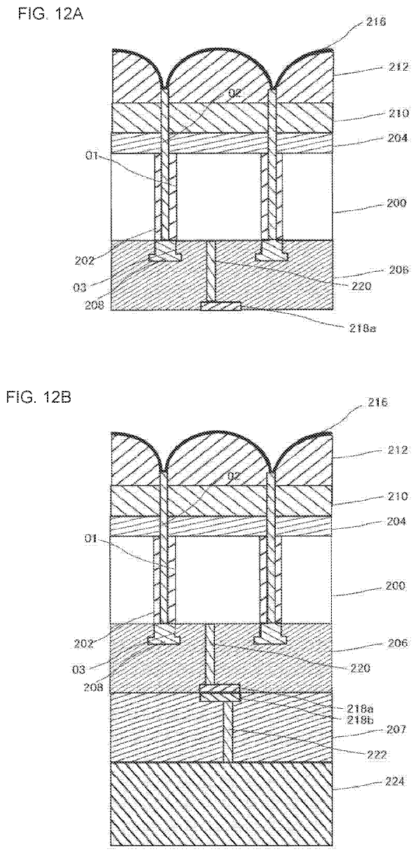

In the next step S12, as illustrated in FIG. 12A, a thermal conductive film 216 to be the thermal conductive layer 110d is formed on the on-chip lens to be brought into contact with the metal material 208.

In the next step S13, the pixel sensor substrate 115 and the logic substrate 180 are bonded together. Specifically, the insulating film 206 to be the insulating layer 120A of the wiring layer 125 of the pixel sensor substrate 115 and the insulating film 207 to be the insulating layer 120B of the wiring layer 180b of the logic substrate 180 are bonded together. At this time, as illustrated in FIG. 12B, the insulating film 206 and the insulating film 207 are bonded together so that the metal material 218a to be the wiring member 170a of the pixel sensor substrate 115 and the metal material 218b to be the wiring member 170b of the logic substrate 180 are joined each other.

Note that the metal material 222 to be the metal member 175 of the logic substrate 180 and the metal material 218b to be the wiring member 170b of the logic substrate 180 are embedded in the insulating film 207 by a method similar to that in the steps S7 and S7.5.

Note that, although not illustrated, the pixel sensor substrate 115 and the logic substrate 180 can be bonded together in a state where the logic substrate 180 is supported by the support substrate 190 in advance, or the logic substrate 180 can be supported by the support substrate 190 after the pixel sensor substrate 115 and the logic substrate 180 are bonded together.

The method for manufacturing the solid-state image pickup device 1000 according to the first embodiment of the present technology described above includes the steps of: forming a first opening O1 (opening) in a semiconductor substrate 200 in which a photoelectric converter 105 is to be formed; embedding an insulating material 202 in a peripheral part in the first opening O1; arranging an insulating film 204 on the semiconductor substrate 200; forming a second opening O2 (another opening) that communicates with a central part in the first opening O1 in the insulating film 204; embedding a metal material 208 in the central part in the first opening O1 and the second opening O2; and arranging a thermal conductive film 216 on a side opposite to the semiconductor substrate 200 of the insulating film 204.

In this case, a solid-state image pickup device 1000 having an excellent heat dissipation property can be efficiently manufactured.

In the step of arranging the thermal conductive film 216, the thermal conductive film 216 is arranged to brought into in contact with (directly connected to) the metal material 208 embedded in the second opening O2.

In this case, a solid-state image pickup device 1000 having a remarkably excellent heat dissipation property can be efficiently manufactured.

Hereinafter, although a solid-state image pickup device according to other embodiments (second to 41st embodiments) of the present technology will be described, the thermal conductive layer of the solid-state image pickup device of each of the second to 41st embodiments can have a configuration and a function similar to those of the thermal conductive layer 110d of the solid-state image pickup device 1000 of the first embodiment.

<4. Solid-State Image Pickup Device According to Second Embodiment of Present Technology>

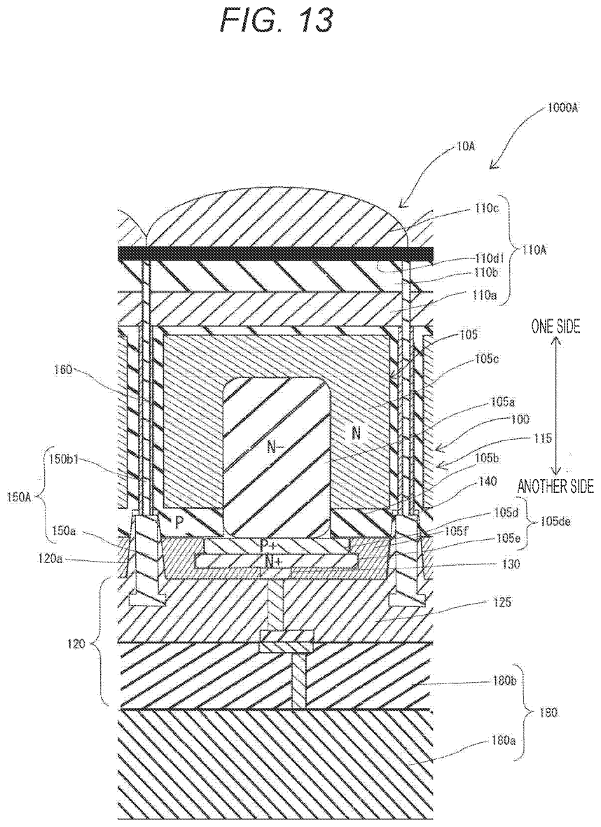

Next, a solid-state image pickup device 1000A according to the second embodiment of the present technology will be described with reference to FIG. 13 and the like. The solid-state image pickup device 1000A according to the second embodiment includes a plurality of pixels 10A arranged two-dimensionally, similarly to the solid-state image pickup device 1000 of the first embodiment.

Each pixel 10A has a substantially similar configuration to the pixel 10 of the solid-state image pickup device 1000 of the first embodiment except that the arrangement of the thermal conductive layer is different.

Specifically, in the pixel 10A, a thermal conductive layer 110d1 is arranged between the lens layer 110c and the color filter layer 110b. That is, the thermal conductive layer 110d1 constitutes an inner layer of the stacked part 110A (an inner layer of the solid-state image pickup device 1000A).

The tip of the extending part 150b1 of a partition wall 150A is in contact with the thermal conductive layer 110d1.

In the solid-state image pickup device 1000A of the second embodiment, the heat generated in the electron multiplication region 105de and the logic substrate 180 is transferred to the thermal conductive layer 110d1 mainly via the partition wall 150A, moves toward the end surface of the thermal conductive layer 110d1 along the thermal conductive layer 110d1 in the thermal conductive layer 110d1, and is released from the end surface to the outside.

As described above, in the solid-state image pickup device 1000A, the thermal conductive layer 110d1 is not exposed, and heat dissipation occurs mainly from the end surface of the thermal conductive layer 110d1.

According to the solid-state image pickup device 1000A of the second embodiment, because the thermal conductive layer 110d1 is positioned closer to the electron multiplication region 105de and the logic substrate 180 which are heat sources, heat from the heat sources can be more quickly conveyed to the thermal conductive layer 110d1.

A method for manufacturing the solid-state image pickup device 1000A of the second embodiment will be briefly described.

The solid-state image pickup device 1000A is manufactured by a method according to the method for manufacturing the solid-state image pickup device 1000 of the first embodiment (method illustrated in FIGS. 5 and 6).

Specifically, the solid-state image pickup device 1000A is manufactured in a procedure substantially similar to the flowcharts illustrated in FIGS. 5 and 6.

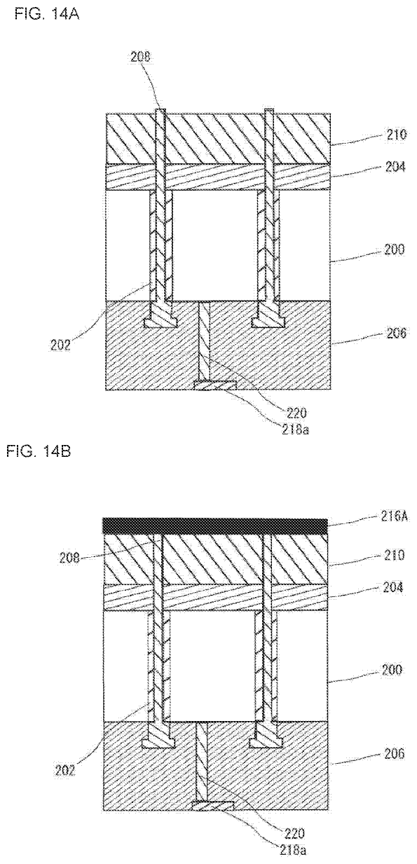

More specifically, in manufacturing the solid-state image pickup device 1000A, after the steps S1 to S8 are performed, the protrusion amount of the protruding part of the metal material 208 from the color filter 210 is reduced as illustrated in FIG. 14A when the color filter 210 is embedded in the region surrounded by the exposed metal material 208 in the step S9.

Next, as illustrated in FIG. 14B, a thermal conductive film 216A to be the thermal conductive layer 110d1 is formed on the color filter 210 and the protruding part of the metal material 208 (see FIG. 14A).

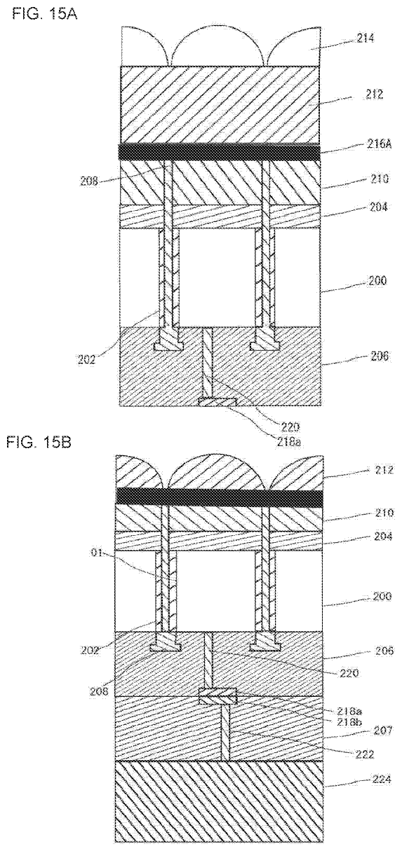

Next, as illustrated in FIG. 15A, a lens film 212 and a resist 214 for forming the lens layer 110c (on-chip lens) are formed on the thermal conductive film 216A.

Next, as illustrated in FIG. 15B, after an on-chip lens is formed by lithography, the lens film 212 is etched backed to position the on-chip lens immediately above the thermal conductive film 216A. Thereafter, the pixel sensor substrate 115 and the logic substrate 180 are bonded together in a manner similar to that in the step S13.

<5. Solid-State Image Pickup Device According to Third Embodiment of Present Technology>

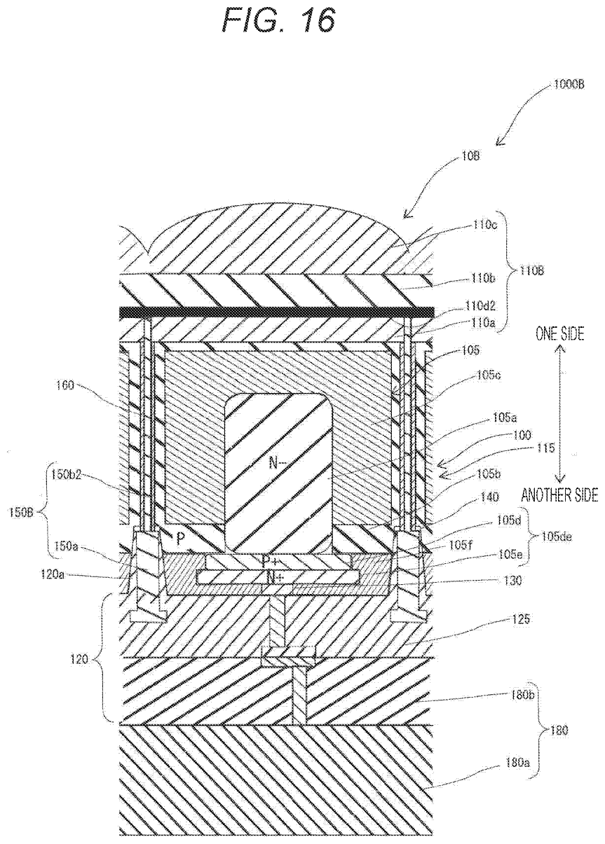

Next, a solid-state image pickup device 1000B according to the third embodiment of the present technology will be described with reference to FIG. 16 and the like. A solid-state image pickup device 1000B according to the third embodiment includes a plurality of pixels 10B arranged two-dimensionally, similarly to the solid-state image pickup device 1000 of the first embodiment.

Each pixel 10B has a substantially similar configuration to the pixel 10 of the solid-state image pickup device 1000 of the first embodiment except that the arrangement of the thermal conductive layer is different.

Specifically, in the pixel 10B, the thermal conductive layer 110d2 is arranged between the color filter layer 110b and the second insulating layer 110a. That is, the thermal conductive layer 110d2 constitutes an inner layer of the stacked part 110B (an inner layer of the solid-state image pickup device 1000B).

The tip of the extending part 150b2 of a partition wall 150B is in contact with the thermal conductive layer 110d2.

In the solid-state image pickup device 1000B of the third embodiment, the heat generated in the electron multiplication region 105de and the logic substrate 180 is transferred to the thermal conductive layer 110d2 mainly via the partition wall 150B, moves toward the end surface of the thermal conductive layer 110d2 along the thermal conductive layer 110d2 in the thermal conductive layer 110d2, and is released from the end surface to the outside.

As described above, in the solid-state image pickup device 1000B, the thermal conductive layer 110d2 is not exposed, and heat dissipation occurs mainly from the end surface of the thermal conductive layer 110d2.

According to the solid-state image pickup device 1000B of the third embodiment, because the thermal conductive layer 110d2 is positioned further closer to the electron multiplication region 105de and the logic substrate 180 which are heat sources, heat from the heat sources can be further more quickly conveyed to the thermal conductive layer 110d2.

A method for manufacturing the solid-state image pickup device 1000B of the third embodiment will be briefly described.

The solid-state image pickup device 1000B is manufactured by a method according to the method for manufacturing the solid-state image pickup device 1000 of the first embodiment (method illustrated in FIGS. 5 and 6).

Specifically, the solid-state image pickup device 1000B is manufactured in a procedure substantially similar to the flowcharts illustrated in FIGS. 5 and 6.

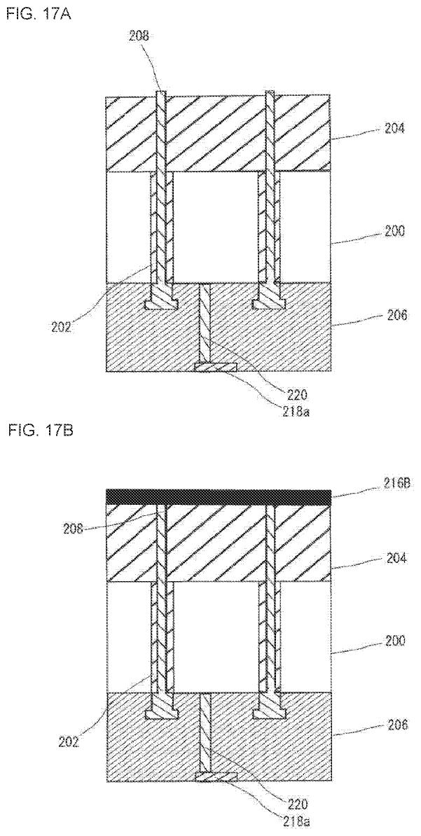

More specifically, in manufacturing the solid-state image pickup device 1000B, after the steps S1 to S7 are performed, the amount of etch-back when the insulating film 204 on the back surface side of the semiconductor substrate 100 is etched back is reduced to reduce the protrusion amount of the protruding part of the metal material 208 from the insulating film 204 in step S8, as illustrated in FIG. 17A.

Next, as illustrated in FIG. 17B, a thermal conductive film 216B to be the thermal conductive layer 110d2 is formed on the insulating film 204 and the protruding part of the metal material 208.

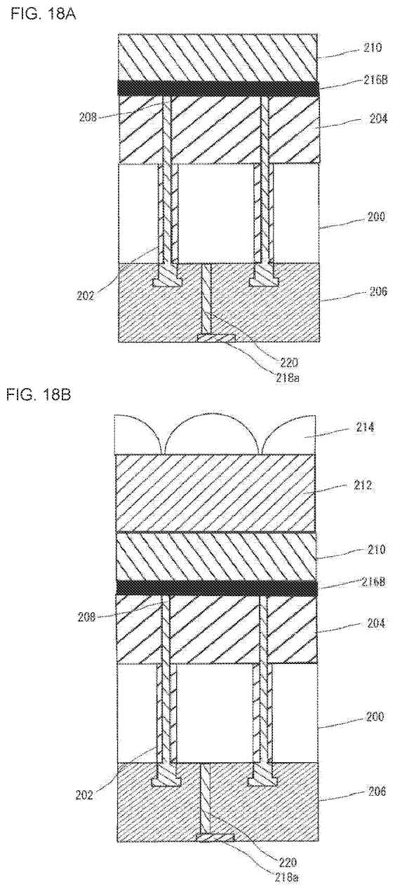

Next, as illustrated in FIG. 18A, a color filter 210 is formed on the thermal conductive film 216B.

Next, as illustrated in FIG. 18B, a lens film 212 and a resist 214 are formed on the color filter 210.

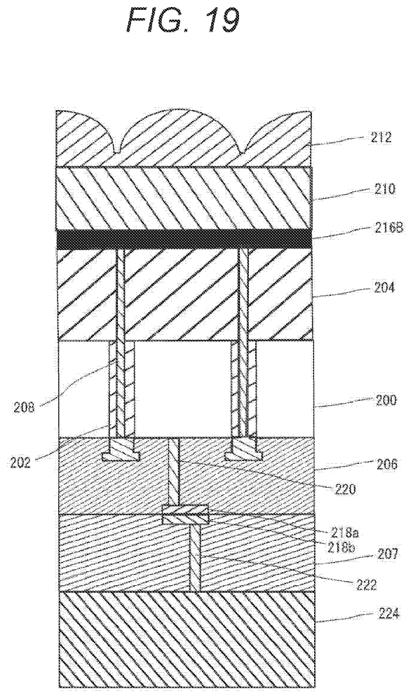

Next, as illustrated in FIG. 19, after an on-chip lens is formed by lithography, the lens film 212 is etched backed to position the on-chip lens immediately above the color filter 210. Thereafter, the pixel sensor substrate 115 and the logic substrate 180 are bonded together in a manner similar to that in the step S13.

<6. Solid-State Image Pickup Device According to Fourth Embodiment of Present Technology>

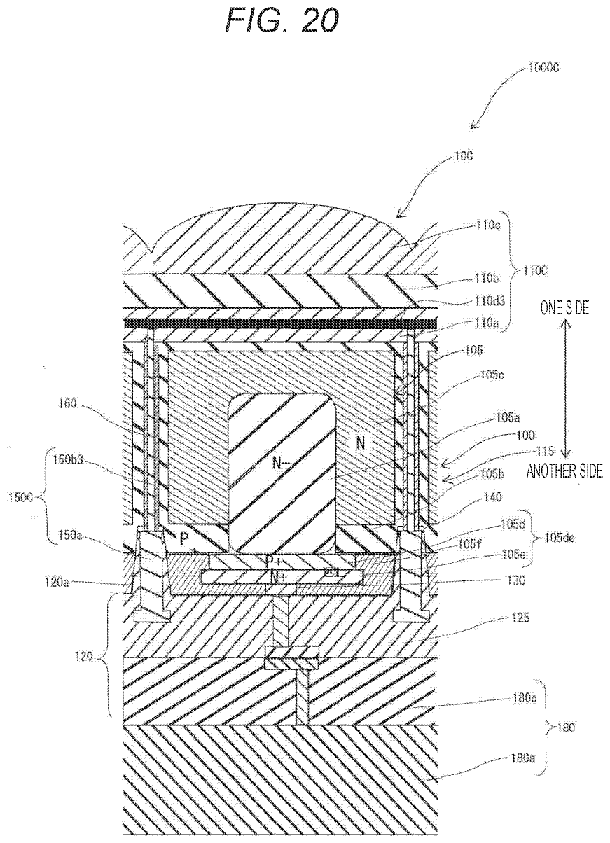

Next, a solid-state image pickup device 1000C according to the fourth embodiment of the present technology will be described with reference to FIG. 20 and the like. A solid-state image pickup device 1000C according to the fourth embodiment includes a plurality of pixels 10C arranged two-dimensionally, similarly to the solid-state image pickup device 1000 of the first embodiment.

Each pixel 10C has a configuration substantially similar to that of the pixel 10 of the solid-state image pickup device 1000 of the first embodiment except that the arrangement of the thermal conductive layer is different.

Specifically, in the pixel 10C, a thermal conductive layer 110d3 is arranged in the second insulating layer 110a. That is, the thermal conductive layer 110d3 constitutes an inner layer of the stacked part 110C (an inner layer of the solid-state image pickup device 1000C).

The tip of the extending part 150b3 of a partition wall 150C is in contact with the thermal conductive layer 110d3.

In the solid-state image pickup device 1000C of the fourth embodiment, the heat generated in the electron multiplication region 105de and the logic substrate 180 is transferred to the thermal conductive layer 110d3 mainly via the partition wall 150C, moves toward the end surface of the thermal conductive layer 110d3 along the thermal conductive layer 110d3 in the thermal conductive layer 110d3, and is released from the end surface to the outside.

As described above, in the solid-state image pickup device 1000C, the thermal conductive layer 110d3 is not exposed, and heat dissipation occurs mainly from the end surface of the thermal conductive layer 110d3.

According to the solid-state image pickup device 1000C of the fourth embodiment, because the thermal conductive layer 110d3 is positioned further closer to the electron multiplication region 105de and the logic substrate 180 which are heat sources, heat from the heat sources can be further more quickly conveyed to the thermal conductive layer 110d3.

A method for manufacturing the solid-state image pickup device 1000C of the fourth embodiment will be briefly described.

The solid-state image pickup device 1000C is manufactured by a method according to the method for manufacturing the solid-state image pickup device 1000 (method illustrated in FIGS. 5 and 6).

Specifically, the solid-state image pickup device 1000C is manufactured in a procedure substantially similar to the flowcharts illustrated in FIGS. 5 and 6.

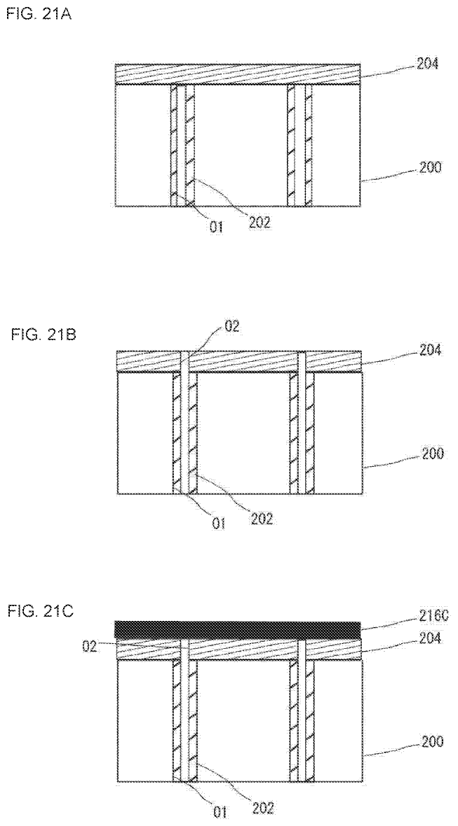

More specifically, in manufacturing the solid-state image pickup device 1000C, after the steps S1 to S3 are performed, the insulating film 204 is thinly formed on the back surface of the semiconductor substrate 200 in the step S4, as illustrated in FIG. 21A.

Next, as illustrated in FIG. 21B, a second opening O2 corresponding to the central part in the first opening O1 is formed in the insulating film 204.

Next, as illustrated in FIG. 21C, a thermal conductive film 216C to be the thermal conductive layer 110d3 is formed on the insulating film 204.

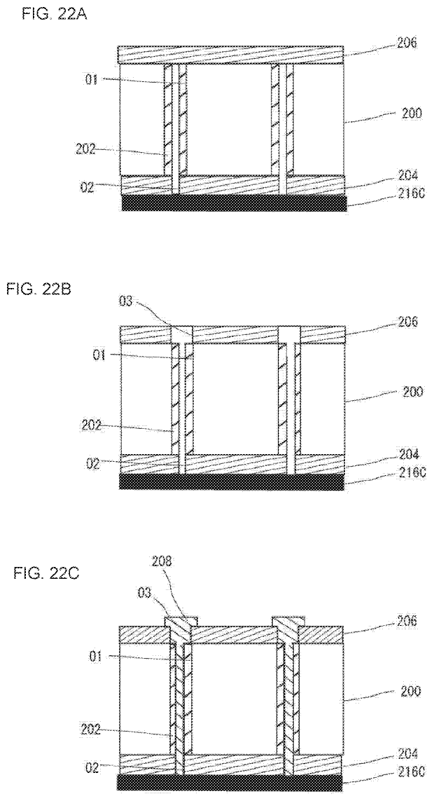

Next, as illustrated in FIG. 22A, an insulating film 206 is formed on the surface of the semiconductor substrate 200.

Next, as illustrated in FIG. 22B, a third opening O3 corresponding to the first opening O1 is formed in the insulating film 206.

Next, as illustrated in FIG. 22C, the metal material 208 is embedded in the central part in the first opening O1, the second opening O2, and the third opening O3. At this time, the metal material 208 embedded in the second opening O2 is brought into contact with the thermal conductive film 216C.

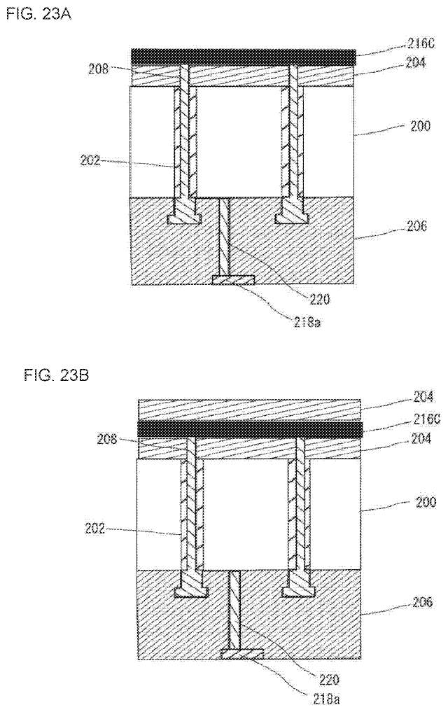

Next, as illustrated in FIG. 23A, an insulating film 206 is further deposited on the surface side of the semiconductor substrate 200 and planarized.

Next, as illustrated in FIG. 23B, an insulating film 204 is formed on the thermal conductive film 216C.

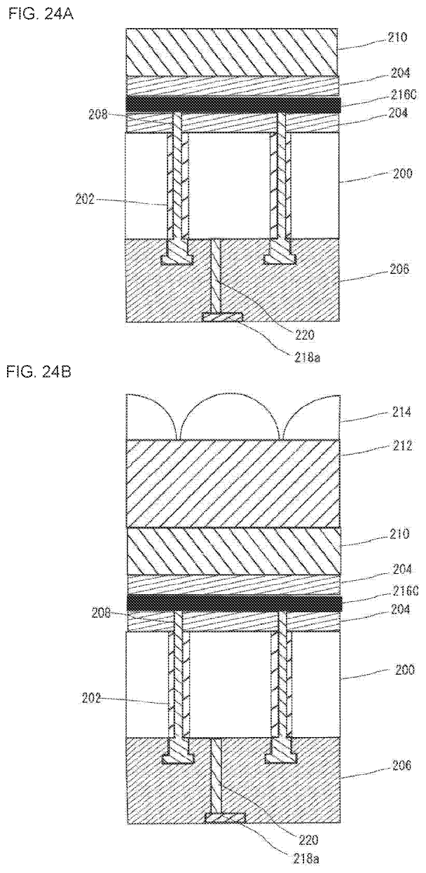

Next, as illustrated in FIG. 24A, a color filter 210 is formed on the insulating film 204.

Next, as illustrated in FIG. 24B, a lens film 212 and a resist 214 are formed on the color filter 210.

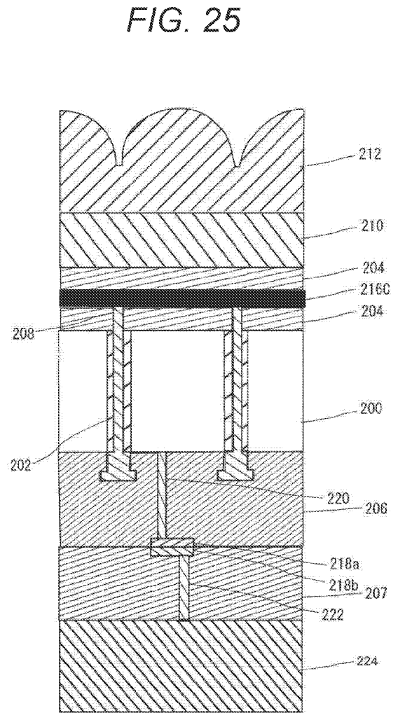

Next, as illustrated in FIG. 25, after an on-chip lens is formed by lithography, the lens film 212 is etched backed to position the on-chip lens immediately above the color filter 210. Thereafter, the pixel sensor substrate 115 and the logic substrate 180 are bonded together in a manner similar to that in the step S13.

<7. Solid-State Image Pickup Device According to Fifth Embodiment of Present Technology>

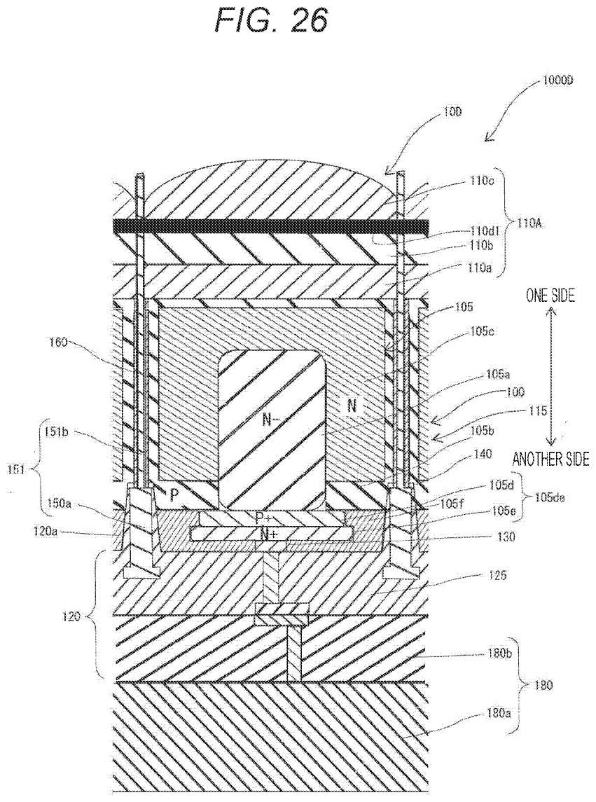

Next, a solid-state image pickup device 1000D according to the fifth embodiment of the present technology will be described with reference to FIG. 26. A solid-state image pickup device 1000D according to the fifth embodiment includes a plurality of pixels 10D arranged two-dimensionally, similarly to the solid-state image pickup device 1000A of the second embodiment.

As illustrated in FIG. 26, each pixel 10D has a configuration substantially similar to that of the pixel 10A of the solid-state image pickup device 1000A of the second embodiment except that a partition wall 151 penetrates the thermal conductive layer 110d1.

Specifically, the extending part 151b of the partition wall 151 penetrates the thermal conductive layer 110d1 with the extending part 151b being in contact with the thermal conductive layer 110d1, and the tip is positioned on the side part of the lens layer 110c (exposed).

The solid-state image pickup device 1000D can be manufactured by a method substantially similar to the method for manufacturing the solid-state image pickup device 1000 of the first embodiment. However, by adjusting the film thickness and the etch-back amount of the insulating film 204 to be the second insulating layer 110a to make the protrusion amount of the metal material 208 from the insulating film 204 larger than that in manufacturing the solid-state image pickup device 1000A, the partition wall 151 can penetrate the thermal conductive layer 110d1 with the partition wall 151 being in contact with the thermal conductive layer 110d1 as described above.

According to the solid-state image pickup device 1000D of the fifth embodiment, the effects similar to those of the solid-state image pickup device 1000A are exhibited, the partition wall 151 can be more reliably brought into contact with the thermal conductive layer 110d1, and heat can be released from the exposed tip of the partition wall 151 to the outside.

Here, although the tip of the partition wall 151 that penetrates the thermal conductive layer 110d1 is exposed to the outside, it can be unexposed.

Note that also in the first, third, and fourth embodiments, the partition wall can penetrate the thermal conductive layer.

<8. Solid-State Image Pickup Device According to Sixth Embodiment of Present Technology>

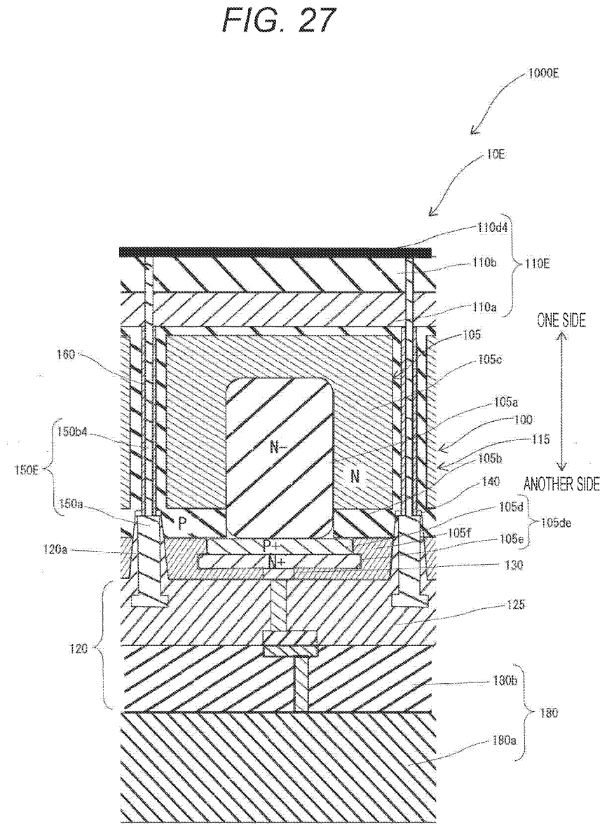

Next, a solid-state image pickup device 1000E according to the sixth embodiment of the present technology will be described with reference to FIG. 27. A solid-state image pickup device 1000E according to the sixth embodiment includes a plurality of pixels 10E arranged two-dimensionally, similarly to the solid-state image pickup device 1000A of the second embodiment.

As illustrated in FIG. 27, each pixel 10E has a configuration substantially similar to that of the pixel 10A of the solid-state image pickup device 1000A of the second embodiment except that the stacked part 110E does not include the lens layer 110c. Although such a pixel structure without the lens layer 110c is inferior in light condensing property to the at least one photoelectric converter 105, it can be manufactured at low cost.

That is, in the pixel 10E, a thermal conductive layer 110d4 is a surface layer of the stacked part 110E (a surface layer of the solid-state image pickup device 1000E), and the color filter layer 110b is arranged immediately below the thermal conductive layer 110d4. In addition, the tip of the extending part 150b4 of a partition wall 150E is in contact with the thermal conductive layer 110d4.

In the solid-state image pickup device 1000D of the sixth embodiment, the heat generated in the electron multiplication region 105de and the logic substrate 180 is transferred to the thermal conductive layer 110d4 which is a surface layer mainly via the partition wall 150E, and is released from the surface and the end surface of the thermal conductive layer 110d4.

The solid-state image pickup device 1000E of the sixth embodiment can also be manufactured by a method substantially similar to the method for manufacturing the solid-state image pickup device 1000A of the second embodiment (however, the step of forming the lens layer 110c is excluded).

<9. Solid-State Image Pickup Device According to Seventh Embodiment of Present Technology>

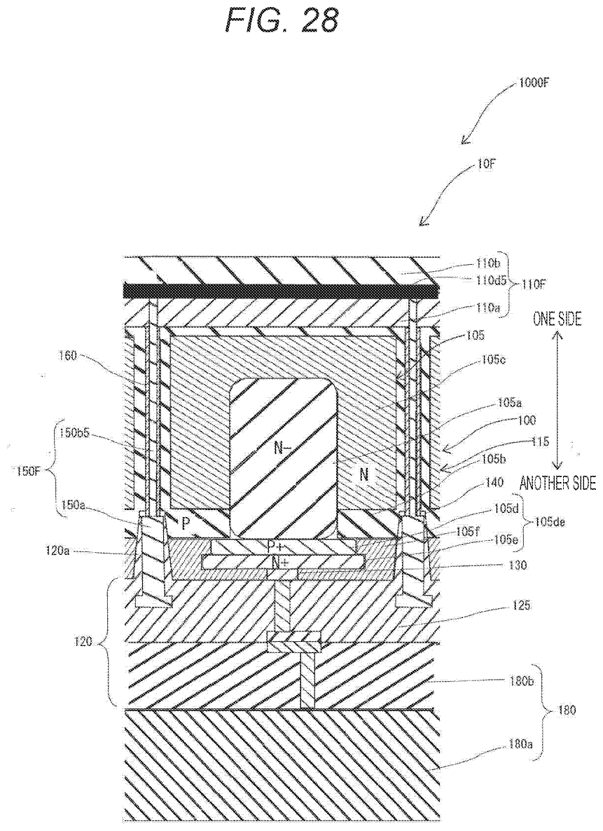

Next, a solid-state image pickup device 1000F according to the seventh embodiment of the present technology will be described with reference to FIG. 28. A solid-state image pickup device 1000F according to the seventh embodiment includes a plurality of pixels 10F arranged two-dimensionally, similarly to the solid-state image pickup device 1000B of the third embodiment.

As illustrated in FIG. 28, each pixel 10F has a configuration substantially similar to that of the pixel 10B of the solid-state image pickup device 1000B of the third embodiment except that the stacked part 110F does not include the lens layer 110c.

That is, in the pixel 10F, the color filter layer 110b is a surface layer of the stacked part 110F (a surface layer of the solid-state image pickup device 1000F), and a thermal conductive layer 110d5 is arranged immediately below the color filter layer 110b. That is, the thermal conductive layer 110d5 is an inner layer of the stacked part 110F (an inner layer of the solid-state image pickup device 1000F).

The tip of the extending part 150b5 of a partition wall 150F is in contact with the thermal conductive layer 110d5.

In the solid-state image pickup device 1000F of the seventh embodiment, the heat generated in the electron multiplication region 105de and the logic substrate 180 is transferred to the thermal conductive layer 110d5 which is an inner layer mainly via the partition wall 150F, and is released from the end surface of the thermal conductive layer 110d5 to the outside.

The solid-state image pickup device 1000F of the seventh embodiment can also be manufactured by a method substantially similar to the method for manufacturing the solid-state image pickup device 1000B of the third embodiment (however, the step of forming the lens layer 110c is excluded).

<10. Solid-State Image Pickup Device According to Eighth Embodiment of Present Technology>

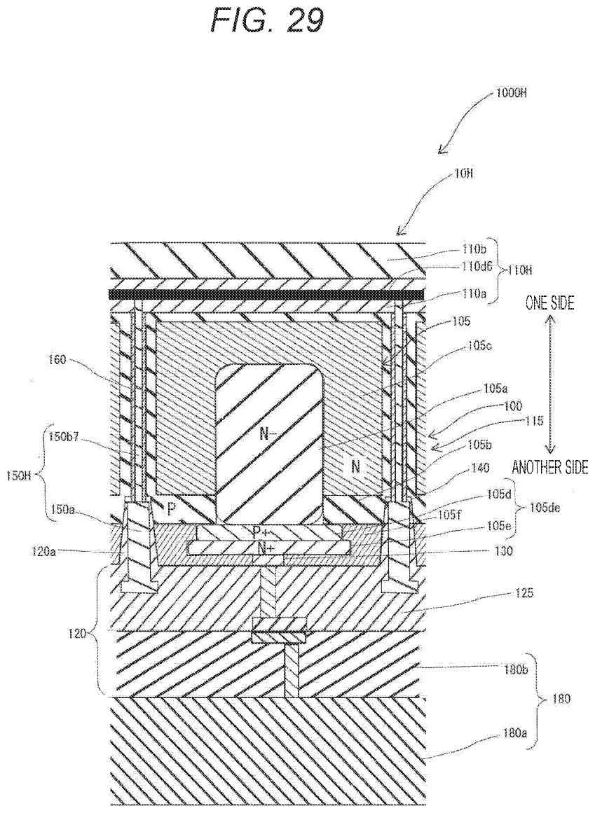

Next, a solid-state image pickup device 1000H according to an eighth embodiment of the present technology will be described with reference to FIG. 29. A solid-state image pickup device 1000H according to the eighth embodiment includes a plurality of pixels 10H arranged two-dimensionally, similarly to the solid-state image pickup device 1000C of the fourth embodiment.

As illustrated in FIG. 29, each pixel 10H has a configuration substantially similar to that of the pixel 10C of the solid-state image pickup device 1000C of the fourth embodiment except that each pixel 10H does not have the lens layer 110c.

Specifically, in the pixel 10H, a thermal conductive layer 110d6 is arranged in the second insulating layer 110a. That is, the thermal conductive layer 110d6 is an inner layer of the stacked part 110H (an inner layer of the solid-state image pickup device 1000H).

The tip of the extending part 150b7 of a partition wall 150H is in contact with the thermal conductive layer 110d6.

In the solid-state image pickup device 1000H of the eighth embodiment, the thermal conductive layer 110d6 is not exposed, and heat dissipation occurs mainly from the end surface of the thermal conductive layer 110d6.

In the solid-state image pickup device 1000H, the heat generated in the electron multiplication region 105de and the logic substrate 180 is transferred to the thermal conductive layer 110d6 which is an inner layer mainly via the partition wall 150H, and is released from the end surface of the thermal conductive layer 110d6 to the outside.

The solid-state image pickup device 1000H of the eighth embodiment can also be manufactured by a method substantially similar to the method for manufacturing the solid-state image pickup device 1000C of the fourth embodiment (however, the step of forming the lens layer 110c is excluded).

<11. Solid-State Image Pickup Device According to Ninth Embodiment of Present Technology>

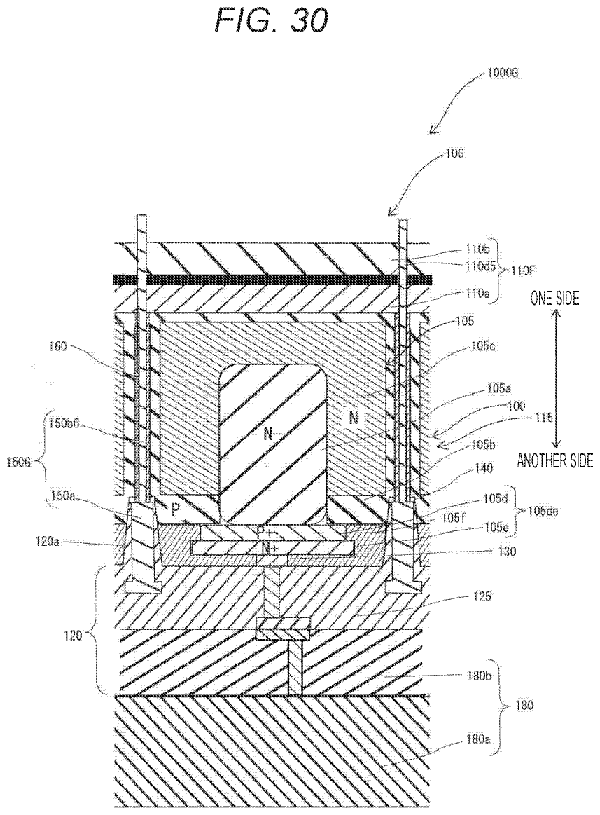

Next, a solid-state image pickup device 1000G according to the ninth embodiment of the present technology will be described with reference to FIG. 30. The solid-state image pickup device 1000G according to the ninth embodiment includes a plurality of pixels 10G arranged two-dimensionally, similarly to the solid-state image pickup device 1000F of the seventh embodiment.

As illustrated in FIG. 30, each pixel 10G has a configuration substantially similar to that of the pixel 10F of the solid-state image pickup device 1000F of the seventh embodiment except that a partition wall 150G penetrates the thermal conductive layer 110d5.

Specifically, the extending part 150b6 of the partition wall 150G penetrates the thermal conductive layer 110d5 with the extending part 150b6 being in contact with the thermal conductive layer 110d5, and the tip protrudes onto the color filter layer 110b. That is, the tip of the partition wall 150G is exposed.

A solid-state image pickup device 1000G can be manufactured by a method substantially similar to the method for manufacturing the solid-state image pickup device 1000F of the seventh embodiment. However, by adjusting the film thickness and the etch-back amount of the insulating film 204 to be the second insulating layer 110a to make the protrusion amount of the metal material 208 from the insulating film 204 larger than that in manufacturing the solid-state image pickup device 1000F, the partition wall 150G can penetrate the thermal conductive layer 110d5 with the partition wall 150G being in contact with the thermal conductive layer 110d5 as described above.

According to the solid-state image pickup device 1000G of the ninth embodiment, the effects similar to those of the solid-state image pickup device 1000F are exhibited, the partition wall 150G can be more reliably brought into contact with the thermal conductive layer 110d5, and heat can be released from the exposed tip of the partition wall 150G to the outside.

Here, although the tip of the partition wall 150G that penetrates the thermal conductive layer 110d5 is exposed, it can be unexposed.

Note that also in the sixth embodiment and the eighth embodiment, the partition wall can penetrate the thermal conductive layer with the partition wall being in contact with the thermal conductive layer.

<12. Solid-State Image Pickup Device According to 10th Embodiment of Present Technology>

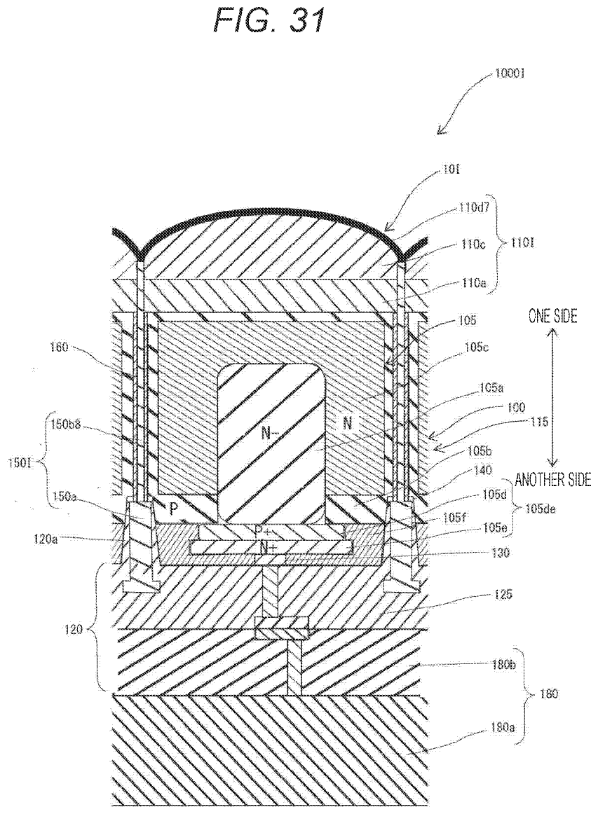

Next, a solid-state image pickup device 1000I according to the 10th embodiment of the present technology will be described with reference to FIG. 31. The solid-state image pickup device 1000I according to the 10th embodiment includes a plurality of pixels 10I arranged two-dimensionally, similarly to the solid-state image pickup device 1000 of the first embodiment.

As illustrated in FIG. 31, each pixel 10I has a configuration substantially similar to that of the pixel 10 of the first embodiment except that the stacked part 110I does not have the color filter layer 110b.

Such a pixel structure without the color filter layer 110b can be used, for example, for an application of outputting a black-and-white image, a ranging application, and the like.

Specifically, in the pixel 10I, the lens layer 110c is arranged immediately below a thermal conductive layer 110d7, and the second insulating layer 110a is arranged immediately below the lens layer 110c. That is, the thermal conductive layer 110d7 constitutes a surface layer of the stacked part 110I (a surface layer of the solid-state image pickup device 1000I).

The tip of the extending part 150b8 of a partition wall 150I is in contact with the thermal conductive layer 110d7.

In the solid-state image pickup device 1000I of the 10th embodiment, the heat generated in the electron multiplication region 105de and the logic substrate 180 is transferred to the thermal conductive layer 110d7 which is a surface layer mainly via the partition wall 150I, and is released from the surface and the end surface of the thermal conductive layer 110d7 to the outside.

The solid-state image pickup device 1000H of the 10th embodiment can also be manufactured by a method substantially similar to the method for manufacturing the solid-state image pickup device 1000 of the first embodiment (however, the step of forming the color filter layer 110b is excluded.).

<13. Solid-State Image Pickup Device According to 11th Embodiment of Present Technology>

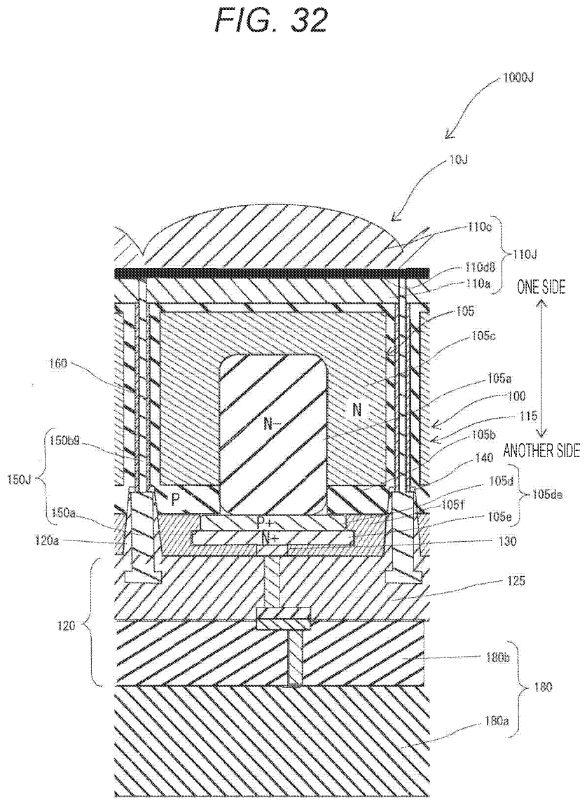

Next, a solid-state image pickup device 1000J according to the 11th embodiment of the present technology will be described with reference to FIG. 32. The solid-state image pickup device 1000J according to the 11th embodiment includes a plurality of pixels 10J arranged two-dimensionally, similarly to the solid-state image pickup device 1000B of the third embodiment.

As illustrated in FIG. 32, each pixel 10J has a configuration substantially similar to that of the pixel 10B of the solid-state image pickup device 1000B of the third embodiment except that the stacked part 110J does not have the color filter layer 110b.

Such a pixel structure without the color filter layer 110b can be used, for example, for an application of outputting a black-and-white image, a ranging application, and the like.

Specifically, in the pixel 10J, a thermal conductive layer 110d8 is arranged immediately below the lens layer 110c, and the second insulating layer 110a is arranged immediately below the thermal conductive layer 110d8. That is, the thermal conductive layer 110d8 constitutes an inner layer of the stacked part 110J (an inner layer of the solid-state image pickup device 1000J).

The tip of the extending part 150b9 of a partition wall 150J is in contact with the thermal conductive layer 110d8.

In the solid-state image pickup device 1000J of the 10th embodiment, the heat generated in the electron multiplication region 105de and the logic substrate 180 is transferred to the thermal conductive layer 110d8 which is an inner layer mainly via the partition wall 150J, and is released from the end surface of the thermal conductive layer 110d8 to the outside.

The solid-state image pickup device 1000J of the 11th embodiment can also be manufactured by a method substantially similar to the method for manufacturing the solid-state image pickup device 1000B of the third embodiment (however, the step of forming the color filter layer 110b is excluded.).

<14. Solid-State Image Pickup Device According to 12th Embodiment of Present Technology>

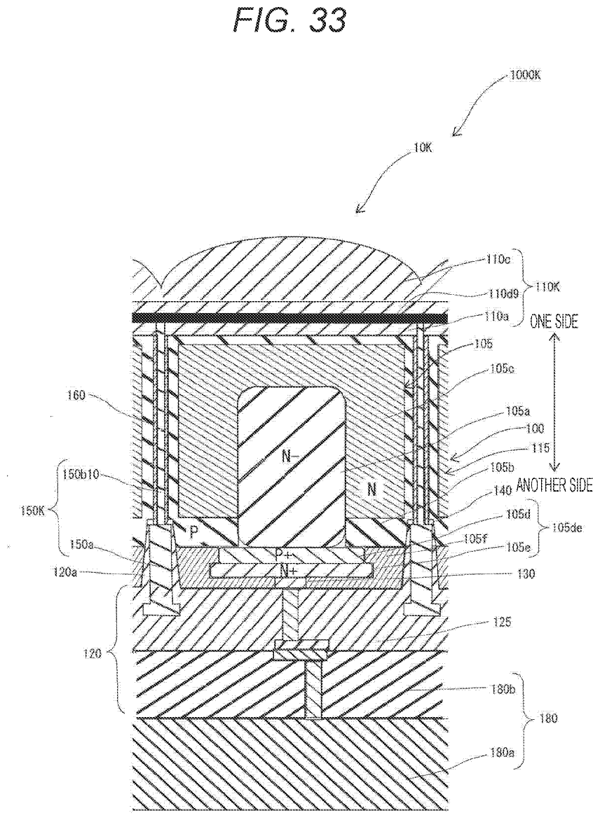

Next, a solid-state image pickup device 1000K according to the 12th embodiment of the present technology will be described with reference to FIG. 33. The solid-state image pickup device 1000K according to the 12th embodiment includes a plurality of pixels 10K arranged two-dimensionally, similarly to the solid-state image pickup device 1000C of the fourth embodiment.

As illustrated in FIG. 33, each pixel 10K has a configuration substantially similar to that of the pixel 10C of the solid-state image pickup device 1000C of the fourth embodiment except that the stacked part 110K does not have the color filter layer 110b.

Such a pixel structure without the color filter layer 110b can be used, for example, for an application of outputting a black-and-white image, a ranging application, and the like.

Specifically, in the pixel 10K, the second insulating layer 110a is arranged immediately below the lens layer 110c, and a thermal conductive layer 110d9 is arranged in the second insulating layer 110a. That is, the thermal conductive layer 110d9 constitutes an inner layer of the stacked part 110K (an inner layer of the solid-state image pickup device 1000K).

The tip of the extending part 150b10 of a partition wall 150K is in contact with the thermal conductive layer 110d9.

In the solid-state image pickup device 1000K of the 12th embodiment, the heat generated in the electron multiplication region 105de and the logic substrate 180 is transferred to the thermal conductive layer 110d9 which is an inner layer mainly via the partition wall 150K, and is released from the end surface of the thermal conductive layer 110d9 to the outside.

The solid-state image pickup device 1000K of the 12th embodiment can also be manufactured by a method substantially similar to the method for manufacturing the solid-state image pickup device 1000C of the fourth embodiment (however, the step of forming the color filter layer 110b is excluded.).

<15. Solid-State Image Pickup Device According to 13th Embodiment of Present Technology>

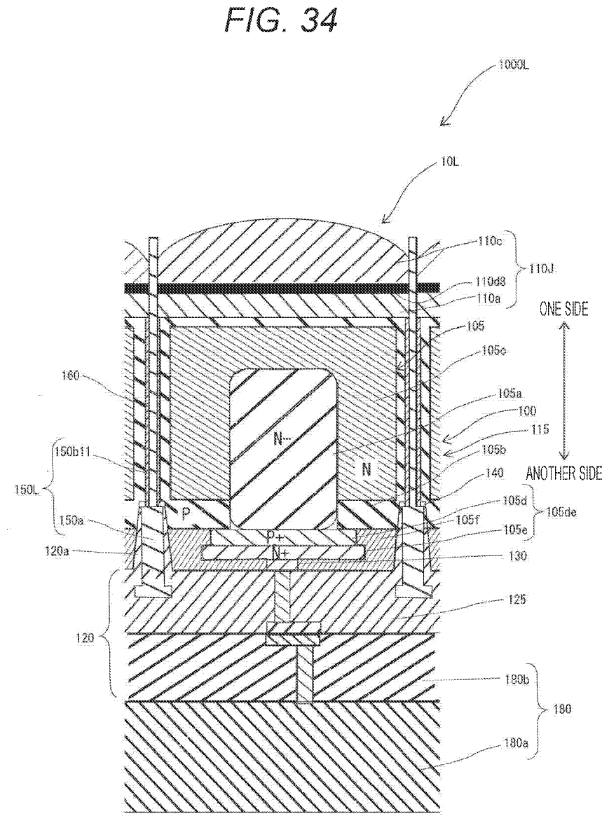

Next, a solid-state image pickup device 1000L according to the 13th embodiment of the present technology will be described with reference to FIG. 34. The solid-state image pickup device 1000L according to the 13th embodiment includes a plurality of pixels 10L arranged two-dimensionally, similarly to the solid-state image pickup device 1000J of the 11th embodiment.

As illustrated in FIG. 34, each pixel 10L has a configuration substantially similar to that of the pixel 10J of the solid-state image pickup device 1000J of the 11th embodiment except that a partition wall 150L penetrates the thermal conductive layer 110d8.

Specifically, the extending part 150b11 of the partition wall 150L penetrates the thermal conductive layer 110d8 with the extending part 150b11 being in contact with the thermal conductive layer 110d8, and the tip protrudes to the side part of the lens layer 110c. That is, the tip of the partition wall 150L is exposed.

The solid-state image pickup device 1000L can be manufactured by a manufacturing method substantially similar to that of the solid-state image pickup device 1000J of the 11th embodiment. However, by adjusting the film thickness and the etch-back amount of the insulating film 204 to be the second insulating layer 110a to make the protrusion amount of the metal material 208 from the insulating film 204 larger than that in manufacturing the solid-state image pickup device 1000J, the partition wall 150L can penetrate the thermal conductive layer 110d8 with the partition wall 150L being in contact with the thermal conductive layer 110d8 as described above.

According to the solid-state image pickup device 1000L of the 13th embodiment, the effects similar to those of the solid-state image pickup device 1000J are exhibited, the partition wall 150L can be more reliably brought into contact with the thermal conductive layer 110d8, and heat can be released from the exposed tip of the partition wall 150L to the outside.

Here, although the tip of the partition wall 150L that penetrates the thermal conductive layer 110d8 is exposed, it can be unexposed.

Note that also in the 10th embodiment and the 12th embodiment, the partition wall can penetrate the thermal conductive layer with the partition wall being in contact with the thermal conductive layer.

<16. Solid-State Image Pickup Device According to 14th Embodiment of Present Technology>

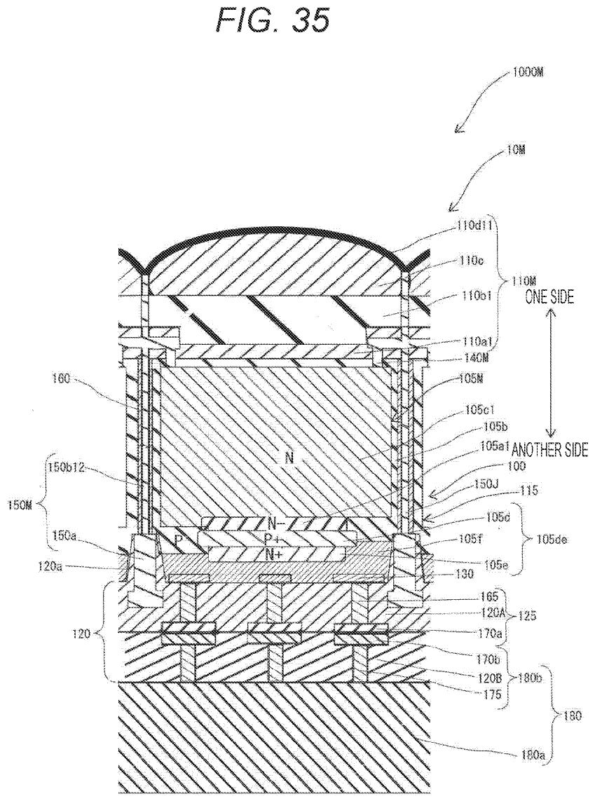

Next, a solid-state image pickup device 1000M according to the 14th embodiment of the present technology will be described with reference to FIG. 35. The solid-state image pickup device 1000M according to the 14th embodiment has a configuration of at least one photoelectric converter 105M and a stacked part 110M of each pixel 10M different from that of the solid-state image pickup device 1000 of the first embodiment.

More specifically, the solid-state image pickup device 1000M has a shape in which an anode electrode 140M is provided in a second insulating layer 110a1, and the second insulating layer 110a1 and a color filter layer 110b1 correspond thereto.

Furthermore, the solid-state image pickup device 1000M has a configuration in which the anode electrode 140M is in contact with the back surface side of the semiconductor substrate 100 (also referred to as “back surface contact”).

The anode electrode 140M is integrated with the extending part 150b12 of a partition wall 150M.

Here, an N− layer 105a1, which is a sensitive region, has a thin flat plate shape instead of a columnar shape, and the region occupied by an N layer 105c1 is increased accordingly.

In the stacked part 110M, the color filter layer 110b1 is arranged on the second insulating layer 110a1, the lens layer 110c is arranged on the color filter layer 110b1, and a thermal conductive layer 110d11 is arranged on the lens layer 110c. That is, the thermal conductive layer 110d11 is a surface layer of the stacked part 110M (a surface layer of the solid-state image pickup device 1000M).

The tip of the extending part 150b12 of the partition wall 150M is in contact with the thermal conductive layer 110d11.

According to the solid-state image pickup device 1000M, action and effects substantially similar to those of the solid-state image pickup device 1000 of the first embodiment are exhibited.

The solid-state image pickup device 1000M can be manufactured by a method according to the method for manufacturing the solid-state image pickup device 1000 of the first embodiment (however, the anode electrode 140M and the partition wall 150M need to be integrally formed with a metal material).

<17. Solid-State Image Pickup Device According to 15th Embodiment of Present Technology>

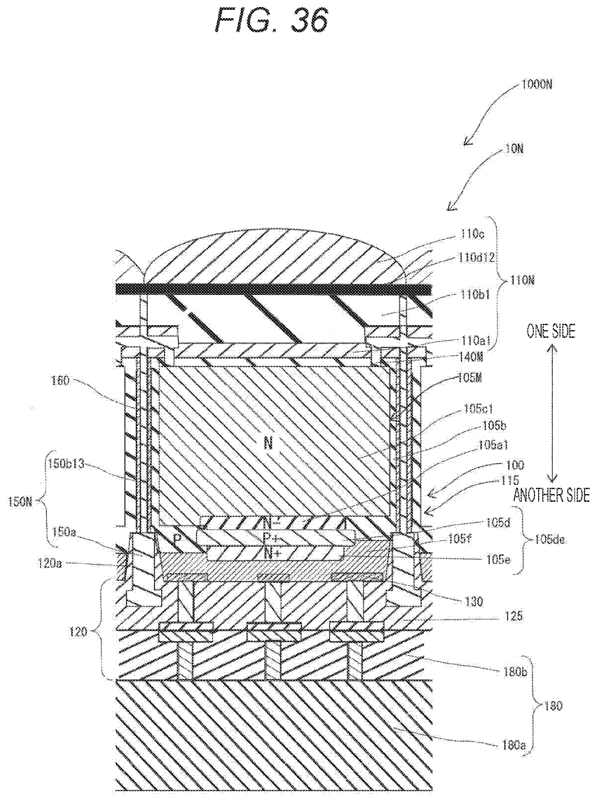

Next, a solid-state image pickup device 1000N according to the 15th embodiment of the present technology will be described with reference to FIG. 36. The solid-state image pickup device 1000N according to the 15th embodiment has a configuration of at least one photoelectric converter 105M and a stacked part 110N of each pixel different from that of the solid-state image pickup device 1000A of the second embodiment. From another viewpoint, the solid-state image pickup device 1000N according to the 15th embodiment has a configuration substantially similar to that of the solid-state image pickup device 1000M of the 14th embodiment except that the arrangement of the thermal conductive layer is different.

In the stacked part 110N of each pixel 10N of the solid-state image pickup device 1000N, the color filter layer 110b1 is arranged on the second insulating layer 110a1, a thermal conductive layer 110d12 is arranged on the color filter layer 110b1, and the lens layer 110c is arranged on the thermal conductive layer 110d12. That is, the thermal conductive layer 110d12 is an inner layer of the stacked part 110N (an inner layer of the solid-state image pickup device 1000N).

The tip of the extending part 150b13 of a partition wall 150N is in contact with the thermal conductive layer 110d12.

According to the solid-state image pickup device 1000N, action and effects substantially similar to those of the solid-state image pickup device 1000A of the second embodiment are exhibited.

The solid-state image pickup device 1000N can be manufactured by a method according to the method for manufacturing the solid-state image pickup device 1000A of the second embodiment and the method for manufacturing the solid-state image pickup device 1000M of the 14th embodiment.

<18. Solid-State Image Pickup Device According to 16th Embodiment of Present Technology>

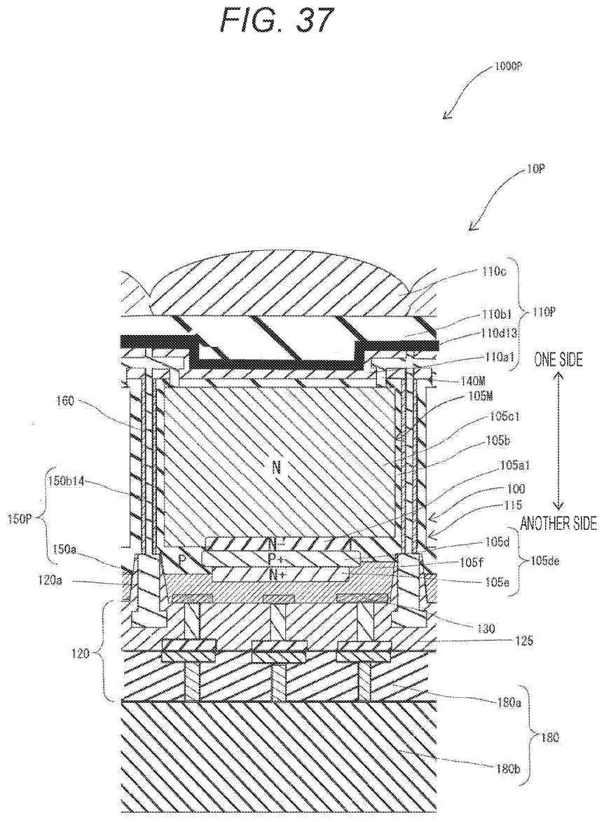

Next, a solid-state image pickup device 1000P according to the 16th embodiment of the present technology will be described with reference to FIG. 37. The solid-state image pickup device 1000P according to the 16th embodiment has a configuration of at least one photoelectric converter 105M and a stacked part 110P of each pixel different from that of the solid-state image pickup device 1000B of the third embodiment. From another viewpoint, the solid-state image pickup device 1000P according to the 16th embodiment has a configuration substantially similar to that of the solid-state image pickup device 1000M of the 14th embodiment except that the arrangement of the thermal conductive layer is different.

In the stacked part 110P of each pixel 10P of the solid-state image pickup device 1000P, a thermal conductive layer 110d13 is arranged on the second insulating layer 110a1, the color filter layer 110b1 is arranged on the thermal conductive layer 110d13, and the lens layer 110c is arranged on the color filter layer 110b1. That is, the thermal conductive layer 110d13 is an inner layer of the stacked part 110P (an inner layer of the solid-state image pickup device 1000P).

The tip of the extending part 150b14 of a partition wall 150P is in contact with the thermal conductive layer 110d13.

According to the solid-state image pickup device 1000P, action and effects substantially similar to those of the solid-state image pickup device 1000B of the third embodiment are exhibited.

The solid-state image pickup device 1000P can be manufactured by a method according to the method for manufacturing the solid-state image pickup device 1000B of the third embodiment and the method for manufacturing the solid-state image pickup device 1000M of the 14th embodiment.

<19. Solid-State Image Pickup Device According to 17th Embodiment of Present Technology>

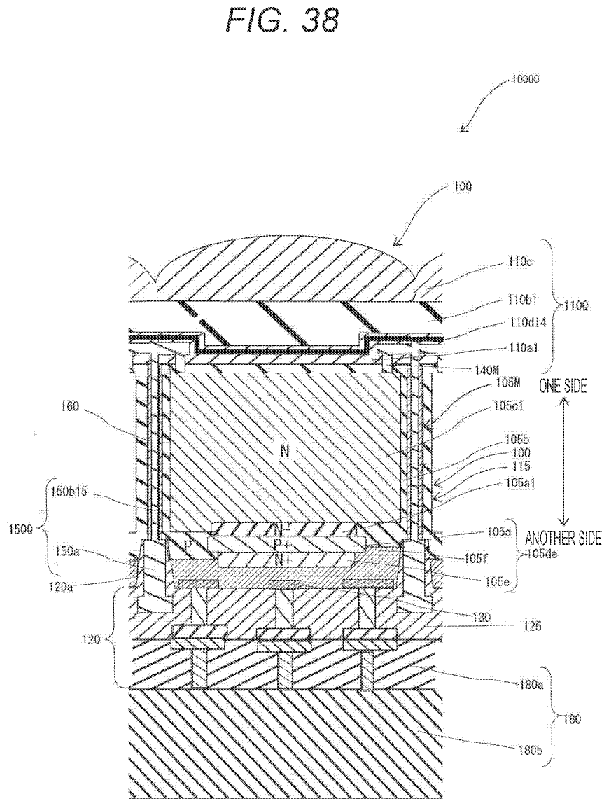

Next, a solid-state image pickup device 1000Q according to the 17th embodiment of the present technology will be described with reference to FIG. 38. The solid-state image pickup device 1000Q according to the 17th embodiment has a configuration of at least one photoelectric converter 105M and a stacked part 110Q of each pixel different from that of the solid-state image pickup device 1000C of the fourth embodiment. From another viewpoint, the solid-state image pickup device 1000Q according to the 17th embodiment has a configuration substantially similar to that of the solid-state image pickup device 1000M of the 14th embodiment except that the arrangement of the thermal conductive layer is different.

In the stacked part 110Q of each pixel 10Q of the solid-state image pickup device 1000Q, a thermal conductive layer 110d14 is provided in the second insulating layer 110a1, the color filter layer 110b1 is arranged on the second insulating layer 110a1, and the lens layer 110c is arranged on the color filter layer 110b1. That is, the thermal conductive layer 110d14 is an inner layer of the stacked part 110Q (an inner layer of the solid-state image pickup device 1000Q).

The tip of the extending part 150b15 of a partition wall 150Q is in contact with the thermal conductive layer 110d14.

According to the solid-state image pickup device 1000Q, action and effects substantially similar to those of the solid-state image pickup device 1000C of the fourth embodiment are exhibited.

The solid-state image pickup device 1000Q can be manufactured by a method according to the method for manufacturing the solid-state image pickup device 1000C of the fourth embodiment and the method for manufacturing the solid-state image pickup device 1000M of the 14th embodiment.

<20. Solid-State Image Pickup Device According to 18th Embodiment of Present Technology>

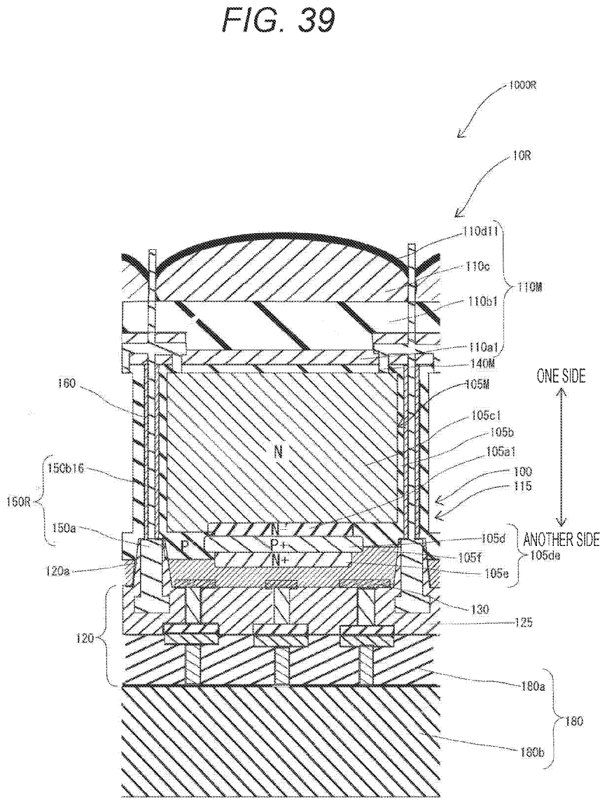

Next, a solid-state image pickup device 1000R according to the 18th embodiment of the present technology will be described with reference to FIG. 39. The solid-state image pickup device 1000R according to the 18th embodiment includes a plurality of pixels 10R arranged two-dimensionally, similarly to the solid-state image pickup device 1000M of the 14th embodiment.

As illustrated in FIG. 39, each pixel 10R has a configuration substantially similar to that of the pixel 10M of the solid-state image pickup device 1000M of the 15th embodiment except that a partition wall 150R penetrates a thermal conductive layer 110d15.

Specifically, the extending part 150b16 of the partition wall 150R penetrates the thermal conductive layer 110d11 with the extending part 150b16 being in contact with the thermal conductive layer 110d11, and the tip protrudes to the side part of the lens layer 110c. That is, the tip of the partition wall 150R is exposed.

The solid-state image pickup device 1000R can be manufactured by a method substantially similar to the method for manufacturing the solid-state image pickup device 1000M of the 14th embodiment. However, by adjusting the film thickness and the etch-back amount of the insulating film 204 to be the second insulating layer 110a to make the protrusion amount of the metal material 208 from the insulating film 204 larger than that in manufacturing the solid-state image pickup device 1000M, the partition wall 150R can penetrate the thermal conductive layer 110d11 with the partition wall 150R being in contact with the thermal conductive layer 110d11 as described above.

According to the solid-state image pickup device 1000R of the 18th embodiment, the effects similar to those of the solid-state image pickup device 1000M are exhibited, the partition wall 150R can be more reliably brought into contact with the thermal conductive layer 110d11, and heat can be released from the exposed tip of the partition wall 150R to the outside.

Here, although the tip of the partition wall 150R that penetrates the thermal conductive layer 110d11 is exposed, it can be unexposed.

Note that also in the 15th embodiment to the 17th embodiment, the partition wall can penetrate the thermal conductive layer with the partition wall being in contact with the thermal conductive layer.

<21. Solid-State Image Pickup Device According to 19th Embodiment of Present Technology>

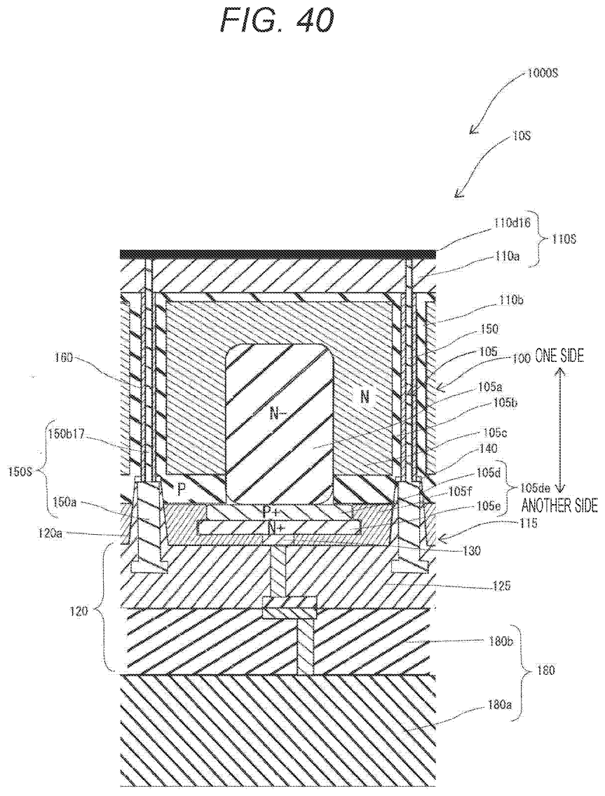

Next, a solid-state image pickup device 1000S according to the 19th embodiment of the present technology will be described with reference to FIG. 40. As illustrated in FIG. 40, the solid-state image pickup device 1000S according to the 20th embodiment is different from the solid-state image pickup device 1000B of the third embodiment in that the lens layer 110c and the color filter layer 110b are not included.

The configuration without the lens layer 110c or the color filter layer 110b can be used, for example, for an application of forming a black-and-white image and a ranging application.

In the stacked part 110S of each pixel 10S of the solid-state image pickup device 1000S, a thermal conductive layer 110d16 constitutes a surface layer, and the second insulating layer 110a is arranged immediately below the thermal conductive layer 110d16.

The tip of the extending part 150b17 of a partition wall 150S is in contact with the thermal conductive layer 110d16.

In the solid-state image pickup device 1000S, the heat generated in the electron multiplication region 105de and the logic substrate 180 is transferred to the thermal conductive layer 110d16 mainly via the partition wall 150S, and is released from the surface and the end surface of the thermal conductive layer 110d16 to the outside.

The solid-state image pickup device 1000S can also be manufactured by a method according to the method for manufacturing the solid-state image pickup device 1000B of the third embodiment (however, the step of forming the color filter layer 110b and the step of forming the lens layer 110c are excluded).

<22. Solid-State Image Pickup Device 1000T According to 20th Embodiment of Present Technology>

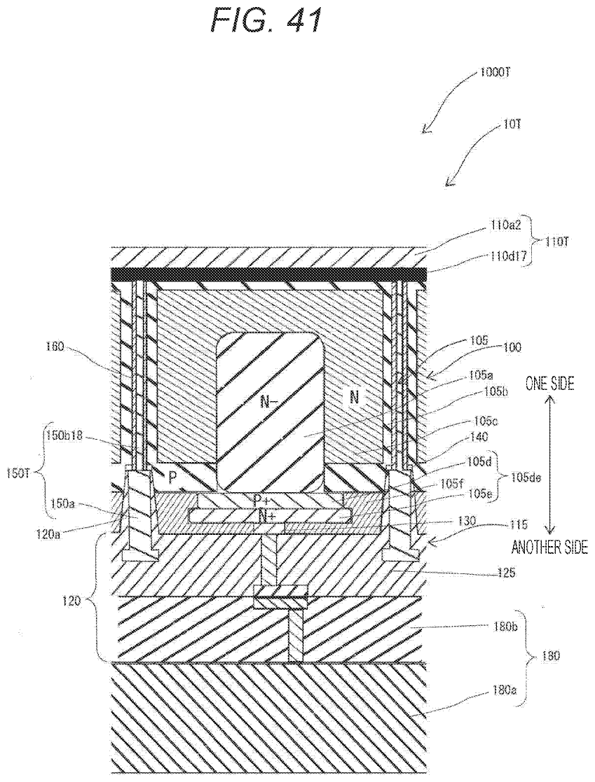

Next, a solid-state image pickup device 1000T according to the 20th embodiment of the present technology will be described with reference to FIG. 41. In the solid-state image pickup device 1000T according to the 20th embodiment, the arrangement of the thermal conductive layer and the second insulating layer is reversed relative to the arrangement of the solid-state image pickup device 1000S of the 19th embodiment.

In the stacked part 110T of each pixel 10T of the solid-state image pickup device 1000T, the second insulating layer 110a2 constitutes a surface layer, and a thermal conductive layer 110d17 is arranged between the second insulating layer 110a2 and the semiconductor substrate 100. That is, the thermal conductive layer 110d17 constitutes an inner layer of the stacked part 110T (an inner layer of the solid-state image pickup device 1000T).

The tip of the extending part 150b18 of a partition wall 150T is in contact with the thermal conductive layer 110d17.

In the solid-state image pickup device 1000T, the heat generated in the electron multiplication region 105de and the logic substrate 180 is transferred to the thermal conductive layer 110d17 mainly via the partition wall 150T, and is released from the end surface of the thermal conductive layer 110d17 to the outside.

In the solid-state image pickup device 1000T, the second insulating layer 110a2 also functions as a protective layer that protects the thermal conductive layer 110d17 (prevents oxidation, corrosion, and the like).

The solid-state image pickup device 1000T can be manufactured by a method according to the method for manufacturing the solid-state image pickup device 1000S of the 19th embodiment (however, the order of formation of the thermal conductive layer and the second insulating layer is reversed).

<23. Solid-State Image Pickup Device 1000U According to 21st Embodiment of Present Technology>

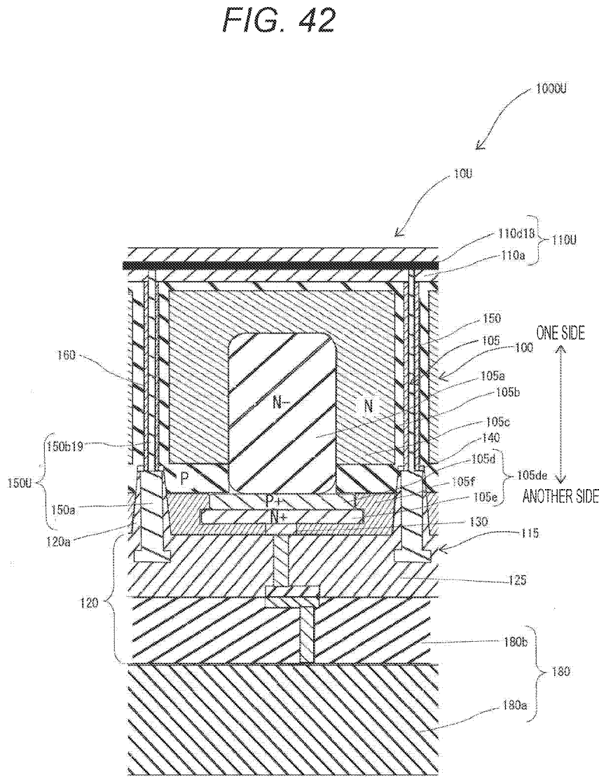

Next, a solid-state image pickup device 1000U according to the 21st embodiment of the present technology will be described with reference to FIG. 42. The solid-state image pickup device 1000U according to the 21st embodiment has a configuration substantially similar to that of the solid-state image pickup device 1000S according to the 19th embodiment except that the arrangement of the thermal conductive layer is different.

In the stacked part 110U of each pixel 10U of the solid-state image pickup device 1000U, a thermal conductive layer 110d18 is arranged in the second insulating layer 110a. That is, a part (upper layer) of the second insulating layer 110a constitutes a surface layer of the stacked part 110U, and the thermal conductive layer 110d18 constitutes an inner layer of the stacked part 110U (an inner layer of the solid-state image pickup device 1000U).

The tip of the extending part 150b19 of the partition wall part 150U is in contact with the thermal conductive layer 110d18.

In the solid-state image pickup device 1000U, the heat generated in the electron multiplication region 105de and the logic substrate 180 is transferred to the thermal conductive layer 110d18 mainly via a partition wall 150U, and is released from the end surface of the thermal conductive layer 110d18 to the outside.

In the solid-state image pickup device 1000U, a part (upper layer) of the second insulating layer 110a also functions as a protective layer that protects the thermal conductive layer 110d18 (prevents oxidation, corrosion, and the like).

The solid-state image pickup device 1000U can be manufactured by a method according to the method for manufacturing the solid-state image pickup device 1000S of the 19th embodiment.

<24. Solid-State Image Pickup Device According to 22nd Embodiment of Present Technology>

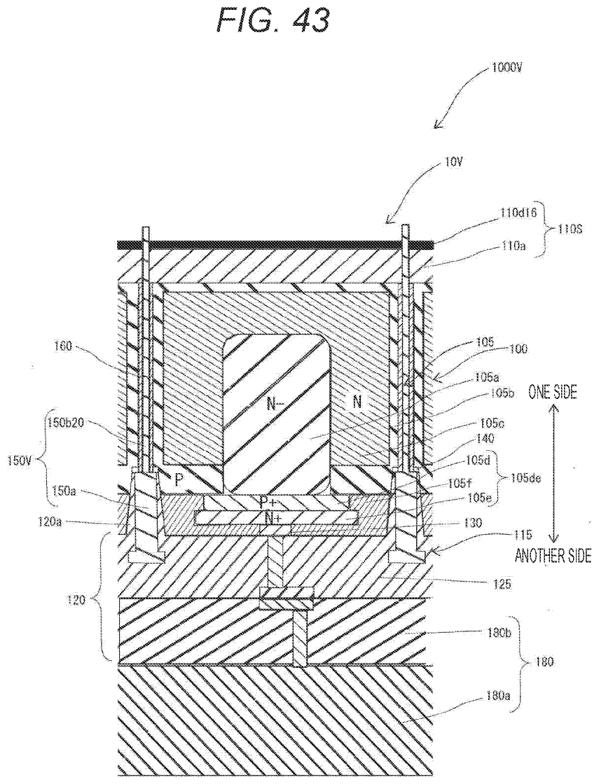

Next, a solid-state image pickup device 1000V according to the 22nd embodiment of the present technology will be described with reference to FIG. 43.

As illustrated in FIG. 43, the solid-state image pickup device 1000V according to the 22nd embodiment includes a plurality of pixels 10V arranged two-dimensionally, similarly to the solid-state image pickup device 1000S of the 19th embodiment.

Each pixel 10V has a configuration substantially similar to that of the pixel 10S of the solid-state image pickup device 1000S of the 19th embodiment except that a partition wall 150V penetrates the thermal conductive layer 110d16.

Specifically, the extending part 150b20 of the partition wall 150V penetrates the thermal conductive layer 110d16 with the extending part 150b20 being in contact with the thermal conductive layer 110d16, and the tip protrudes onto the thermal conductive layer 110d16. That is, the tip of the partition wall 150V is exposed.

The solid-state image pickup device 1000V can be manufactured by a method substantially similar to the method for manufacturing the solid-state image pickup device 1000S of the 19th embodiment. However, by adjusting the film thickness and the etch-back amount of the insulating film 204 to be the second insulating layer 110a to make the protrusion amount of the metal material 208 from the insulating film 204 larger than that in manufacturing the solid-state image pickup device 1000S, the partition wall 150V can penetrate the thermal conductive layer 110d16 with the partition wall 150V being in contact with the thermal conductive layer 110d16 as described above.

According to the solid-state image pickup device 1000V of the 22nd embodiment, the effects similar to those of the solid-state image pickup device 1000S of the 20th embodiment are exhibited, the partition wall 150V can be more reliably brought into contact with the thermal conductive layer 110d16, and heat can be released from the exposed tip of the partition wall 150V to the outside.

Here, although the tip of the partition wall 150 that penetrates the thermal conductive layer 110d16 is exposed, it can be unexposed.

Note that also in the 20th embodiment and the 21st embodiment, the partition wall can penetrate the thermal conductive layer with the partition wall being in contact with the thermal conductive layer.

<25. Solid-State Image Pickup Device According to 23rd Embodiment of Present Technology>

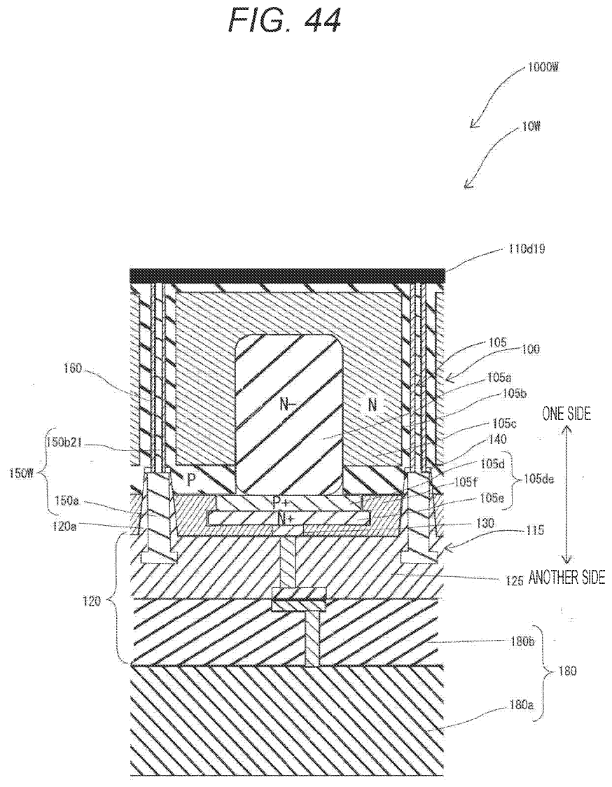

A solid-state image pickup device 1000W according to the 23rd embodiment of the present technology will be described with reference to FIG. 44.

As illustrated in FIG. 44, the solid-state image pickup device 1000W according to the 23rd embodiment includes a plurality of pixels 10W arranged two-dimensionally, similarly to the solid-state image pickup device 1000S of the 19th embodiment.

The solid-state image pickup device 1000W has a configuration substantially similar to that of the solid-state image pickup device 1000S of the 19th embodiment except that the second insulating layer 110a is not included.

In each pixel 10W of the solid-state image pickup device 1000W, a thermal conductive layer 110d19 is arranged immediately above the semiconductor substrate 100. That is, the thermal conductive layer 110d19 is a surface layer.

The tip of the extending part 150b21 of a partition wall 150W is in contact with the thermal conductive layer 110d19.

In the solid-state image pickup device 1000W, the heat generated in the electron multiplication region 105de and the logic substrate 180 is transferred to the thermal conductive layer 110d19 mainly via the partition wall 150W, and is released from the surface and the end surface of the thermal conductive layer 110d19 to the outside.

The solid-state image pickup device 1000W can be manufactured by a method according to the method for manufacturing the solid-state image pickup device 1000S of the 19th embodiment (however, the step of forming the second insulating layer 110a is excluded).

<26. Solid-State Image Pickup Device According to 24th Embodiment of Present Technology>

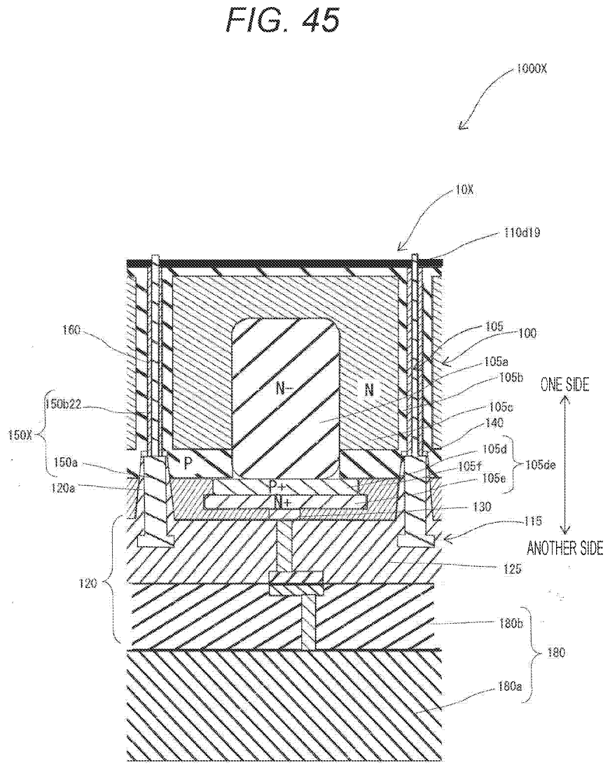

A solid-state image pickup device 1000X according to the 24th embodiment of the present technology will be described with reference to FIG. 45.

As illustrated in FIG. 45, the solid-state image pickup device 1000X according to the 24th embodiment includes a plurality of pixels 10X arranged two-dimensionally, similarly to the solid-state image pickup device 1000W of the 23rd embodiment.

Each pixel 10X has a configuration substantially similar to that of the pixel 10W of the solid-state image pickup device 1000W of the 23rd embodiment except that a partition wall 150X penetrates the thermal conductive layer 110d19.

Specifically, the extending part 150b22 of the partition wall 150X penetrates the thermal conductive layer 110d19 with the extending part 150b22 being in contact with the thermal conductive layer 110d19, and the tip protrudes onto the thermal conductive layer 110d19. That is, the tip of the partition wall 150X is exposed.

The solid-state image pickup device 1000X can be manufactured by a method substantially similar to the method for manufacturing the solid-state image pickup device 1000W of the 23rd embodiment. However, by making the protrusion amount of the metal material 208 from the semiconductor substrate 200 larger than that in manufacturing the solid-state image pickup device 1000W, the partition wall 150X can penetrate the thermal conductive layer 110d19 with the partition wall 150X being in contact with the thermal conductive layer 110d19 as described above.

According to the solid-state image pickup device 1000X of the 24th embodiment, the effects similar to those of the solid-state image pickup device 1000W of the 23rd embodiment are exhibited, the partition wall 150X can be more reliably brought into contact with the thermal conductive layer 110d19, and heat can be released from the exposed tip of the partition wall 150X to the outside.

<27. Solid-State Image Pickup Device According to 25th Embodiment of Present Technology>

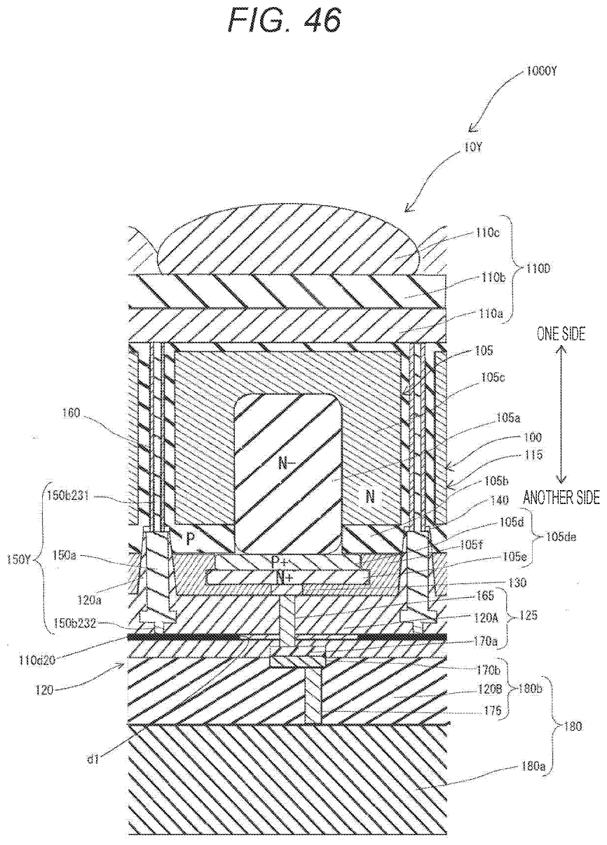

A solid-state image pickup device 1000Y according to the 25th embodiment of the present technology will be described with reference to FIG. 46. As illustrated in FIG. 46, the solid-state image pickup device 1000Y according to the 25th embodiment has a configuration substantially similar to that of the solid-state image pickup device 1000 of the first embodiment except for the arrangement of the thermal conductive layer and the configuration of the partition wall.

In each pixel 10Y of the solid-state image pickup device 1000Y, a thermal conductive layer 110d20 is arranged in the first insulating layer 120 sandwiched between the semiconductor substrate 100 and the semiconductor substrate 180a.

More specifically, in each pixel 10Y, the thermal conductive layer 110d20 is arranged in the insulating layer 120A of the wiring layer 125 of the pixel sensor substrate 115.

As described above, the thermal conductive layer 110d20 constitutes an inner layer of the solid-state image pickup device 1000Y.

The stacked part 110D of the solid-state image pickup device 1000Y includes a second insulating layer 110a, a color filter layer 110b, and a lens layer 110c.

A partition wall 150Y has a first extending part 150b231 that extends to the one side from the base end part 150a and a second extending part 150b232 that extends to the another side.

The first extending part 150b231 remains in the semiconductor substrate 100 (does not protrude to one side (upper side) from the semiconductor substrate 100).

The tip (end part of the another side) of the second extending part 150b232 is in contact with the thermal conductive layer 110d20.

An opening part d1 that the metal member 165 of the wiring layer 125 of the pixel sensor substrate 115 penetrates is formed in the thermal conductive layer 110d20. A part of the insulating layer 120A is in the opening part d1.

In the solid-state image pickup device 1000Y, the heat generated in the electron multiplication region 105de formed in the semiconductor substrate 100 is transferred to the thermal conductive layer 110d20 mainly via the partition wall 150Y, and is released from the end surface of the thermal conductive layer 110d20 to the outside. The heat generated in the logic circuit formed in the semiconductor substrate 180a is transferred to the thermal conductive layer 110d20 mainly via the wiring layer 180b and a part (lower part) of the wiring layer 125, and is released from the end surface of the thermal conductive layer 110d20 to the outside.

According to the solid-state image pickup device 1000Y, the thermal conductive layer 110d20 is arranged in the first insulating layer 120 sandwiched between the semiconductor substrate 100 in which the electron multiplication region 105de is formed and the semiconductor substrate 180a in which the logic circuit is formed, and thus the heat dissipation property of the heat generated in the electron multiplication region 105de and the heat generated in the logic circuit of the logic substrate 180 can be achieved in a high level.

In particular, in the solid-state image pickup device 1000Y, the thermal conductive layer 110d20 is arranged at a position relatively close to the electron multiplication region 105de, and thus the heat dissipation property of the heat generated in the electron multiplication region 105de is remarkably good.

The solid-state image pickup device 1000Y can be manufactured by a method according to the method for manufacturing the solid-state image pickup device 1000 of the first embodiment.

A method for manufacturing the solid-state image pickup device 1000Y of the 25th embodiment will be briefly described.

The solid-state image pickup device 1000Y is manufactured by a method according to the method for manufacturing the solid-state image pickup device 1000 (method illustrated in FIGS. 5 and 6).

Specifically, the solid-state image pickup device 1000Y is manufactured in a procedure substantially similar to the flowcharts illustrated in FIGS. 5 and 6.

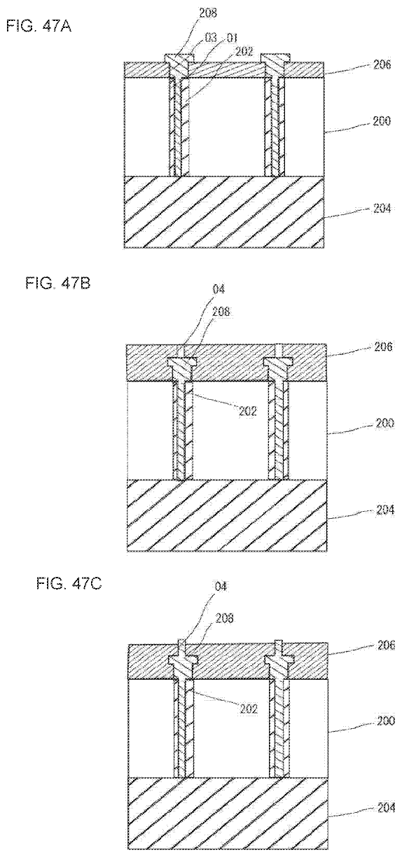

More specifically, in manufacturing of the solid-state image pickup device 1000Y, after the step S6 is performed as illustrated in FIG. 47A (however, here, the step of forming the second opening O2 is not performed in the step S4, and the step of embedding the metal material in the second opening O2 is not performed in the step S6), in the step S7, as illustrated in FIG. 47B, an insulating film 206 is further deposited on the surface of the semiconductor substrate 200, and the fourth opening O4 for forming the second extending part of the partition wall 150Y is formed on the insulating film 206 by etching.

Next, as illustrated in FIG. 47C, a metal material 208 to be the second extending part 150b232 is embedded in the fourth opening O4. At this time, the metal material 208 slightly protrudes from the insulating film 206.

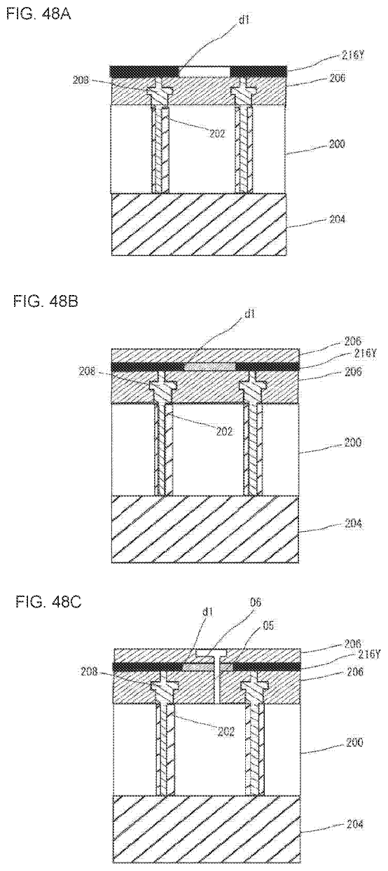

Next, as illustrated in FIG. 48A, a thermal conductive film 216Y to be the thermal conductive layer 110d20 is formed on the insulating film 206, and an opening part d1 that the metal member 165 for cathode contact penetrates is formed in the insulating film 206. At this time, the thermal conductive film 216Y is brought into contact with the protruding part of the metal material 208.

Next, as illustrated in FIG. 48B, the insulating film 206 is thinly deposited on the thermal conductive film 216Y. At this time, a part of the insulating film 206 is in the opening part d1 of the thermal conductive layer 216Y.

Next, as illustrated in FIG. 48C, after a fifth opening O5 for cathode contact that extends in the film thickness direction is formed at a position corresponding to the opening part d1 of the insulating film 206, a recess O6 for holding a wiring member that communicates with the fifth opening O5 is formed on a surface layer of the insulating layer 206.

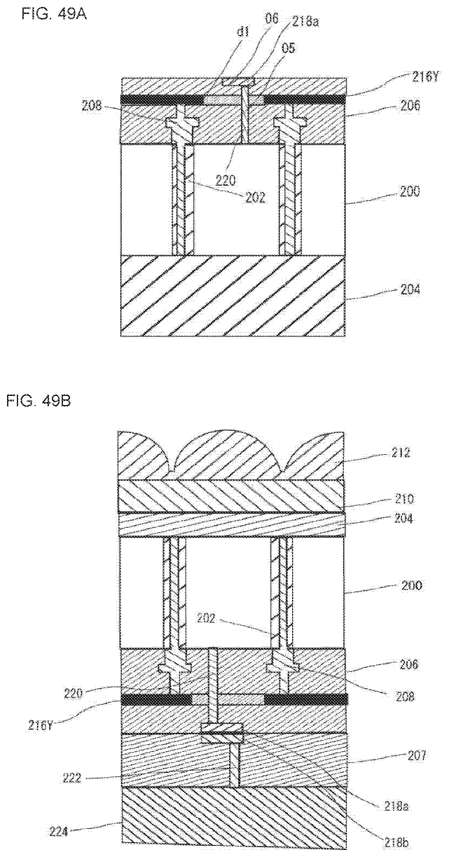

Next, as shown in FIG. 49A, after the metal material 220 to be the metal member 165 is embedded in the fifth opening O5, the metal material 218a to be the wiring member 170a is embedded in the recess O6 to be in contact with the metal material 220.

Next, the steps S8 to S12 are performed to sequentially form the color filter 210 and the on-chip lens on the insulating film 204. Thereafter, as illustrated in FIG. 49B, the pixel sensor substrate 115 and the logic substrate 180 are bonded each other so that the metal material 218a and the metal material 218b are joined each other.

Note that prior to this bonding, the metal material 222 to be the metal member 175 and the metal material 218b to be the wiring member 170b are embedded in the insulating film 207 to be the insulating layer 120B of the logic substrate 180 by a procedure similar to the procedure described with reference to FIG. 48C.

The method for manufacturing the solid-state image pickup device 1000Y of the 25th embodiment described above includes the steps of: forming a first opening O1 (opening) in a semiconductor substrate 200 in which a photoelectric converter 105 is to be formed; embedding an insulating material 202 in a peripheral part in the first opening O1; arranging an insulating film 206 on the semiconductor substrate 200; forming a third opening O3 (another opening) that communicates with a central part in the first opening O1 in the insulating film 206; embedding a metal material 208 in the central part in the first opening O1 and the third opening O3; and arranging a thermal conductive film 216Y on a side opposite to the semiconductor substrate 200 of the insulating film 206.

In this case, a solid-state image pickup device 1000Y having an excellent heat dissipation property can be efficiently manufactured.

Moreover, in the step of arranging the thermal conductive film 216Y, the thermal conductive film 216Y is arranged so that the thermal conductive film 216Y is connected to the metal material 208 embedded in the third opening O3 via the metal material 208 (another metal material) embedded in the fourth opening O4.

In this case, a solid-state image pickup device 1000Y having a remarkably excellent heat dissipation property can be efficiently manufactured.

<28. Solid-State Image Pickup Device According to 26th Embodiment of Present Technology>

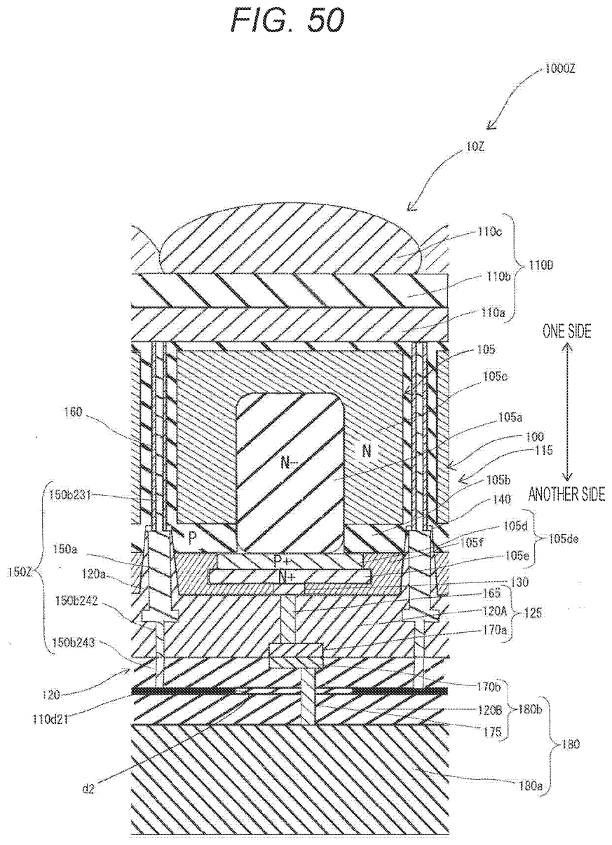

A solid-state image pickup device 1000Z according to the 26th embodiment of the present technology will be described with reference to FIG. 50. As illustrated in FIG. 50, the solid-state image pickup device 1000Z according to the 26th embodiment has a configuration substantially similar to that of the solid-state image pickup device 1000Y of the 25th embodiment except for the arrangement of the thermal conductive layer and the configuration of the partition wall.

Also, in each pixel 10Z of the solid-state image pickup device 1000Z, a thermal conductive layer 110d21 is arranged in the first insulating layer 120.

More specifically, the thermal conductive layer 110d21 is arranged in the insulating layer 120B of the wiring layer 180b of the logic substrate 180.

A partition wall 150Z has a first extending part 150b231 that extends to the one side from the base end part 150a, a second extending part 150b242 that extends to the another side, and a connecting part 150b243 that connects the second extending part 150b242 and the thermal conductive layer 110d21.

The tip surface of the second extending part 150b242 is substantially flush with the surface on the another side (lower side) of the insulating layer 120A.

An opening part d2 that the metal member 175 of the wiring layer 180b of the logic substrate 180 penetrates is formed in the thermal conductive layer 110d21. A part of the insulating layer 120B is in the opening part d2.

The connecting part 150b243 is arranged in the insulating layer 120B of the logic substrate 180. An end surface on the one side (upper side) of the connecting part 150d243 is substantially flush with a surface on the one side (upper side) of the insulating layer 120B, and an end surface on the another side (lower side) is in contact with the thermal conductive layer 110d21.

Note that the partition wall 150Z does not have to have the connecting part 150b243.

In the solid-state image pickup device 1000Z, the heat generated in the electron multiplication region 105de formed in the semiconductor substrate 100 is transferred to the thermal conductive layer 110d21 mainly via the partition wall 150Z, and is released from the end surface of the thermal conductive layer 110d21 to the outside. The heat generated in the logic circuit formed in the semiconductor substrate 180a is transferred to the thermal conductive layer 110d21 mainly via a part (lower part) of the wiring layer 180b, and is released from the end surface of the thermal conductive layer 110d21 to the outside.

According to the solid-state image pickup device 1000Z, the thermal conductive layer 110d21 is arranged in the first insulating layer 120 sandwiched between the semiconductor substrate 100 in which the electron multiplication region 105de is formed and the semiconductor substrate 180a in which the logic circuit is formed, and thus both the heat dissipation property of the heat generated in the electron multiplication region 105de and the heat dissipation property of the heat generated in the logic circuit of the logic substrate 180 can be achieved in a high level.

In particular, in the solid-state image pickup device 1000Z, the thermal conductive layer 110d21 is arranged at a position relatively close to the semiconductor substrate 180a of the logic substrate 180, and thus the heat dissipation property of the logic circuit formed in the semiconductor substrate 180a is remarkably good.

A method for manufacturing the solid-state image pickup device 1000Z of the 26th embodiment will be briefly described.

The solid-state image pickup device 1000Z is manufactured by a method according to the method for manufacturing the solid-state image pickup device 1000 (method illustrated in FIGS. 5 and 6).

Specifically, the solid-state image pickup device 1000Z is manufactured in a procedure substantially similar to the flowcharts illustrated in FIGS. 5 and 6.

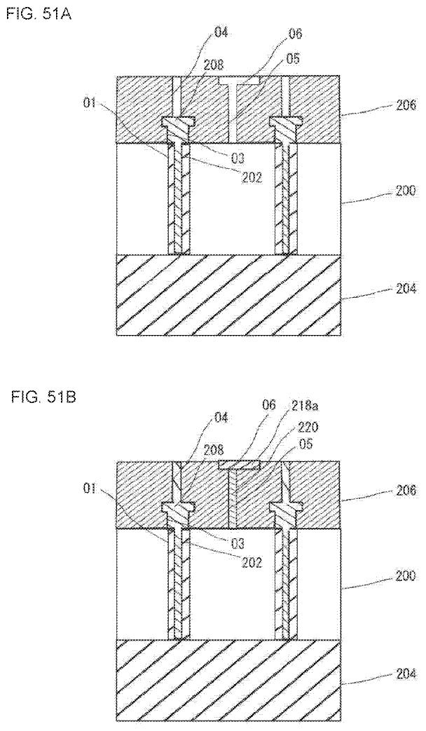

More specifically, in manufacturing of the solid-state image pickup device 1000Z, similar to the 25th embodiment, after the step S6 is performed (however, here, the step of forming the second opening O2 is not performed in the step S4, and the step of embedding the metal material in the second opening O2 is not performed in the step S6), in the step S7, as illustrated in FIG. 51A, the insulating film 206 is deposited on the surface of the semiconductor substrate 200, and the fourth opening O4 for forming the second extending part of the partition wall 150Z, the fifth opening O5 for cathode contact, and a recess O6 for holding the wiring member that communicates with the fifth opening O5 are formed on the insulating film 206 by etching.

Next, as illustrated in FIG. 51B, after the metal material 208 to be the second extending part 150b242 is embedded in the fourth opening O4 and the metal material 220 to be the metal member 165 is embedded in the fifth opening O5, the metal material 218a to be the wiring member 170a is embedded in the recess O6 to be in contact with the metal material 220.

Next, the steps S8 to S12 are performed to sequentially form the color filter 210 and the on-chip lens on the insulating film 204.

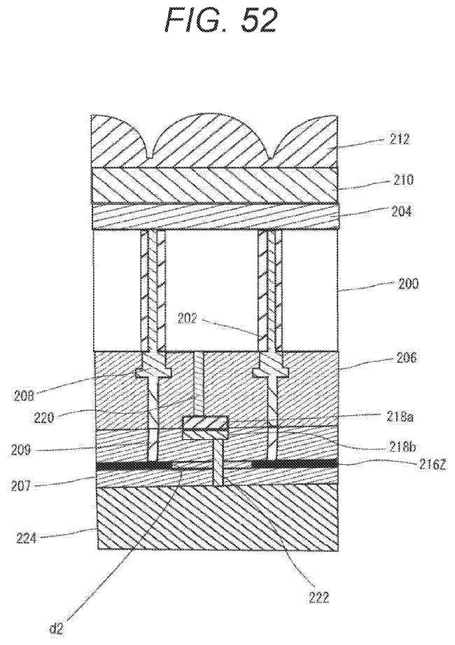

Thereafter, as illustrated in FIG. 52, the pixel sensor substrate 115 and the logic substrate 180 are bonded to each other so that the metal material 218a and the metal material 218b are joined to each other, and the another end surface of the metal material 209 to be the connecting part 150b243, one end surface of which is in contact with a thermal conductive film 216Z to be the thermal conductive layer 110d21, and the metal material 208 to be the second extending part 150b242 are in contact with each other.

Note that prior to this bonding, by a method substantially similar to that of the 25th embodiment, after the thermal conductive film 216Z to be the thermal conductive layer 110d21 is formed in the insulating film 207 to be the insulating layer 120B of the logic substrate 180 and the opening part d2 for cathode contact is formed in the thermal conductive film 216Z, the metal material 222 to be the metal member 175 is embedded in the insulating film 207 to penetrate the opening part d2, and a metal material 218b to be the wiring member 170b is embedded in a surface layer of the insulating film 206 side of the insulating film 207 to be in contact with the metal material 222. Moreover, a metal material 209 to be the connecting part 150b243 is embedded in the insulating film 207 so that one end surface is in contact with the thermal conductive film 216Z and the another end surface is substantially flush with (exposed to) the surface on the one side (upper side) of the insulating film 207.

The method for manufacturing the solid-state image pickup device 1000Z of the 26th embodiment of the present technology described above includes the steps of: forming a first opening O1 (opening) in a semiconductor substrate 200 in which a photoelectric converter 105 is to be formed; embedding an insulating material 202 in a peripheral part in the first opening O1; arranging an insulating film 206 on the semiconductor substrate 200; forming a third opening O3 (another opening) that communicates with a central part in the first opening O1 in the insulating film 206; embedding a metal material 208 in the central part in the first opening O1 and the third opening O3; and arranging a thermal conductive film 216Z on a side opposite to the semiconductor substrate 200 of the insulating film 206.

In this case, a solid-state image pickup device 1000Z having excellent heat dissipation property can be efficiently manufactured.

Moreover, in the step of arranging the thermal conductive film 216Z, the thermal conductive film 216Z is arranged so that the thermal conductive film 216Z is connected to the metal material 208 embedded in the third opening O3 via the metal material 208 (another metal material) embedded in the fourth opening O4 and the metal material 209 (another metal material) embedded in the insulating film 207.

In this case, a solid-state image pickup device 1000Z having a remarkably excellent heat dissipation property can be efficiently manufactured.

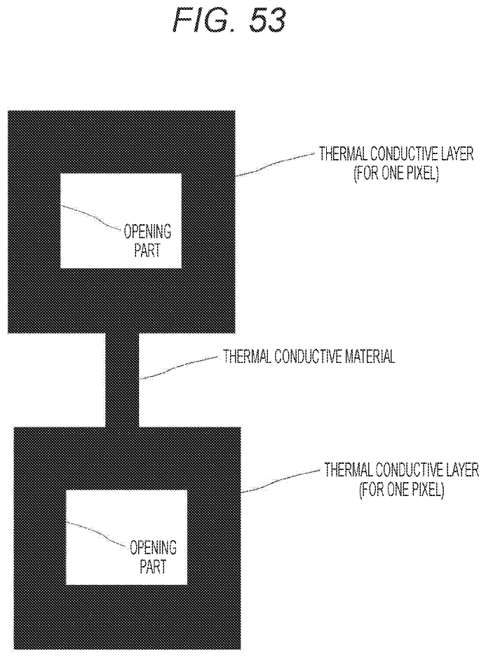

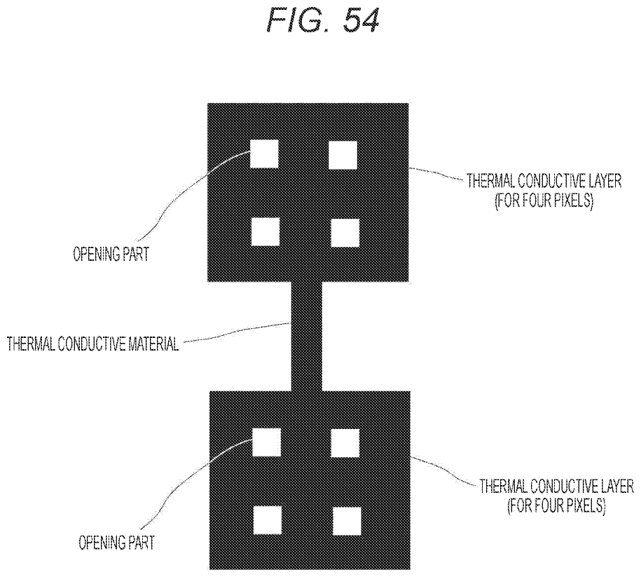

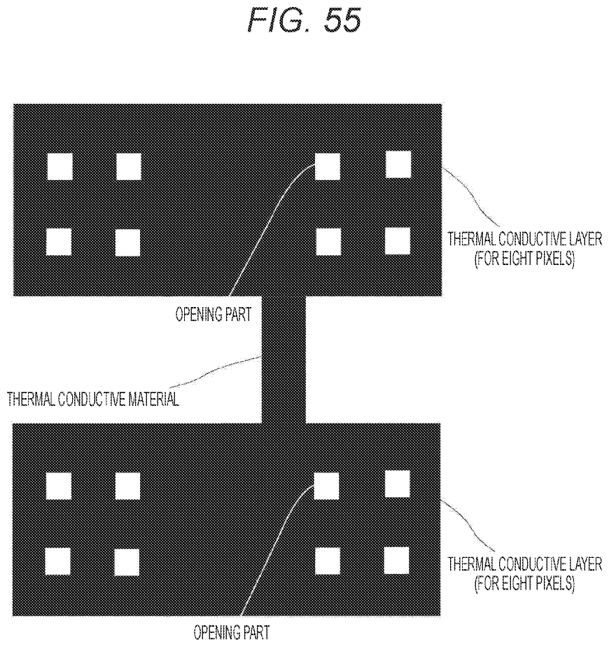

Here, in the 25th embodiment and the 26th embodiment, the thermal conductive layer can be provided for each pixel, for example, as illustrated in FIG. 53, can be provided to be shared by four pixels, for example, as illustrated in FIG. 54, or can be provided to be shared by eight pixels, for example, as illustrated in FIG. 55. Note that the “opening part” in FIGS. 53 to 55 corresponds to one of the opening part d1 in FIG. 46 and the opening part d2 in FIG. 50.

However, as illustrated in FIGS. 53 to 55, adjacent thermal conductive layers are preferably connected to each other via a thermal conductive material. In this case, while the heat in each of the thermal conductive layers is quickly delivered between adjacent thermal conductive layers, the heat can be released to the outside from the end surface of the thermal conductive layer positioned at the most end, which is the thermal conductive layer whose end surface is exposed to the outside.

In the solid-state image pickup devices 1000Y and 1000Z of the 25th and 26th embodiments described above, the thermal conductive layer is arranged between the semiconductor substrate 100 of the pixel sensor substrate 115 and the semiconductor substrate 180a of the logic substrate 180.

Specifically, the solid-state image pickup devices 1000Y and 1000Z of the 25th and 26th embodiments each include the first insulating layer 120 between the semiconductor substrate 100 and the semiconductor substrate 180a, and the thermal conductive layer is arranged in the first insulating layer 120.

<29. Solid-State Image Pickup Device According to 27th Embodiment of Present Technology>

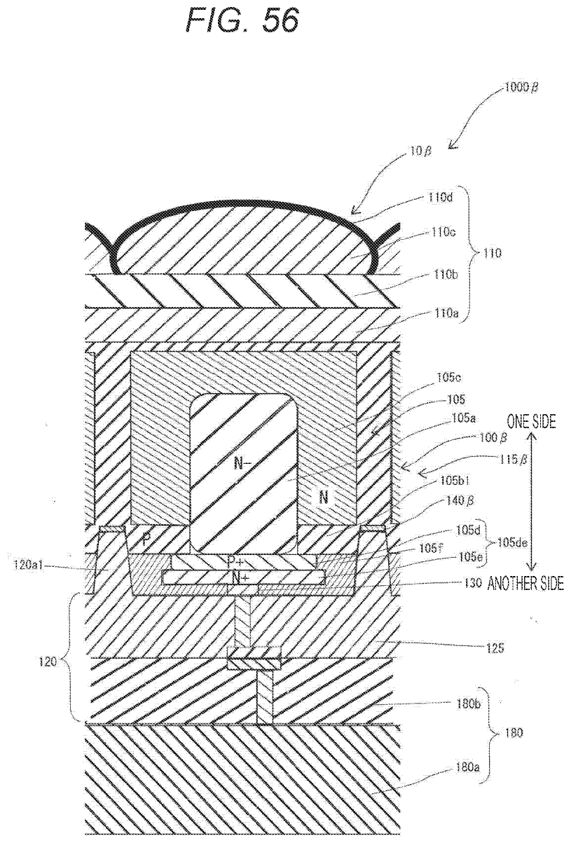

A solid-state image pickup device 1000β according to the 27th embodiment of the present technology will be described with reference to FIG. 56. The solid-state image pickup device 1000β according to the 27th embodiment has a configuration substantially similar to that of the solid-state image pickup device 1000 of the first embodiment except that the partition wall is not included.

In each pixel 10β of the solid-state image pickup device 1000β, a partition wall that separates adjacent photoelectric converters 105 is not provided. Therefore, an opening for arranging the partition wall is not formed in the protruding part 120a1 of the first insulating layer 120 and a semiconductor substrate 100β, and in addition, the anode electrode 140β has a flat plate shape instead of a frame shape.

In the solid-state image pickup device 1000β, the heat generated in the electron multiplication region 105de of the pixel sensor substrate 115β is transferred to the thermal conductive layer 110d via a region other than the electron multiplication region 105de of the at least one photoelectric converter 105, the second insulating layer 110a, the color filter layer 110b, and the lens layer 110c, and is released from the surface and the end surface of the thermal conductive layer 110d to the outside. The heat generated in the logic circuit of the logic substrate 180 is transferred to the thermal conductive layer 110d via the first insulating layer 120, the semiconductor substrate 100β, the second insulating layer 110a, the color filter layer 110b, and the lens layer 110c, and is released from the surface and the end surface of the thermal conductive layer 110d to the outside.

The solid-state image pickup device 1000β can be manufactured by a method according to the method for manufacturing the solid-state image pickup device 1000 of the first embodiment (however, the steps S2 to S6 are excluded).

<30. Solid-State Image Pickup Device According to 28th Embodiment of Present Technology>

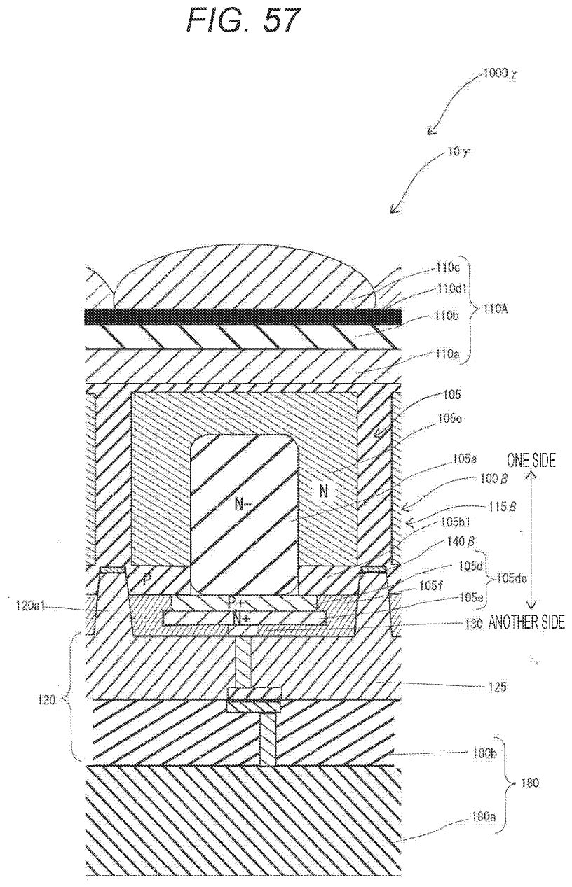

A solid-state image pickup device 1000γ according to the 28th embodiment of the present technology will be described with reference to FIG. 57. The solid-state image pickup device 1000γ according to the 28th embodiment has a configuration substantially similar to that of the solid-state image pickup device 1000β of the 27th embodiment except for the arrangement of the thermal conductive layer.

In each pixel 10γ of the solid-state image pickup device 1000γ, the thermal conductive layer 110d1 is arranged between the lens layer 110c and the color filter layer 110b.

In the solid-state image pickup device 1000γ, the heat generated in the electron multiplication region 105de of the pixel sensor substrate 115β is transferred to the thermal conductive layer 110d1 via a region other than the electron multiplication region 105de of the at least one photoelectric converter 105, the second insulating layer 110a, and the color filter layer 110b, and is released from the end surface of the thermal conductive layer 110d1 to the outside. The heat generated in the logic circuit of the logic substrate 180 is transferred to the thermal conductive layer 110d1 via the first insulating layer 120, the semiconductor substrate 100β, the second insulating layer 110a, and the color filter layer 110b, and is released to the outside from the end surface of the thermal conductive layer 110d1.

The solid-state image pickup device 1000γ can be manufactured by a method according to the method for manufacturing the solid-state image pickup device 1000β of the 27th embodiment (however, the thermal conductive layer 110d1 is formed before the lens layer 110c is formed).

<31. Solid-State Image Pickup Device According to 29th Embodiment of Present Technology>

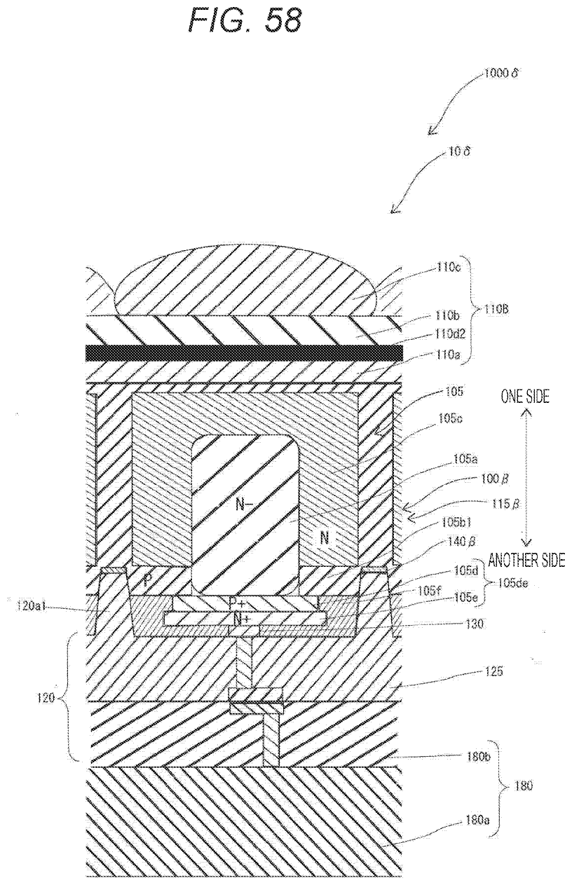

A solid-state image pickup device 1000δ according to the 29th embodiment of the present technology will be described with reference to FIG. 58. The solid-state image pickup device 1000δ according to the 29th embodiment has a configuration substantially similar to that of the solid-state image pickup device 1000β of the 27th embodiment except for the arrangement of the thermal conductive layer.

In each pixel 10δ of the solid-state image pickup device 1000δ, the thermal conductive layer 110d2 is arranged between the color filter layer 110b and the second insulating layer 110a.

In the solid-state image pickup device 1000δ, the heat generated in the electron multiplication region 105de of the pixel sensor substrate 115β is transferred to the thermal conductive layer 110d2 via a region other than the electron multiplication region 105de of the at least one photoelectric converter 105 and the second insulating layer 110a, and is released from the end surface of the thermal conductive layer 110d2 to the outside. The heat generated in the logic circuit of the logic substrate 180 is transferred to the thermal conductive layer 110d2 via the first insulating layer 120, the semiconductor substrate 100β, and the second insulating layer 110a, and is released from the end surface of the thermal conductive layer 110d2 to the outside.

The solid-state image pickup device 1000δ can be manufactured by a method according to the method for manufacturing the solid-state image pickup device 1000β of the 27th embodiment (however, the thermal conductive layer 110d2 is formed before the lens layer 110c and the color filter layer 110b are formed).

<32. Solid-State Image Pickup Device According to 30th Embodiment of Present Technology>

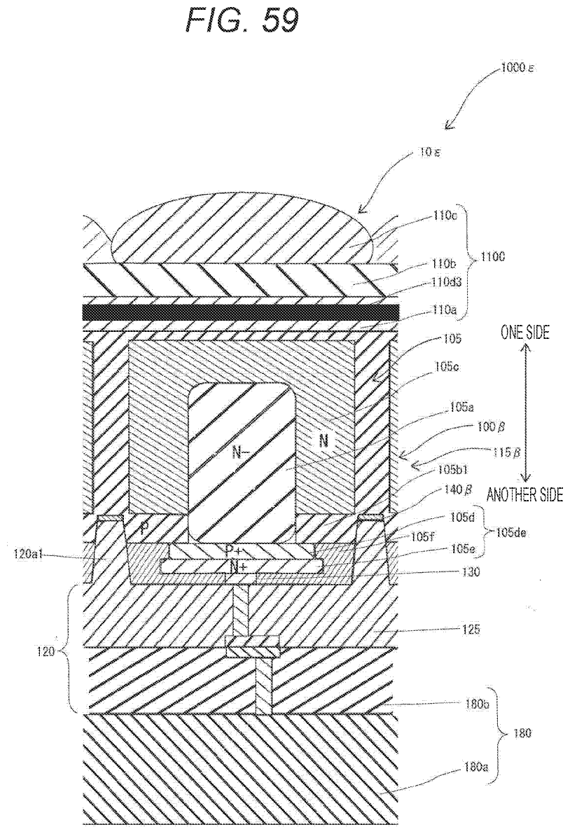

A solid-state image pickup device 1000ε according to the 30th embodiment of the present technology will be described with reference to FIG. 59. The solid-state image pickup device 1000ε according to the 30th embodiment has a configuration substantially similar to that of the solid-state image pickup device 1000β of the 27th embodiment except for the arrangement of the thermal conductive layer.

In each pixel 10ε of the solid-state image pickup device 1000ε, the thermal conductive layer 110d3 is arranged in the second insulating layer 110a.

In the solid-state image pickup device 1000ε, the heat generated in the electron multiplication region 105de of the pixel sensor substrate 115β is transferred to the thermal conductive layer 110d3 via a region other than the electron multiplication region 105de of the at least one photoelectric converter 105 and a part of the second insulating layer 110a (a part on the another side of the thermal conductive layer 110d3), and is released from the end surface of the thermal conductive layer 110d3 to the outside. The heat generated in the logic circuit of the logic substrate 180 is transferred to the thermal conductive layer 110d3 via the first insulating layer 120, the semiconductor substrate 100β, and a part of the second insulating layer 110a (a part on the another side of the thermal conductive layer 110d2), and is released from the end surface of the thermal conductive layer 110d3 to the outside.

The solid-state image pickup device 1000ε can be manufactured by a method according to the method for manufacturing the solid-state image pickup device 1000β of the 27th embodiment (however, the thermal conductive layer 110d3 is formed in the second insulating layer 110a).

<33. Solid-State Image Pickup Device According to 31st Embodiment of Present Technology>

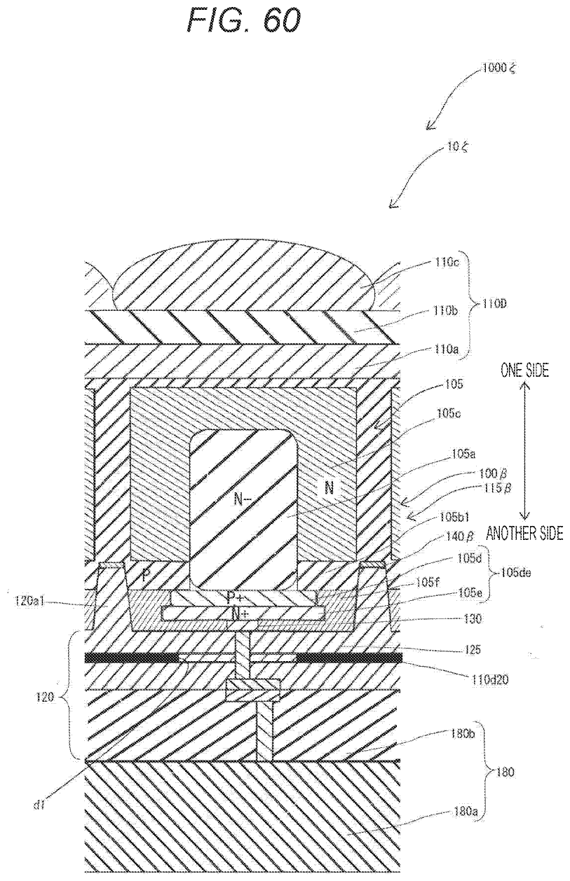

A solid-state image pickup device 1000ζ according to the 31st embodiment of the present technology will be described with reference to FIG. 60. The solid-state image pickup device 1000ζ according to the 31st embodiment has a configuration substantially similar to that of the solid-state image pickup device 1000β of the 27th embodiment except for the arrangement of the thermal conductive layer. From another viewpoint, the solid-state image pickup device 1000ζ of the 31st embodiment has a configuration substantially similar to that of the solid-state image pickup device 1000Y of the 25th embodiment except that the partition wall or the like is not included.

In each pixel 10ζ of the solid-state image pickup device 1000ζ, as illustrated in FIG. 60, the thermal conductive layer 110d20 is arranged in the first insulating layer 120.

More specifically, in each pixel 10ζ, the thermal conductive layer 110d20 is arranged in the insulating layer 120A of the wiring layer 125 of the pixel sensor substrate 115β.

In the solid-state image pickup device 1000ζ, the heat generated in the electron multiplication region 105de of the pixel sensor substrate 115β is transferred to the thermal conductive layer 110d20 via a region other than the electron multiplication region 105de of the at least one photoelectric converter 105 and a part (upper part) of the wiring layer 125, and is released from the end surface of the thermal conductive layer 110d20 to the outside. The heat generated in the logic circuit of the logic substrate 180 is transferred to the thermal conductive layer 110d20 via the wiring layer 180b and the another part (lower part) of the wiring layer 125, and is released from the end surface of the thermal conductive layer 110d20 to the outside.

The solid-state image pickup device 1000 can be manufactured by a method according to the method for manufacturing the solid-state image pickup device 1000β of the 27th embodiment and the method for manufacturing the solid-state image pickup device 1000Y of the 25th embodiment.

<34. Solid-State Image Pickup Device According to 32nd Embodiment of Present Technology>

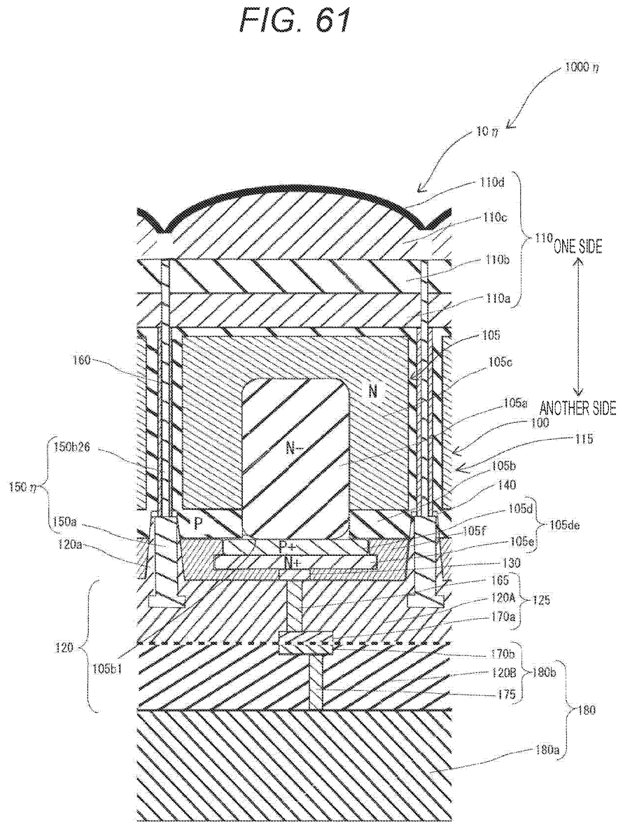

A solid-state image pickup device 1000η according to the 32nd embodiment of the present technology will be described with reference to FIG. 61. The solid-state image pickup device 1000η according to the 32nd embodiment has a configuration substantially similar to that of the solid-state image pickup device 1000 of the first embodiment except for the configuration of the partition wall.

In each pixel 10η of the solid-state image pickup device 1000η, as illustrated in FIG. 61, the tip of the extending part 150b26 of a partition wall 150η not in contact with the thermal conductive layer 110d.

Specifically, the tip of the extending part 150b26 of the partition wall 150η is positioned in the vicinity of the boundary between the color filter layer 110b and the lens layer 110c.

In the solid-state image pickup device 1000η, the heat generated in the electron multiplication region 105de is transferred to the thermal conductive layer 110d mainly via the partition wall 150η and the lens layer 110c, and is released from the surface and the end surface of the thermal conductive layer 110d to the outside. The heat generated in the logic circuit of the logic substrate 180 is transferred to the thermal conductive layer 110d mainly via the first insulating layer 120 and the partition wall 150η, and is released from the surface and the end surface of the thermal conductive layer 110d to the outside.

At this time, although the partition wall 150η is not in contact with the thermal conductive layer 110d, the partition wall 150η is relatively close to the thermal conductive layer 110d (adjacent to the thermal conductive layer 110d with only the lens layer 110c interposed therebetween). Thus, heat can be smoothly delivered from the partition wall 150η to the thermal conductive layer 110d.

Note that the tip of the partition wall 150η can be positioned in the lens layer 110c with the partition wall 150η being not in contact with the thermal conductive layer 110d, can be positioned in the color filter layer 110b, can be positioned in the second insulating layer 110a, or can be positioned in the semiconductor substrate 100.

The solid-state image pickup device 1000η can be manufactured by a method according to the method for manufacturing the solid-state image pickup device 1000 of the first embodiment (however, the protrusion amount of the metal material 208 to be the partition wall 150n is reduced.).

<35. Solid-State Image Pickup Device According to 33rd Embodiment of Present Technology>

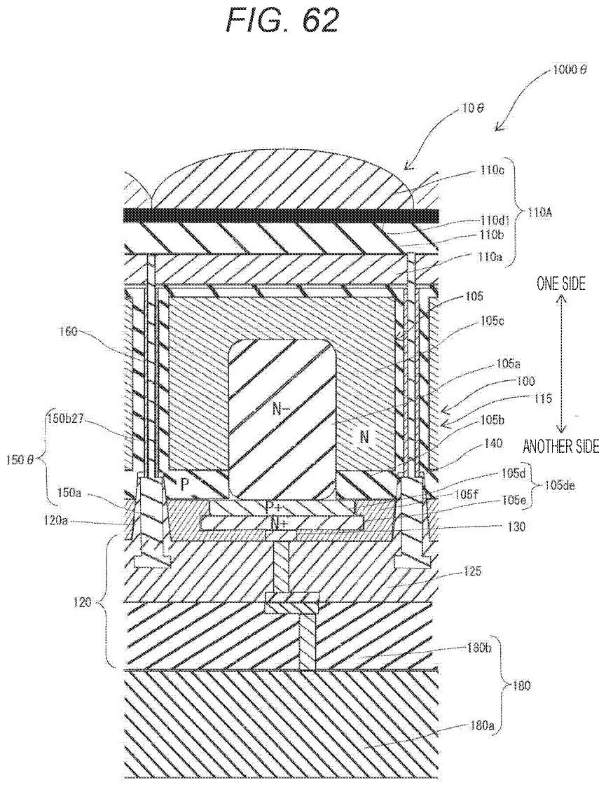

A solid-state image pickup device 1000θ according to the 33rd embodiment of the present technology will be described with reference to FIG. 62. The solid-state image pickup device 1000θ according to the 33rd embodiment has a configuration substantially similar to that of the solid-state image pickup device 1000A of the second embodiment except for the configuration of the partition wall.

In each pixel 10θ of the solid-state image pickup device 1000θ, as illustrated in FIG. 62, the extending part 150b27 of a partition wall 150θ is not in contact with the thermal conductive layer 110d.

Specifically, the tip of the extending part 150b27 of the partition wall 150θ is positioned in the vicinity of the boundary between the color filter layer 110b and the second insulating layer 110a.

In the solid-state image pickup device 1000θ, the heat generated in the electron multiplication region 105de is transferred to the thermal conductive layer 110d1 mainly via the partition wall 150θ and the color filter layer 110b, and is released from the end surface of the thermal conductive layer 110d1 to the outside. The heat generated in the logic circuit of the logic substrate 180 is transferred to the thermal conductive layer 110d1 mainly via the first insulating layer 120, the partition wall 150θ, and the color filter layer 110b, and is released from the end surface of the thermal conductive layer 110d1 to the outside.

At this time, although the partition wall 150θ is not in contact with the thermal conductive layer 110d1, the partition wall 150θ is relatively close to the thermal conductive layer 110d1 (adjacent to the thermal conductive layer 110d1 with only the color filter layer 110b interposed therebetween). Thus, heat can be smoothly delivered from the partition wall 150θ to the thermal conductive layer 110d1.

Note that the tip of the partition wall 150θ can be positioned in the color filter layer 110b with the partition wall 150θ being not in contact with the thermal conductive layer 110d1, can be positioned in the second insulating layer 110a, or can be positioned in the semiconductor substrate 100.

The solid-state image pickup device 1000θ can be manufactured by a method according to the method for manufacturing the solid-state image pickup device 1000A of the second embodiment (however, the protrusion amount of the metal material 208 to be the partition wall 150θ is reduced.).

<36. Solid-State Image Pickup Device According to 34th Embodiment of Present Technology>

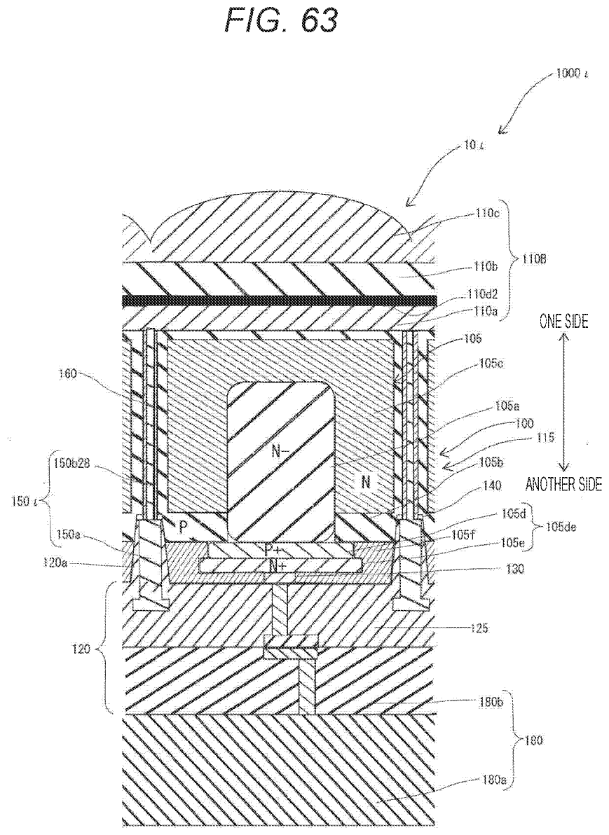

A solid-state image pickup device 1000ι according to the 34th embodiment of the present technology will be described with reference to FIG. 63. The solid-state image pickup device 1000ι according to the 34th embodiment has a configuration substantially similar to that of the solid-state image pickup device 1000B of the third embodiment except for the configuration of the partition wall.

In each pixel 10ι of the solid-state image pickup device 1000ι, as illustrated in FIG. 63, the extending part 150b28 of a partition wall 150ι is not in contact with the thermal conductive layer 110d.

Specifically, the tip of the extending part 150b28 of the partition wall 150ι is positioned in the vicinity of the boundary between the second insulating layer 110a and the semiconductor substrate 100.

In the solid-state image pickup device 1000ι, the heat generated in the electron multiplication region 105de is transferred to the thermal conductive layer 110d2 mainly via the partition wall 150ι and the second insulating layer 110a, and is released from the end surface of the thermal conductive layer 110d2 to the outside. The heat generated in the logic circuit of the logic substrate 180 is transferred to the thermal conductive layer 110d2 mainly via the first insulating layer 120, the partition wall 150ι, and the second insulating layer 110a, and is released from the end surface of the thermal conductive layer 110d2 to the outside.

At this time, although the partition wall 150ι is not in contact with the thermal conductive layer 110d2, the partition wall 150ι is relatively close to the thermal conductive layer 110d2 (adjacent to the thermal conductive layer 110d2 with only the second insulating layer 110a interposed therebetween). Thus, heat can be smoothly delivered from the partition wall 150ι to the thermal conductive layer 110d2.

Note that the tip of the extending part 150b28 of the partition wall 150ι can be positioned in the second insulating layer 110a or the semiconductor substrate 100 with the partition wall 150ι being not in contact with the thermal conductive layer 110d2.

The solid-state image pickup device 1000ι can be manufactured by a method according to the method for manufacturing the solid-state image pickup device 1000B of the third embodiment (however, the protrusion amount of the metal material 208 to be the partition wall 150ι is reduced).

<37. Solid-State Image Pickup Device According to 35th Embodiment of Present Technology>

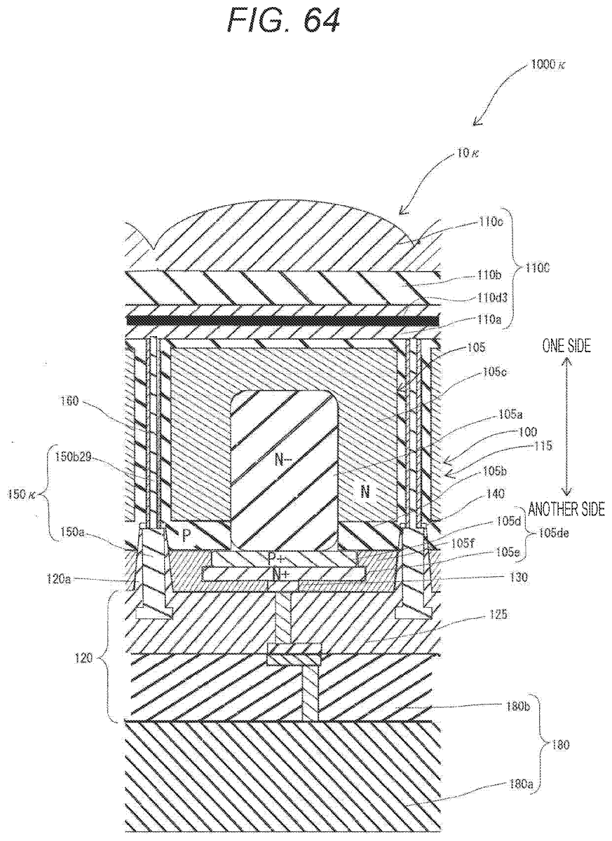

A solid-state image pickup device 1000κ according to the 35th embodiment of the present technology will be described with reference to FIG. 64. The solid-state image pickup device 1000κ according to the 35th embodiment has a configuration substantially similar to that of the solid-state image pickup device 1000C of the fourth embodiment except for the configuration of the partition wall.

In each pixel 10κ of the solid-state image pickup device 1000κ, as illustrated in FIG. 64, the extending part 150b29 of a partition wall 150κ is not in contact with the thermal conductive layer 110d3.

Specifically, the tip of the extending part 150b29 of the partition wall 150κ is positioned in the vicinity of the boundary between the second insulating layer 110a and the semiconductor substrate 100.

In the solid-state image pickup device 1000κ, the heat generated in the electron multiplication region 105de is transferred to the thermal conductive layer 110d3 mainly via the partition wall 150κ and a part of the second insulating layer 110a (a part on the another side of the thermal conductive layer 110d3), and is released from the end surface of the thermal conductive layer 110d3 to the outside. The heat generated in the logic circuit of the logic substrate 180 is transferred to the thermal conductive layer 110d3 mainly via the first insulating layer 120, the partition wall 150L, and a part of the second insulating layer 110a (a part on the another side of the thermal conductive layer 110d3), and is released from the end surface of the thermal conductive layer 110d3 to the outside.

At this time, although the partition wall 150κ is not in contact with the thermal conductive layer 110d3, the partition wall 150κ is relatively close to the thermal conductive layer 110d3 (adjacent to the thermal conductive layer 110d3 with only the lower part of the second insulating layer 110a interposed therebetween). Thus, heat can be smoothly delivered from the partition wall 150κ to the thermal conductive layer 110d3.

Note that the tip of the extending part 150b29 of the partition wall 150κ can be positioned in the second insulating layer 110a or the semiconductor substrate 100 with the partition wall 150κ being not in contact with the thermal conductive layer 110d3.

The solid-state image pickup device 1000κ can be manufactured by a method according to the method for manufacturing the solid-state image pickup device 1000C of the fourth embodiment (however, the protrusion amount of the metal material 208 to be the partition wall 150κ is reduced).

<38. Solid-State Image Pickup Device According to 36th Embodiment of Present Technology>

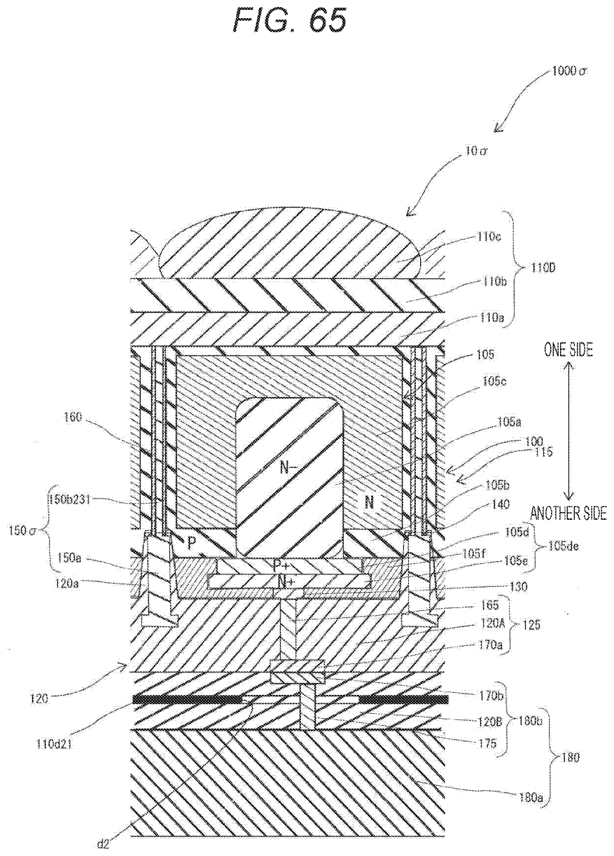

A solid-state image pickup device 1000σ according to the 36th embodiment of the present technology will be described with reference to FIG. 65. The solid-state image pickup device 1000σ according to the 36th embodiment has a configuration substantially similar to that of the solid-state image pickup device 1000Z of the 26th embodiment except for the configuration of the partition wall.

In each pixel 10σ of the solid-state image pickup device 1000σ, as illustrated in FIG. 65, a partition wall 150σ is not in contact with the thermal conductive layer 110d20.

Specifically, the partition wall 150σ does not have the second extending part 150b242 included in the solid-state image pickup device 1000Z of the 26th embodiment.

In the solid-state image pickup device 1000σ, the heat generated in the electron multiplication region 105de is transferred to the thermal conductive layer 110d21 via a region other than the electron multiplication region 105de of the semiconductor substrate 100, the wiring layer 125, and a part (upper part) of the wiring layer 180b, and is released from the end surface of the thermal conductive layer 110d21 to the outside. The heat generated in the logic circuit of the logic substrate 180 is transferred to the thermal conductive layer 110d21 via the another part (lower part) of the wiring layer 180b, and is released from the end surface of the thermal conductive layer 110d21 to the outside.

At this time, although the partition wall 150σ is not in contact with the thermal conductive layer 110d21, the partition wall 150σ is relatively close to the thermal conductive layer 110d21 (adjacent to the thermal conductive layer 110d21 with only the wiring layer 125 and a part of the wiring layer 180b interposed therebetween). Thus, heat can be smoothly delivered from the partition wall 150σ to the thermal conductive layer 110d21.

Note that in the partition wall 150σ, a second extending part 150b242 can be provided so that the second extending part 150b242 will not be in contact with the thermal conductive layer 110d21.

In this case, the partition wall 150σ can be further brought close to the thermal conductive layer 110d21, and heat can be more smoothly delivered from the partition wall 150σ to the thermal conductive layer 110d21.

The solid-state image pickup device 1000σ can be manufactured by a method according to the method for manufacturing the solid-state image pickup device 1000Z of the 26th embodiment (however, the step of forming the second extending part 150b242 is excluded).

<39. Solid-State Image Pickup Device According to 37th Embodiment of Present Technology>

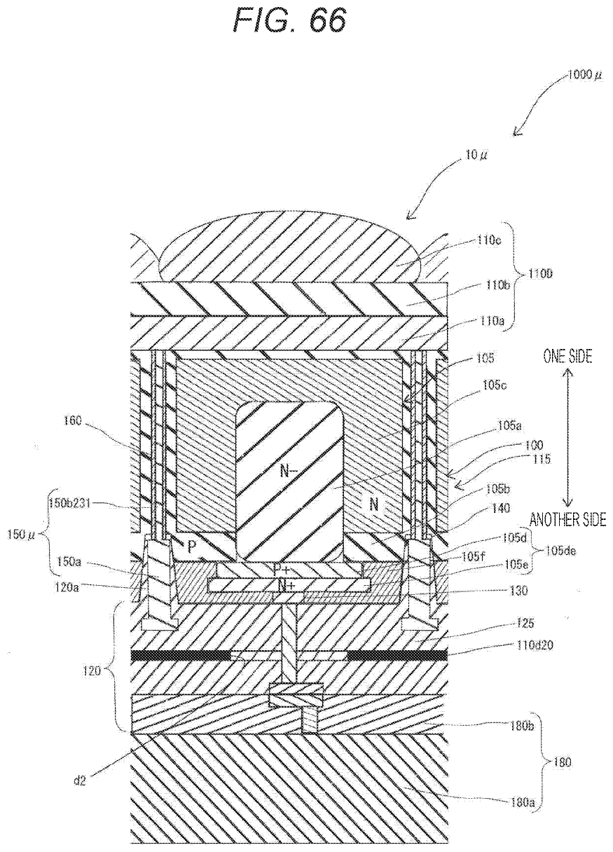

A solid-state image pickup device 1000μ according to the 37th embodiment of the present technology will be described with reference to FIG. 66. The solid-state image pickup device 1000μ according to the 37th embodiment has a configuration substantially similar to that of the solid-state image pickup device 1000Y of the 25th embodiment except for the configuration of the partition wall.

In each pixel 10μ of the solid-state image pickup device 1000μ, as illustrated in FIG. 66, a partition wall 150μ is not in contact with the thermal conductive layer 110d20.

Specifically, the partition wall 150μ does not have the second extending part 150b232 included in the solid-state image pickup device 1000Y of the 25th embodiment.

In the solid-state image pickup device 1000μ, the heat generated in the electron multiplication region 105de is transferred to the thermal conductive layer 110d20 via a region other than the electron multiplication region 105de of the semiconductor substrate 100 and a part (upper part) of the wiring layer 125, and is released from the end surface of the thermal conductive layer 110d20 to the outside. The heat generated in the logic circuit of the logic substrate 180 is transferred to the thermal conductive layer 110d20 via the wiring layer 180b and the another part (lower part) of the wiring layer 125, and is released from the end surface of the thermal conductive layer 110d20 to the outside.

At this time, although the partition wall 150μ is not in contact with the thermal conductive layer 110d20, the partition wall 150μ is relatively close to the thermal conductive layer 110d20 (adjacent to the thermal conductive layer 110d20 with only a part of the wiring layer 125 interposed therebetween). Thus, heat can be smoothly delivered from the partition wall 150μ to the thermal conductive layer 110d20.

Note that in the partition wall 150μ, a second extending part 150b232 can be provided so that the second extending part 150b232 will not be in contact with the thermal conductive layer 110d20.

In this case, the partition wall 150μ can be further brought close to the thermal conductive layer 110d20, and heat can be more smoothly delivered from the partition wall 150μ to the thermal conductive layer 110d20.

The solid-state image pickup device 1000μ can be manufactured by a method according to the method for manufacturing the solid-state image pickup device 1000Y of the 25th embodiment (however, the step of forming the second extending part 150b232 is excluded).

<40. Solid-State Image Pickup Device According to 38th Embodiment of Present Technology>

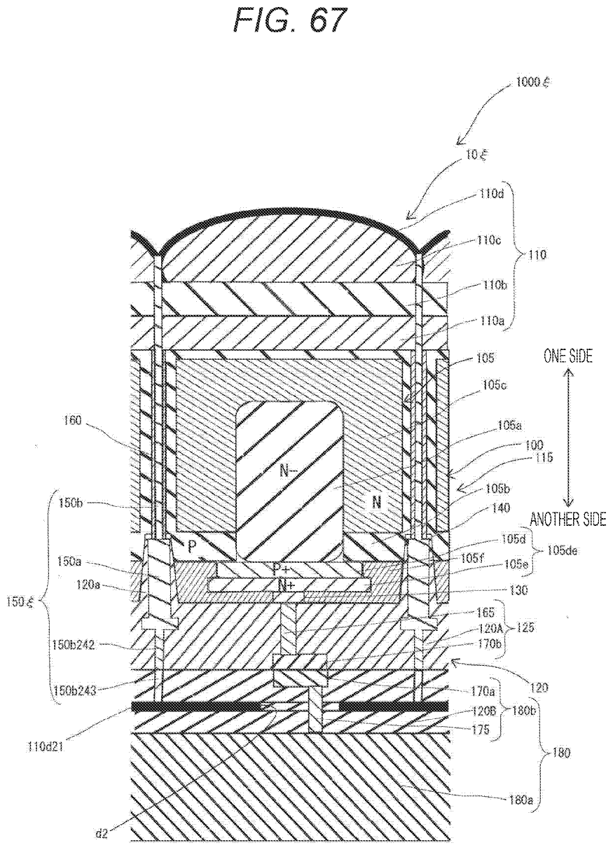

A solid-state image pickup device 1000ξ according to the 38th embodiment of the present technology will be described with reference to FIG. 67. The solid-state image pickup device 1000ξ according to the 38th embodiment has a configuration substantially similar to that of the solid-state image pickup device 1000Z of the 26th embodiment except that a thermal conductive layer is also provided on the one side of the semiconductor substrate 100. Furthermore, from another viewpoint, the solid-state image pickup device 1000 according to the 38th embodiment has a configuration substantially similar to that of the solid-state image pickup device 1000 of the first embodiment except that a thermal conductive layer is also provided on the another side of the semiconductor substrate 100.

In each pixel 10ξ of the solid-state image pickup device 1000ξ, as illustrated in FIG. 67, the first extending part 150b (denoted by the same reference number 150b because of the configuration same as the extending part 150b of the partition wall 150) of a partition wall 150ξ is in contact with the thermal conductive layer 110d, and the second extending part 150b242 is connected to the thermal conductive layer 110d21 via the connecting part 150b243.

In the solid-state image pickup device 1000ξ, the heat generated in the electron multiplication region 105de is transferred to the thermal conductive layer 110d and the thermal conductive layer 110d21 mainly via the partition wall 150ξ, and is released from the surface and the end surface of the thermal conductive layer 110d and the end surface of the thermal conductive layer 110d21 to the outside. The heat generated in the logic circuit of the logic substrate 180 is transferred to the thermal conductive layer 110d21 via a part (lower part) of the wiring layer 180b, one part is released from the end surface of the thermal conductive layer 110d21 to the outside, and another part is transferred to the thermal conductive layer 110d via the partition wall 150ξ, and is released from the surface and the end surface of the thermal conductive layer 110d to the outside.

As described above, according to the solid-state image pickup device 1000ξ, there is a plurality of systems of a release path of the heat generated in the electron multiplication region 105de and the logic circuit of the logic substrate 180, and thus the heat dissipation property can be remarkably improved.

Note that at least one of the thermal conductive layer 110d or the thermal conductive layer 110d21 can penetrate the corresponding thermal conductive layer.

The solid-state image pickup device 1000ξ can be manufactured by a method according to the method for manufacturing the solid-state image pickup device 1000Z of the 26th embodiment and the method for manufacturing the solid-state image pickup device 1000 of the first embodiment.

<41. Solid-State Image Pickup Device According to 39th Embodiment of Present Technology>

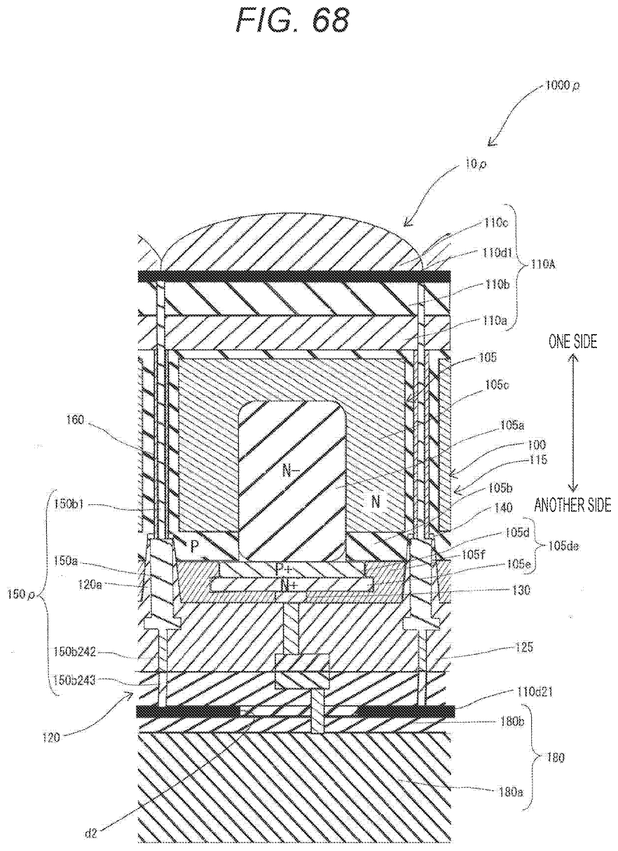

A solid-state image pickup device 1000ρ according to the 39th embodiment of the present technology will be described with reference to FIG. 68. The solid-state image pickup device 1000ρ according to the 39th embodiment has a configuration substantially similar to that of the solid-state image pickup device 1000Z of the 26th embodiment except that a thermal conductive layer is also provided on the one side of the semiconductor substrate 100. Furthermore, from another viewpoint, the solid-state image pickup device 1000ρ according to the 39th embodiment has a configuration substantially similar to that of the solid-state image pickup device 1000A of the second embodiment except that a thermal conductive layer is also provided on the another side of the semiconductor substrate 100.

In each pixel ρ of the solid-state image pickup device 1000ρ, as illustrated in FIG. 68, the first extending part 150b1 of a partition wall 150ρ (denoted by the same reference number 150b1 because of the configuration same as the extending part 150b1 of the partition wall 150A) is in contact with the thermal conductive layer 110d1, and the second extending part 150b242 is connected to the thermal conductive layer 110d21 via the connecting part 150b243.

In the solid-state image pickup device 1000ρ, the heat generated in the electron multiplication region 105de is transferred to the thermal conductive layer 110d1 and the thermal conductive layer 110d21 mainly via the partition wall 150ρ, and is released from the end surfaces of the thermal conductive layer 110d1 and the thermal conductive layer 110d21 to the outside. The heat generated in the logic circuit of the logic substrate 180 is transferred to the thermal conductive layer 110d21 via a part (lower part) of the wiring layer 180b, one part is released from the end surface of the thermal conductive layer 110d21 to the outside, and another part is transferred to the thermal conductive layer 110d1 via the partition wall 150ρ, and is released from the end surface of the thermal conductive layer 110d1 to the outside.

As described above, according to the solid-state image pickup device 1000ρ, there is a plurality of systems of a release path of the heat generated in the electron multiplication region 105de and the logic circuit of the logic substrate 180, and thus the heat dissipation property can be remarkably improved.

Note that at least one of the first extending part 150b1 or the second extending part 150b242 of the partition wall 150ρ can penetrate the corresponding thermal conductive layer.

The solid-state image pickup device 1000ρ can be manufactured by a method according to the method for manufacturing the solid-state image pickup device 1000Z of the 26th embodiment and the method for manufacturing the solid-state image pickup device 1000A of the second embodiment.

<42. Solid-State Image Pickup Device According to 40th Embodiment of Present Technology>

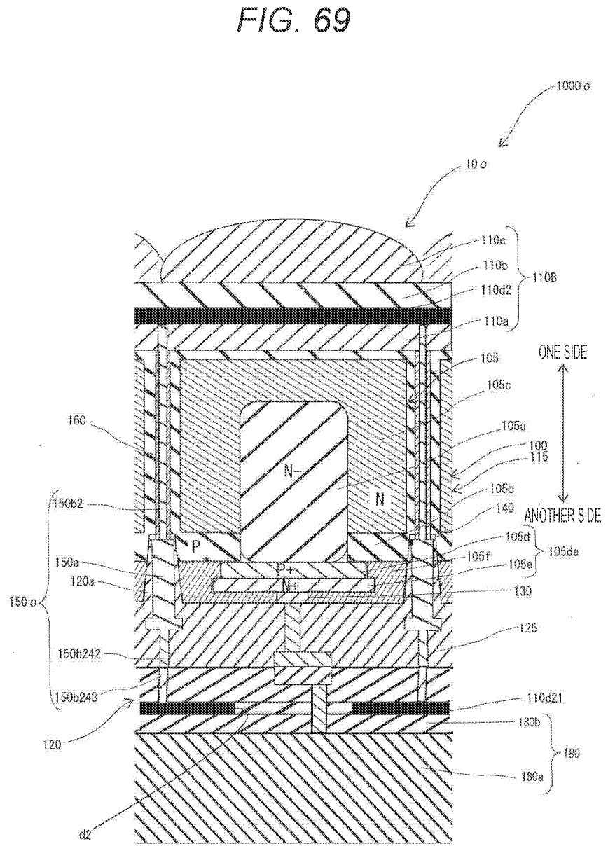

A solid-state image pickup device 1000∘ according to the 40th embodiment of the present technology will be described with reference to FIG. 69. The solid-state image pickup device 1000∘, as illustrated in FIG. 69, has a configuration substantially similar to that of the solid-state image pickup device 1000Z of the 26th embodiment except that a thermal conductive layer is also provided on the one side of the semiconductor substrate 100. Furthermore, from another viewpoint, the solid-state image pickup device 1000∘ according to the 40th embodiment has a configuration substantially similar to that of the solid-state image pickup device 1000B of the third embodiment except that a thermal conductive layer is also provided on the another side of the semiconductor substrate 100.

In each pixel 10∘ of the solid-state image pickup device 1000∘, as illustrated in FIG. 69, the first extending part 150b2 (denoted by the same reference number 150b2 because of the configuration same as the extending part 150b2 of the partition wall 150B) of a partition wall 150∘ is in contact with the thermal conductive layer 110d2, and the second extending part 150b242 is connected to the thermal conductive layer 110d21 via the connecting part 150b243.

In the solid-state image pickup device 1000∘, the heat generated in the electron multiplication region 105de is transferred to the thermal conductive layer 110d2 and the thermal conductive layer 110d21 mainly via the partition wall 150∘, and is released from the end surface of the thermal conductive layer 110d2 and the end surface of the thermal conductive layer 110d21 to the outside. The heat generated in the logic circuit of the logic substrate 180 is transferred to the thermal conductive layer 110d21 via a part (lower part) of the wiring layer 180b, one part is released from the end surface of the thermal conductive layer 110d21 to the outside, and another part is transferred to the thermal conductive layer 110d2 via the partition wall 150∘, and is released from the end surface of the thermal conductive layer 110d2 to the outside.

As described above, according to the solid-state image pickup device 1000∘, there is a plurality of systems of a release path of the heat generated in the electron multiplication region 105de and the logic circuit of the logic substrate 180, and thus the heat dissipation property can be remarkably improved.

The solid-state image pickup device 1000∘ can be manufactured by a method according to the method for manufacturing the solid-state image pickup device 1000Z of the 26th embodiment and the method for manufacturing the solid-state image pickup device 1000B of the third embodiment.

<43. Solid-State Image Pickup Device According to 41st Embodiment of Present Technology>

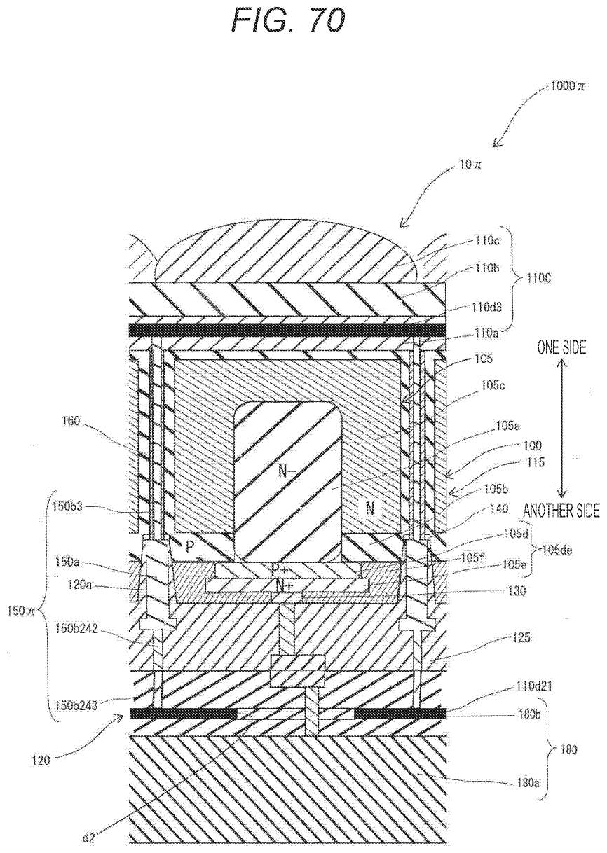

A solid-state image pickup device 1000π according to the 41st embodiment of the present technology will be described with reference to FIG. 70. The solid-state image pickup device 1000π, as illustrated in FIG. 70, has a configuration substantially similar to that of the solid-state image pickup device 1000Z of the 26th embodiment except that a thermal conductive layer is also provided on the one side of the semiconductor substrate 100. Furthermore, from another viewpoint, the solid-state image pickup device 1000π according to the 41st embodiment has a configuration substantially similar to that of the solid-state image pickup device 1000C of the fourth embodiment except that a thermal conductive layer is also provided on the another side of the semiconductor substrate 100.

In the solid-state image pickup device 1000π, as illustrated in FIG. 70, the first extending part 150b3 (denoted by the same reference number 150b3 because of the configuration same as the extending part 150b3 of the partition wall 150C) of a partition wall 150π is in contact with the thermal conductive layer 110d3, and the second extending part 150b242 is connected to the thermal conductive layer 110d21 via the connecting part 150b243.

In the solid-state image pickup device 1000π, the heat generated in the electron multiplication region 105de is transferred to the thermal conductive layer 110d3 and the thermal conductive layer 110d21 mainly via the partition wall 150π, and is released from the end surface of the thermal conductive layer 110d3 and the end surface of the thermal conductive layer 110d21 to the outside. The heat generated in the logic circuit of the logic substrate 180 is transferred to the thermal conductive layer 110d21 via a part (lower part) of the wiring layer 180b, one part is released from the end surface of the thermal conductive layer 110d21 to the outside, and another part is transferred to the thermal conductive layer 110d3 via the partition wall 150π, and is released from the end surface of the thermal conductive layer 110d3 to the outside.

As described above, according to the solid-state image pickup device 1000π, there is a plurality of systems of a release path of the heat generated in the electron multiplication region 105de and the logic circuit of the logic substrate 180, and thus the heat dissipation property can be remarkably improved.

The solid-state image pickup device 1000π can be manufactured by a method according to the method for manufacturing the solid-state image pickup device 1000Z of the 26th embodiment and the method for manufacturing the solid-state image pickup device 1000C of the fourth embodiment.

<44. Solid-State Image Pickup Device According to Modification Example of Present Technology>

The configuration of each of the first to 41st embodiments described above can be appropriately changed.

For example, the configurations of the solid-state image pickup devices of the embodiments above can be combined with each other within a range not technically contradictory.

For example, the solid-state image pickup device of each of the embodiments above can be a linear image sensor (line image sensor) in which a plurality of pixels is arranged one-dimensionally in series.

For example, the solid-state image pickup device of each of the embodiments above can have a single pixel structure that includes only one pixel.

For example, the solid-state image pickup device of each of the embodiments above can have a configuration in which each pixel has a plurality of photoelectric converters.

For example, the at least one photoelectric converter of the solid-state image pickup device of each of the embodiments above need not necessarily be a SPAD. Specifically, the at least one photoelectric converter of the solid-state image pickup device of each of the embodiments can be a photodiode without the electron multiplication region 105de (for example, a photodiode having a PN junction such as a PN photodiode and a PIN photodiode).

Furthermore, the at least one photoelectric converter of the solid-state image pickup device of each of the embodiments above can be a photodiode that is not a back-illuminated type, that is, a front-illuminated photodiode in which light is incident from the surface side (the another surface side) of a semiconductor substrate.

For example, a Ge substrate, a GaAs substrate, an InGaAs substrate, and the like can be used as the semiconductor substrate of the solid-state image pickup device of each of the embodiments above.

For example, the wiring layer 125 of the pixel sensor substrate of the solid-state image pickup device of each of the embodiments above is a single wiring layer having a single wiring member 170a in the insulating layer, but can be a multilayer wiring layer in which a plurality of wiring members is arranged in the insulating layer in the thickness direction.

For example, the wiring layer 180b of the logic substrate 180 of the solid-state image pickup device of each of the embodiments above is a single wiring layer having a single wiring member 170b in the insulating layer, but can be a multilayer wiring layer in which a plurality of wiring members is arranged in the insulating layer in the thickness direction.

For example, a material other than SiO₂, for example, SiN, SiON, or the like can be used as a material of the first insulating layer and the second insulating layer of the solid-state image pickup device of each of the embodiments above.

For example, the logic substrate 180 need not be a component of the solid-state image pickup device of each of the embodiments above. In this case, an electronic apparatus including the solid-state image pickup device and the logic substrate 180 can be provided.

Furthermore, the logic substrate 180 can be separated from a pixel region (pixel chip) in which a plurality of pixels 10 is arranged.

Furthermore, the electronic apparatus according to the present technology can include, instead of the logic substrate 180, a circuit unit that is separate from the solid-state image pickup device and has a function similar to that of the logic substrate 180.

For example, the support substrate 190 need not be a component of the solid-state image pickup device of each of the embodiments above. In this case, an electronic apparatus including the solid-state image pickup device and the support substrate 190 can be provided.

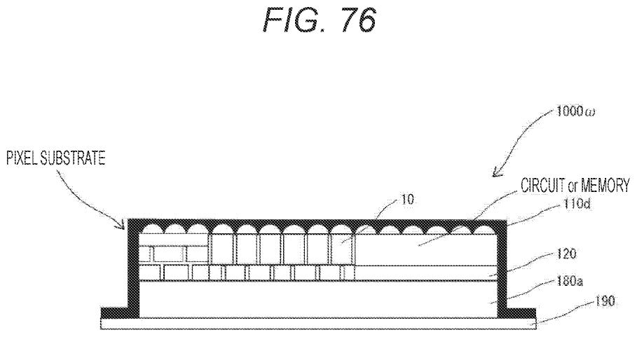

In the above description, although the description has been made on the assumption that the solid-state image pickup device has a COW structure, the solid-state image pickup device of each of the embodiments above can have a wafer-on-wafer structure (WOW structure) such as the solid-state image pickup device 1000ω illustrated in FIG. 76, for example.

In the solid-state image pickup device 1000ω, a control circuit that controls the pixel 10, a memory that temporarily stores signals output from the pixel 10, and the like are arranged around a pixel substrate (substrate on which the pixel 10 is formed).

<45. Layout of Thermal Conductive Layer in Entire Solid-State Image Pickup Device>

In each of the embodiments described above, the Layout of the thermal conductive layer in the entire solid-state image pickup device has several variations as listed below.

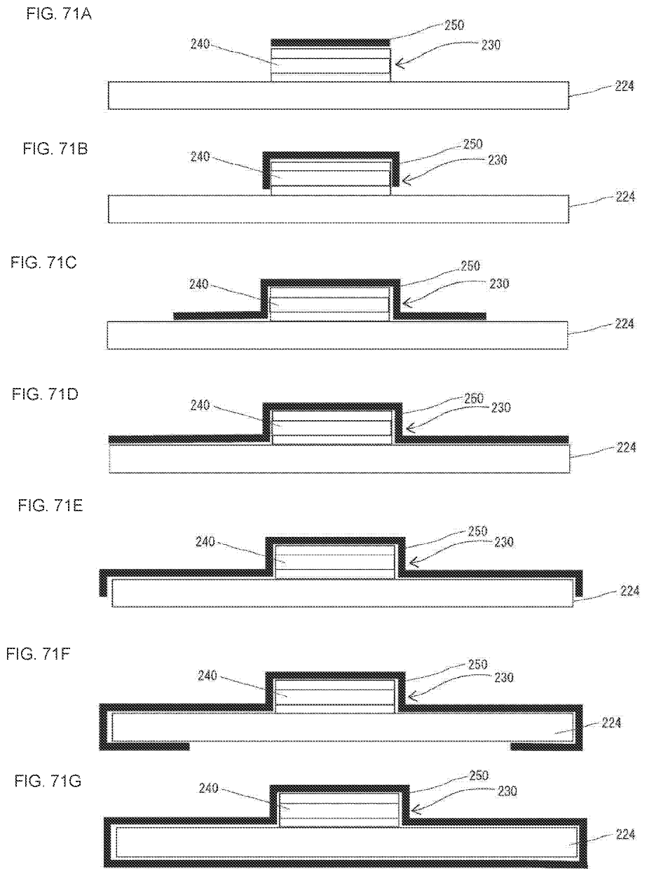

First, as illustrated in FIGS. 71A to 71G, a case where a series of integrated thermal conductive layers 250 constitutes at least a surface layer of a pixel region 230 (a region where a plurality of pixels is arranged) will be described. FIGS. 71A to 71G illustrate a simplified cross section of the entire solid-state image pickup device in a case where a thermal conductive layer 250 constitutes a surface layer of the pixel region 230 (for example, the first embodiment, the sixth embodiment, the 10th embodiment, the 14th embodiment, the 18th embodiment, the 19th embodiment, the 22nd embodiment, the 23rd embodiment, the 24th embodiment, the 27th embodiment, and the 32nd embodiment). In each of the solid-state image pickup devices illustrated in FIGS. 71A to 71G, a cross section orthogonal to the paper surface has a configuration similar to a cross section parallel to the paper surface.

For example, as illustrated in FIG. 71A, there is a Layout 1 in which the thermal conductive layer 250 constitutes the upper part of the pixel region 230. That is, in Layout 1, the thermal conductive layer 250 is arranged on the upper side of a semiconductor substrate 240.

For example, as illustrated in FIG. 71B, there is a Layout 2 in which the thermal conductive layer 250 constitutes an upper part and a side part of the pixel region 230. That is, in the Layout 2, the thermal conductive layer 250 is arranged on the upper side and each end surface side of the semiconductor substrate 240.

For example, as illustrated in FIG. 71C, there is a Layout 3 in which the thermal conductive layer 250 constitutes the upper part and the side part of the pixel region 230 and covers a part of the peripheral part of the pixel region 230 on the upper surface of the semiconductor substrate 224. That is, in the Layout 3, the thermal conductive layer 250 is arranged on the upper side and each end surface side of the semiconductor substrate 240.

For example, as illustrated in FIG. 71D, there is a Layout 4 in which the thermal conductive layer 250 constitutes the upper part and the side part of the pixel region 230 and covers the entire peripheral part of the pixel region 230 on the upper surface of the semiconductor substrate 224. That is, in the Layout 4, the thermal conductive layer 250 is arranged on the upper side and each end surface side of the semiconductor substrate 240.

For example, as illustrated in FIG. 71E, there is a Layout 5 in which the thermal conductive layer 250 constitutes the upper part and the side part of the pixel region 230, and covers the entire peripheral part of the pixel region 230 on the upper surface of the semiconductor substrate 224 and each side surface of the semiconductor substrate 224. That is, in the Layout 5, the thermal conductive layer 250 is arranged on the upper side and each end surface side of the semiconductor substrate 240.

For example, as illustrated in FIG. 71F, there is a Layout 6 in which the thermal conductive layer 250 constitutes the upper part and the side part of the pixel region 230, and covers the entire peripheral part of the pixel region 230 on the upper surface of the semiconductor substrate 224 and the side surface and a part of the lower surface of the semiconductor substrate 224. That is, in the Layout 6, the thermal conductive layer 250 is arranged on the upper side and each end surface side of the semiconductor substrate 240.

For example, as illustrated in FIG. 71G, there is a Layout 7 in which the thermal conductive layer 250 constitutes the upper part and the side part of the pixel region 230, and covers the entire peripheral part of the pixel region 230 on the upper surface of the semiconductor substrate 224 and the entire side surfaces and the entire lower surface of the semiconductor substrate 224. That is, in the Layout 7, the thermal conductive layer 250 is arranged on the upper side, each end surface side, and the lower side of the semiconductor substrate 240. As described above, in the Layout 7, the thermal conductive layer 250 extends across the back surface side and the surface side of the semiconductor substrate 240.

The surface area of the thermal conductive layer 250 gradually increases from the Layout 1 to the Layout 7, and the heat dissipation effect also increases accordingly. Meanwhile, trouble of layout of the thermal conductive layer 250 presumably increases from the Layout 1 to the Layout 7, and thus it is preferable to employ a suitable Layout on the basis of comparison and consideration of the heat dissipation effect and the Layout property.

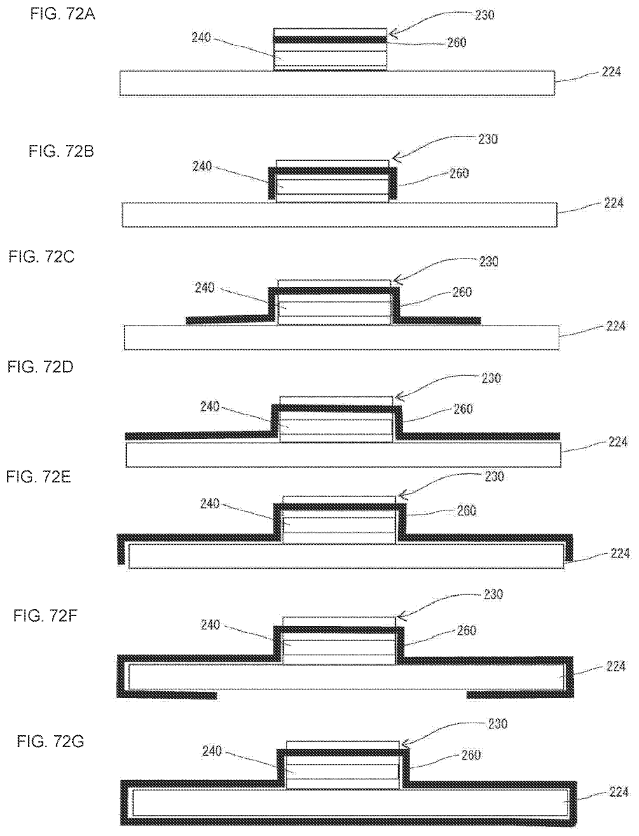

Next, as illustrated in FIGS. 72A to 72G, a case where a series of integrated thermal conductive layers 260 constitutes at least an inner layer of the pixel region 230 on the upper side of the semiconductor substrate 240 will be described. FIGS. 72A to 72G illustrate a simplified cross section of the entire solid-state image pickup device in a case where a thermal conductive layer 260 constitutes an inner layer of the pixel region 230 on the upper side of the semiconductor substrate 240 (for example, the second to fifth embodiments, the seventh to ninth embodiments, the 11th to 13th embodiments, the 15th to 17th embodiments, the 20th embodiment, the 21st embodiment, the 28th to 30th embodiments, and the 33rd to 35th embodiments). In each of the solid-state image pickup devices illustrated in FIGS. 72A to 72G, a cross section orthogonal to the paper surface has a configuration similar to a cross section parallel to the paper surface.

For example, as illustrated in FIG. 72A, there is a Layout 8 in which the thermal conductive layer 260 constitutes an inner layer of the pixel region 230. That is, in Layout 8, the thermal conductive layer 260 is arranged on the upper side of semiconductor substrate 240.

For example, as illustrated in FIG. 72B, there is a Layout 9 in which the thermal conductive layer 260 constitutes an inner layer and a part of the side part of the pixel region 230. That is, in the Layout 9, the thermal conductive layer 260 is arranged on the upper side and each end surface side of the semiconductor substrate 240.

For example, as illustrated in FIG. 72C, there is a Layout 10 in which the thermal conductive layer 260 constitutes an inner layer and a part of the side part of the pixel region 230 and covers a part of the peripheral part of the pixel region 230 on the upper surface of the semiconductor substrate 224. That is, in the Layout 10, the thermal conductive layer 260 is arranged on the upper side and each end surface side of the semiconductor substrate 240.

For example, as illustrated in FIG. 72D, there is a Layout 11 in which the thermal conductive layer 260 constitutes an inner layer and a part of the side part of the pixel region 230 and covers the entire peripheral part of the pixel region 230 on the upper surface of the semiconductor substrate 224. That is, in the Layout 11, the thermal conductive layer 260 is arranged on the upper side and each end surface side of the semiconductor substrate 240.

For example, as illustrated in FIG. 72E, there is a Layout 12 in which the thermal conductive layer 260 constitutes an inner layer and a part of the side part of the pixel region 230, and covers the entire peripheral part of the pixel region 230 on the upper surface of the semiconductor substrate 224 and the side surface of the semiconductor substrate 224. That is, in the Layout 12, the thermal conductive layer 260 is arranged on the upper side and each end surface side of the semiconductor substrate 240.

For example, as illustrated in FIG. 72F, there is a Layout 13 in which the thermal conductive layer 260 constitutes an inner layer and a part of the side part of the pixel region 230, and covers the entire peripheral part of the pixel region 230 on the upper surface of the semiconductor substrate 224 and the side surface and a part of the lower surface of the semiconductor substrate 224. That is, in the Layout 13, the thermal conductive layer 260 is arranged on the upper side and each end surface side of the semiconductor substrate 240.

For example, as illustrated in FIG. 72G, there is a Layout 14 in which the thermal conductive layer 260 constitutes an inner layer and a part of the side part of the pixel region 230, and covers the entire peripheral part of the pixel region 230 on the upper surface of the semiconductor substrate 224 and the entire side surface and the entire lower surface of the semiconductor substrate 224. That is, in the Layout 14, the thermal conductive layer 260 is arranged on the upper side, each end surface side, and the lower side of the semiconductor substrate 240. As described above, in the Layout 14, the thermal conductive layer 260 extends across the back surface side and the surface side of the semiconductor substrate 240.

The surface area of the thermal conductive layer 260 gradually increases from the Layout 8 to the Layout 14, and the heat dissipation effect also increases accordingly. Meanwhile, trouble of layout of the thermal conductive layer 260 presumably increases from the Layout 8 to the Layout 14, and thus it is preferable to employ a suitable Layout on the basis of comparison and consideration of the heat dissipation effect and the Layout property.

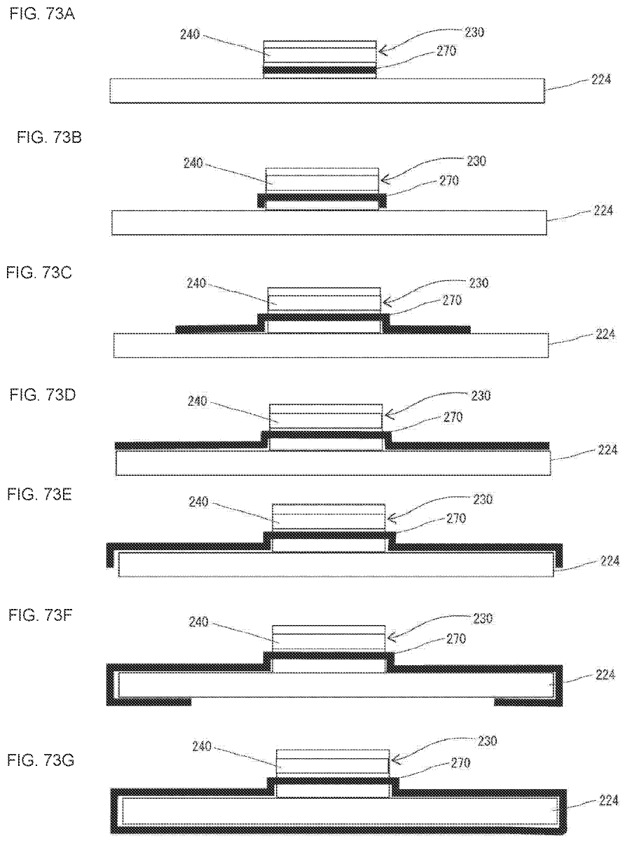

Next, as illustrated in FIGS. 73A to 73G, a case where a series of integrated thermal conductive layers 270 constitutes at least an inner layer of the pixel region 230 on the lower side of the semiconductor substrate 240 (for example, the 25th embodiment, the 26th embodiment, the 31st embodiment, and the 35th to 37th embodiments) will be described. FIGS. 73A to 73G illustrate a simplified cross section of the entire solid-state image pickup device in a case where a thermal conductive layer 270 constitutes an inner layer of the pixel region 230 on the lower side of the semiconductor substrate 240. In each of the solid-state image pickup devices illustrated in FIGS. 73A to 73G, a cross section orthogonal to the paper surface has a configuration similar to a cross section parallel to the paper surface.

For example, as illustrated in FIG. 73A, there is a Layout 15 in which the thermal conductive layer 270 constitutes an inner layer of the pixel region 230.

For example, as illustrated in FIG. 73B, there is a Layout 16 in which the thermal conductive layer 270 constitutes an inner layer and the lower part of the side part of the pixel region 230.

For example, as illustrated in FIG. 73C, there is a Layout 17 in which the thermal conductive layer 270 constitutes an inner layer and the lower part of the side part of the pixel region 230 and covers a part of the peripheral part of the pixel region 230 on the upper surface of the semiconductor substrate 224.

For example, as illustrated in FIG. 73D, there is a Layout 18 in which the thermal conductive layer 270 constitutes an inner layer and the lower part of the side part of the pixel region 230 and covers the entire peripheral part of the pixel region 230 on the upper surface of the semiconductor substrate 224.

For example, as illustrated in FIG. 73E, there is a Layout 19 in which the thermal conductive layer 270 constitutes an inner layer and the lower part of the side part of the pixel region 230, and covers the entire peripheral part of the pixel region 230 on the upper surface of the semiconductor substrate 224 and the side surface of the semiconductor substrate 224.

For example, as illustrated in FIG. 73F, there is a Layout 20 in which the thermal conductive layer 270 constitutes an inner layer and the lower part of the side part of the pixel region 230, and covers the entire peripheral part of the pixel region 230 on the upper surface of the semiconductor substrate 224 and the side surface and a part of the lower surface of the semiconductor substrate 224.

For example, as illustrated in FIG. 73G, there is a Layout 21 in which the thermal conductive layer 270 constitutes an inner layer and the lower part of the side part of the pixel region 230, and covers the entire peripheral part of the pixel region 230 on the upper surface of the semiconductor substrate 224 and the entire side surface and the entire lower surface of the semiconductor substrate 224. As described above, in the Layout 21, the thermal conductive layer 270 extends across the back surface side and the surface side of the semiconductor substrate 240.

In any of the Layouts 15 to 21, the thermal conductive layer 270 is arranged on the lower side of the semiconductor substrate 240.

The surface area of the thermal conductive layer 270 gradually increases from the Layout 15 to the Layout 21, and the heat dissipation effect also increases accordingly. Meanwhile, trouble of layout of the thermal conductive layer 270 presumably increases from the Layout 15 to the Layout 21, and thus it is preferable to employ a suitable Layout on the basis of comparison and consideration of the heat dissipation effect and the Layout property.

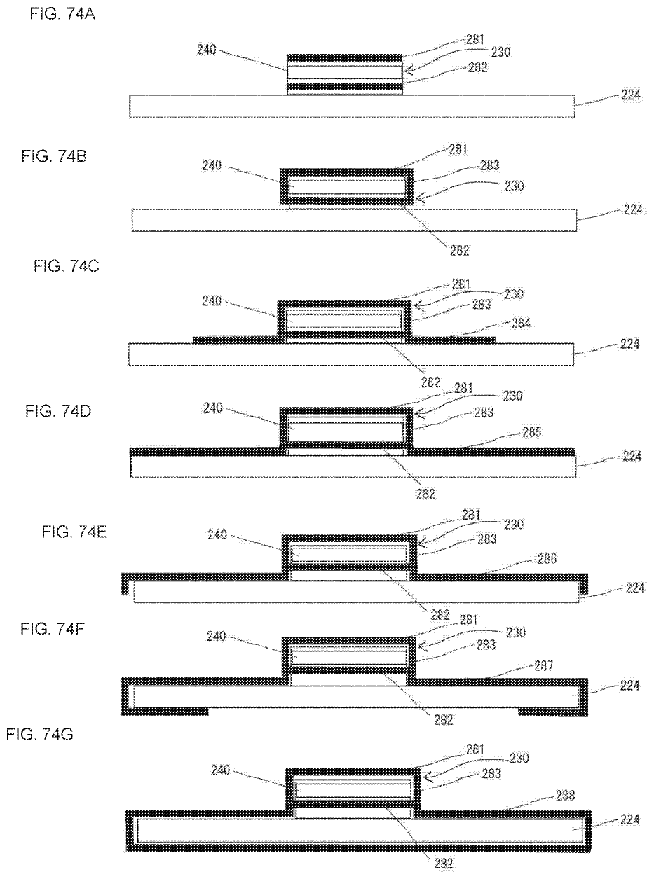

Next, as illustrated in FIGS. 74A to 74G, a case where the thermal conductive layer constitutes at least a surface layer of the pixel region 230 and constitutes an inner layer of the pixel region 230 on the lower side of the semiconductor substrate 240 will be described. FIGS. 74A to 74G illustrate a simplified cross section of the entire solid-state image pickup device in a case where the thermal conductive layer constitutes at least a surface layer of the pixel region 230 and constitutes an inner layer of the pixel region 230 on the lower side of the semiconductor substrate 240 (for example, the 38th embodiment). In each of the solid-state image pickup devices illustrated in FIGS. 74A to 74G, a cross section orthogonal to the paper surface has a configuration similar to a cross section parallel to the paper surface.

For example, in the Layout 22 illustrated in FIG. 74A, a thermal conductive layer 281 constitutes the upper part of the pixel region 230, and a thermal conductive layer 282 constitutes an inner layer of the pixel region 230. That is, in the Layout 22, the thermal conductive layers are arranged on the upper side and the lower side of the semiconductor substrate 240.

For example, in the Layout 23 illustrated in FIG. 74B, a thermal conductive layer 281 that constitutes the upper part of the pixel region 230 and a thermal conductive layer 282 that constitutes an inner layer of the pixel region 230 are connected via a thermal conductive layer 283 that constitutes the side part of the pixel region 230.

For example, in the Layout 24 illustrated in FIG. 74C, a thermal conductive layer 281 that constitutes the upper part of the pixel region 230 and a thermal conductive layer 282 that constitutes an inner layer of the pixel region 230 are connected via a thermal conductive layer 283 that constitutes the side part of the pixel region 230. Moreover, in the Layout 24, a thermal conductive layer 284 that covers a part of the peripheral part of the pixel region 230 on the upper surface of the semiconductor substrate 224 is connected to the connecting part between the thermal conductive layer 282 and the thermal conductive layer 283.

For example, in the Layout 25 illustrated in FIG. 74D, a thermal conductive layer 281 that constitutes the upper part of the pixel region 230 and a thermal conductive layer 282 that constitutes an inner layer of the pixel region 230 are connected via a thermal conductive layer 283 that constitutes the side part of the pixel region 230. Moreover, in the Layout 25, a thermal conductive layer 285 that covers the entire peripheral part of the pixel region 230 on the upper surface of the semiconductor substrate 224 is connected to the connecting part between the thermal conductive layer 282 and the thermal conductive layer 283.

For example, in the Layout 26 illustrated in FIG. 74E, a thermal conductive layer 281 that constitutes the upper part of the pixel region 230 and a thermal conductive layer 282 that constitutes an inner layer of the pixel region 230 are connected via a thermal conductive layer 283 that constitutes the side part of the pixel region 230. Moreover, in the Layout 26, a thermal conductive layer 286 that covers the entire peripheral part of the pixel region 230 on the upper surface of the semiconductor substrate 224 and each side surface of the semiconductor substrate 224 is connected to the connecting part between the thermal conductive layer 282 and the thermal conductive layer 283.

For example, in the Layout 27 illustrated in FIG. 74F, a thermal conductive layer 281 that constitutes the upper part of the pixel region 230 and a thermal conductive layer 282 that constitutes an inner layer of the pixel region 230 are connected via the thermal conductive layer 283 that constitutes the side part of the pixel region 230. Moreover, in the Layout 27, a thermal conductive layer 287 that covers the entire peripheral part of the pixel region 230 on the upper surface of the semiconductor substrate 224 and each side surface and a part of the lower surface of the semiconductor substrate 224 is connected to the connecting part between the thermal conductive layer 282 and the thermal conductive layer 283.

For example, in the Layout 28 illustrated in FIG. 74G, a thermal conductive layer 281 that constitutes the upper part of the pixel region 230 and a thermal conductive layer 282 that constitutes an inner layer of the pixel region 230 are connected via a thermal conductive layer 283 that constitutes the side part of the pixel region 230. Moreover, in the Layout 28, a thermal conductive layer 288 that covers the entire peripheral part of the pixel region 230 on the upper surface of the semiconductor substrate 224 and each side surface and the entire lower surface of the semiconductor substrate 224 is connected to the connecting part between the thermal conductive layer 282 and the thermal conductive layer 283.

That is, in the Layouts 23 to 28, the thermal conductive layer is arranged on the upper side, each end surface side, and the lower side of the semiconductor substrate 240. That is, in the Layout 23 to 28, the thermal conductive layer extends across the back surface side and the surface side of the semiconductor substrate 240 as a whole.

The surface area of the thermal conductive layer gradually increases from the Layout 22 to the Layout 28, and the heat dissipation effect also increases accordingly. Meanwhile, trouble of layout of the thermal conductive layer presumably increases from the Layout 22 to the Layout 28, and thus it is preferable to employ a suitable Layout on the basis of comparison and consideration of the heat dissipation effect and the Layout property.

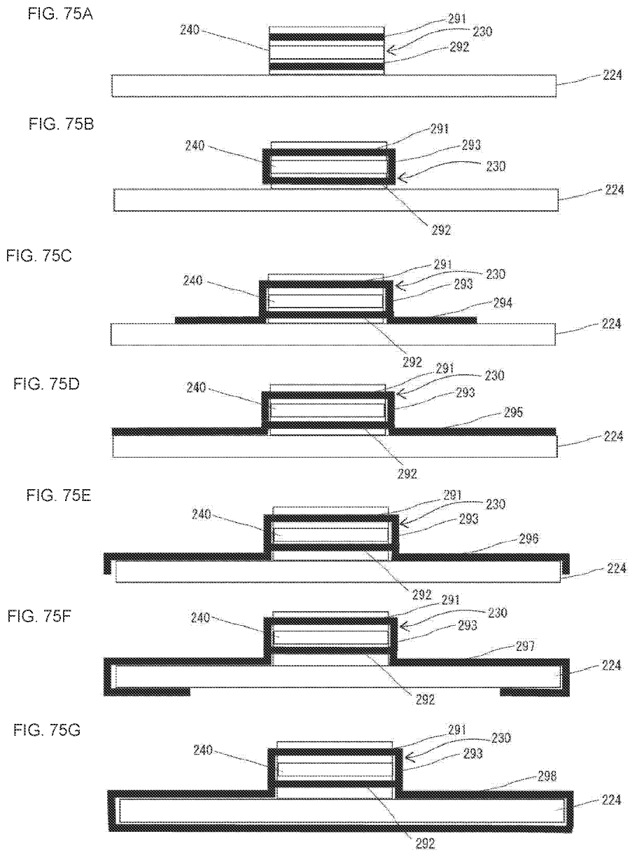

Next, as illustrated in FIGS. 75A to 75G, a case where the thermal conductive layer constitutes at least an inner layer of the pixel region 230 on the upper side and the lower side of the semiconductor substrate 240 will be described. FIGS. 75A to 75G illustrate a simplified cross section of the entire solid-state image pickup device in a case where the thermal conductive layer constitutes at least an inner layer of the pixel region 230 on the upper side and the lower side of the semiconductor substrate 240 (for example, the 39th to 41st embodiments). In each of the solid-state image pickup devices illustrated in FIGS. 75A to 75G, a cross section orthogonal to the paper surface has a configuration similar to a cross section parallel to the paper surface.

For example, in the Layout 29 illustrated in FIG. 75A, a thermal conductive layer 291 constitutes an inner layer of the pixel region 230 on the upper side of the semiconductor substrate 240, and a thermal conductive layer 292 constitutes an inner layer of the pixel region 230 on the lower side of the semiconductor substrate 240. That is, in the Layout 29, the thermal conductive layers are arranged on the upper side and the lower side of the semiconductor substrate 240.

For example, in the Layout 30 illustrated in FIG. 75B, a thermal conductive layer 291 that constitutes an inner layer of the pixel region 230 on the upper side of the semiconductor substrate 240 and a thermal conductive layer 292 that constitutes an inner layer of the pixel region 230 on the lower side of the semiconductor substrate 240 are connected via a thermal conductive layer 293 that constitutes the side part of the pixel region 230.

For example, in the Layout 31 illustrated in FIG. 75C, a thermal conductive layer 291 that constitutes an inner layer of the pixel region 230 on the upper side of the semiconductor substrate 240 and a thermal conductive layer 292 that constitutes an inner layer of the pixel region 230 on the lower side of the semiconductor substrate 240 are connected via a thermal conductive layer 293 that constitutes the side part of the pixel region 230. Moreover, in the Layout 31, a thermal conductive layer 294 that covers a part of the peripheral part of the pixel region 230 on the upper surface of the semiconductor substrate 224 is connected to the connecting part between the thermal conductive layer 292 and the thermal conductive layer 293.

For example, in the Layout 32 illustrated in FIG. 75D, a thermal conductive layer 291 that constitutes an inner layer of the pixel region 230 on the upper side of the semiconductor substrate 240 and a thermal conductive layer 292 that constitutes an inner layer of the pixel region 230 on the lower side of the semiconductor substrate 240 are connected via a thermal conductive layer 293 that constitutes the side part of the pixel region 230. Moreover, in the Layout 32, a thermal conductive layer 295 that covers the entire peripheral part of the pixel region 230 on the upper surface of the semiconductor substrate 224 is connected to the connecting part between the thermal conductive layer 292 and the thermal conductive layer 293.

For example, in the Layout 33 illustrated in FIG. 75E, a thermal conductive layer 291 that constitutes an inner layer of the pixel region 230 on the upper side of the semiconductor substrate 240 and a thermal conductive layer 292 that constitutes an inner layer of the pixel region 230 on the lower side of the semiconductor substrate 240 are connected via a thermal conductive layer 293 that constitutes the side part of the pixel region 230. Moreover, in the Layout 33, a thermal conductive layer 296 that covers the entire peripheral part of the pixel region 230 on the upper surface of the semiconductor substrate 224 and each side surface of the semiconductor substrate 224 is connected to the connecting part between the thermal conductive layer 292 and the thermal conductive layer 293.

For example, in the Layout 34 illustrated in FIG. 75F, a thermal conductive layer 291 that constitutes an inner layer of the pixel region 230 on the upper side of the semiconductor substrate 240 and a thermal conductive layer 292 that constitutes an inner layer of the pixel region 230 on the lower side of the semiconductor substrate 240 are connected via a thermal conductive layer 293 that constitutes the side part of the pixel region 230. Moreover, in the Layout 34, a thermal conductive layer 297 that covers the entire peripheral part of the pixel region 230 on the upper surface of the semiconductor substrate 224 and each side surface and a part of the lower surface of the semiconductor substrate 224 is connected to the connecting part between the thermal conductive layer 292 and the thermal conductive layer 293.

For example, in the Layout 35 illustrated in FIG. 75G, a thermal conductive layer 291 that constitutes an inner layer of the pixel region 230 on the upper side of the semiconductor substrate 240 and a thermal conductive layer 292 that constitutes an inner layer of the pixel region 230 on the lower side of the semiconductor substrate 240 are connected via a thermal conductive layer 293 that constitutes the side part of the pixel region 230. Moreover, in the Layout 35, a thermal conductive layer 298 that covers the entire peripheral part of the pixel region 230 on the upper surface of the semiconductor substrate 224 and each side surface and the entire lower surface of the semiconductor substrate 224 is connected to the connecting part between the thermal conductive layer 292 and the thermal conductive layer 293.

That is, in the Layouts 30 to 35, the thermal conductive layer is arranged on the upper side, each end surface side, and the lower side of the semiconductor substrate 240. That is, in the Layout 30 to 35, the thermal conductive layer extends across the back surface side and the surface side of the semiconductor substrate 240 as a whole.

The surface area of the thermal conductive layer gradually increases from the Layout 29 to the Layout 35, and the heat dissipation effect also increases accordingly. Meanwhile, trouble of layout of the thermal conductive layer presumably increases from the Layout 29 to the Layout 35, and thus it is preferable to employ a suitable Layout on the basis of comparison and consideration of the heat dissipation effect and the Layout property.

<46. Example of Electronic Apparatus According to 42nd Embodiment of Present Technology>

An electronic apparatus of a 42nd embodiment according to the present technology is an electronic apparatus including the solid-state image pickup device of the first aspect according to the present technology, and the solid-state image pickup device of the first aspect according to the present technology is a solid-state image pickup device including: a semiconductor substrate having a first main surface which is a light incident side and a second main surface which is a side opposite to the first main surface, in which a light receiving element arranged two-dimensionally on the first main surface is formed; a light-transmissive substrate arranged above the light receiving elements; a wiring layer formed on the second main surface of the semiconductor substrate; a first rewiring electrically connected to an internal electrode formed in the wiring layer; and a second rewiring formed on the second main surface of the semiconductor substrate.

Furthermore, the electronic apparatus according of a 42nd embodiment according to the present technology is an electronic apparatus including the solid-state image pickup device of the second aspect according to the present technology, and the solid-state image pickup device of the second aspect according to the present technology is a solid-state image pickup device, including: a sensor substrate including a first semiconductor substrate having a first main surface which is a light incident side and a second main surface which is a side opposite to the first main surface, in which a light receiving element arranged two-dimensionally on the first main surface is formed, and a first wiring layer formed on the second main surface of the first semiconductor substrate; a circuit substrate including a second semiconductor substrate having a third main surface which is a light incident side and a fourth main surface which is a side opposite to the third main surface, and a second wiring layer formed on the third main surface of the second semiconductor substrate; a light transmissive substrate arranged above the light receiving element; a first rewiring electrically connected to an internal electrode formed in the second wiring layer; and a second rewiring formed on the fourth main surface side of the second semiconductor substrate, in which the first wiring layer of the sensor substrate and the second wiring layer of the circuit substrate are bonded together to form a stacked structure of the sensor substrate and the circuit substrate.

For example, the electronic apparatus of the 42nd embodiment according to the present technology is an electronic apparatus including a solid-state image pickup device of any one of the first to 41st embodiments according to the present technology.

<47. Use Example of Solid-State Image Pickup Device to which Present Technology is Applied>

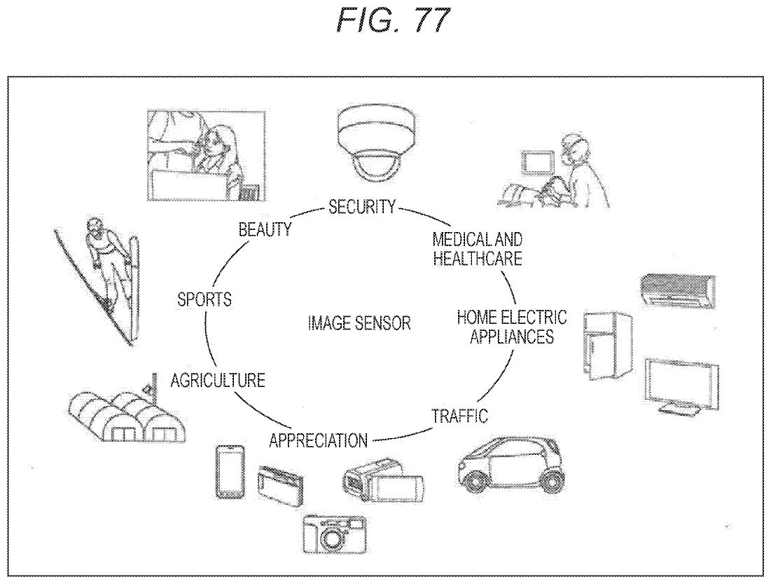

FIG. 77 is a diagram illustrating use examples of the solid-state image pickup device of the first to 41st embodiments according to the present technology as an image sensor.

The solid-state image pickup device of the first to 41st embodiments described above can be used in various cases of sensing light such as visible light, infrared light, ultraviolet light, and X-rays as described below, for example. That is, as illustrated in FIG. 77, for example, the solid-state image pickup device of any one of the first to 41st embodiments can be used in a device (for example, the electronic apparatus of the 42nd embodiment above) used in a field of appreciation in which an image to be provided for appreciation is imaged, a field of traffic, a field of home electric appliances, a field of medical and healthcare, a field of security, a field of beauty, a field of sports, a field of agriculture, and the like.

Specifically, in the field of appreciation, for example, the solid-state image pickup device of any one of the first to fifth embodiments can be used as a device for imaging an image to be provided for appreciation, such as a digital camera, a smartphone, and a mobile phone with a camera function.

In the field of traffic, for example, the solid-state image pickup device of any one of the first to 41st embodiments can be used as a device used for traffic, such as an in-vehicle sensor that images of the front, rear, surroundings, inside, and the like of an automobile for safe driving such as automatic stop, recognition of a driver's condition, and the like, a monitoring camera that monitors traveling vehicles and roads, and a distance measuring sensor that measures a distance between vehicles and the like.

In the field of home electric appliances, for example, the solid-state image pickup device of any one of the first to 41st embodiments can be used in a device provided for home electric appliances, such as a television receiver, a refrigerator, and an air conditioner, in order to image a gesture of a user and operate a device according to the gesture.

In the field of medical and healthcare, for example, the solid-state image pickup device of any one of the first to 41st embodiments can be used in a device to be provided for medical and healthcare, such as an endoscope and a device that performs angiography by receiving infrared light.

In the field of security, for example, the solid-state imaging element of any one of the first to 41st embodiments can be used in a device to be provided for security, such as a surveillance camera for crime prevention, a camera for person authentication, and the like.

In the field of beauty, for example, the solid-state image pickup device of any one of the first to 41st embodiments can be used in a device to be provided for beauty, such as a skin measuring instrument for imaging skin and a microscope for imaging a scalp.

In the field of sports, for example, the solid-state image pickup device of any one of the first to 41st embodiments can be used in a device to be provided for sports, such as an action camera and a wearable camera for sports.

In the field of agriculture, for example, the solid-state image pickup device of any one of the first to 41st embodiments can be used in a device to be provided for agriculture, such as a camera for monitoring the condition of fields and crops.

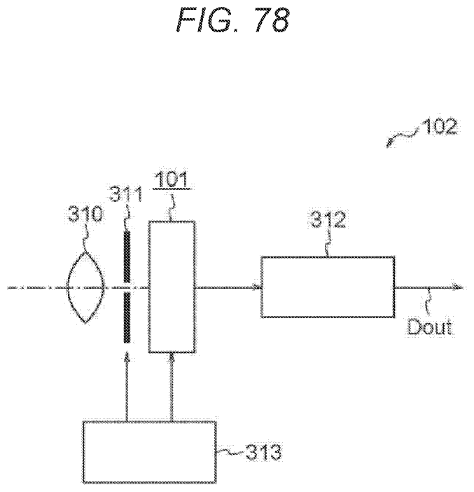

Next, use examples of the solid-state image pickup device of the first to 41st embodiments according to the present technology will be specifically described. For example, the solid-state image pickup device of any one of the first to 41st embodiments described above can be applied to any type of electronic apparatus having an imaging function, such as a camera system such as a digital still camera and a video camera, and a mobile phone having an imaging function, as the solid-state image pickup device 101. FIG. 78 illustrates a schematic configuration of an electronic apparatus 102 (camera) as an example. The electronic apparatus 102 is, for example, a video camera capable of imaging a still image or a moving image, and includes a solid-state image pickup device 101, an optical system (optical lens) 310, a shutter device 311, a drive unit 313 that drives the solid-state image pickup device 101 and the shutter device 311, and a signal processing unit 312.

The optical system 310 guides image light (incident light) from a subject to the pixel unit 101a of the solid-state image pickup device 101. The optical system 310 can include a plurality of optical lenses. The shutter device 311 controls a light irradiation period and a light shielding period for the solid-state image pickup device 101. The drive unit 313 controls a transfer operation of the solid-state image pickup device 101 and a shutter operation of the shutter device 311. The signal processing unit 312 performs various types of signal processing on a signal output from the solid-state image pickup device 101. The video signal Dout after the signal processing is stored in a storage medium such as a memory or output to a monitor or the like.

<48. Another Use Example of Solid-State Image Pickup Device to which Present Technology is Applied>

The solid-state image pickup device of any one of the first to 41st embodiments according to the present technology can also be applied to, for example, another electronic apparatus that detects light, such as a time of flight (TOF) sensor. In a case of application to a TOF sensor, for example, the solid-state image pickup device can be applied to a distance image sensor based on a direct TOF measurement method and a distance image sensor based on an indirect TOF measurement method. In the distance image sensor based on a direct TOF measurement method, the arrival timing of the photon is directly obtained in the time domain in each pixel, thus a light pulse having a short pulse width is sent, and an electrical pulse is produced by a receiver that responds at a high speed. The present disclosure can be applied to a receiver at that time. Furthermore, in an indirect TOF method, the flight time of light is measured using a semiconductor element structure in which the detection and accumulation amount of carriers generated by light change depending on the arrival timing of light. The present disclosure can also be applied as such a semiconductor structure. In the case of application to the TOF sensor, it is optional to provide the first insulating layer, the second insulating layer, the color filter layer, the lens layer, and the logic substrate as illustrated in FIG. 4 and the like, and these need not be provided.

<49. Application Example to Movable Object>

The technology according to the present disclosure (present technology) can be applied to various products. For example, the technology according to the present disclosure can be realized as a device mounted on any type of movable object such as an automobile, an electric vehicle, a hybrid electric vehicle, a motorcycle, a bicycle, a personal mobility, an airplane, a drone, a ship, and a robot.

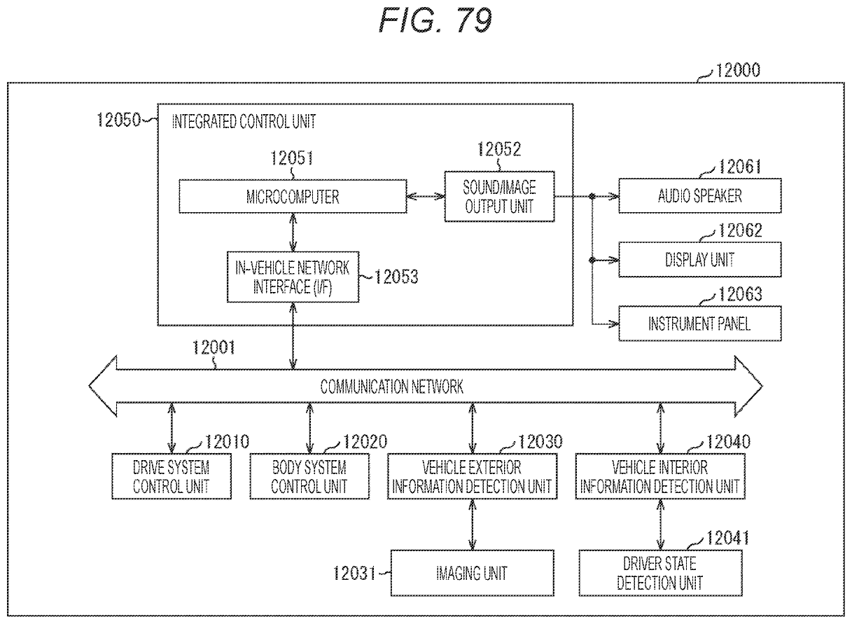

FIG. 79 is a block diagram illustrating a schematic configuration example of a vehicle control system which is an example of a movable object control system to which the technology according to the present disclosure can be applied.

The vehicle control system 12000 includes a plurality of electronic control units connected via a communication network 12001. In the example illustrated in FIG. 79, the vehicle control system 12000 includes a drive system control unit 12010, a body system control unit 12020, a vehicle exterior information detection unit 12030, a vehicle interior information detection unit 12040, and an integrated control unit 12050. Furthermore, as a functional configuration of the integrated control unit 12050, a microcomputer 12051, a sound/image output unit 12052, and an in-vehicle network interface (I/F) 12053 are illustrated.

The drive system control unit 12010 controls the operation of devices related to the drive system of the vehicle according to various programs. For example, the drive system control unit 12010 functions as a control device of a driving force generation device for generating a driving force of the vehicle such as an internal combustion engine and a driving motor, a driving force transferring mechanism for transferring the driving force to wheels, a steering mechanism for adjusting a steering angle of the vehicle, a braking device for generating a braking force of the vehicle, and the like.

The body system control unit 12020 controls operations of various devices mounted on the vehicle body according to various programs. For example, the body system control unit 12020 functions as a control device of a keyless entry system, a smart key system, a power window device, or various lamps such as a head lamp, a back lamp, a brake lamp, a blinker, and a fog lamp. In this case, radio waves submitted from a portable device that substitutes for a key or signals of various switches can be input to the body system control unit 12020. The body system control unit 12020 receives input of these radio waves or signals, and controls a door lock device, a power window device, a lamp, and the like of the vehicle.

The vehicle exterior information detection unit 12030 detects information outside the vehicle on which the vehicle control system 12000 is mounted. For example, an imaging unit 12031 is connected to the vehicle exterior information detection unit 12030. The vehicle exterior information detection unit 12030 makes the imaging unit 12031 image an image of the outside of the vehicle, and receives the imaged image. The vehicle exterior information detection unit 12030 can perform object detection processing or distance detection processing of a person, a vehicle, an obstacle, a sign, a character on a road surface, or the like on the basis of the received image.

The imaging unit 12031 is an optical sensor that receives light and outputs an electrical signal corresponding to the amount of received light. The imaging unit 12031 can output the electric signal as an image or can output the electrical signal as distance measurement information. Furthermore, the light received by the imaging unit 12031 can be visible light or invisible light such as infrared rays.

The vehicle interior information detection unit 12040 detects information inside the vehicle. For example, a driver state detection unit 12041 that detects a state of a driver is connected to the vehicle interior information detection unit 12040. The driver state detection unit 12041 includes, for example, a camera that images the driver, and the vehicle interior information detection unit 12040 can calculate the degree of fatigue or the degree of concentration of the driver or can determine whether or not the driver is dozing off on the basis of the detection information input from the driver state detection unit 12041.

The microcomputer 12051 can calculate a control target value of the driving force generation device, the steering mechanism, or the braking device on the basis of the information inside and outside the vehicle acquired by the vehicle exterior information detection unit 12030 or the vehicle interior information detection unit 12040, and output a control command to the drive system control unit 12010. For example, the microcomputer 12051 can perform cooperative control for the purpose of implementing functions of an Advanced Driver Assistance System (ADAS) including collision avoidance or impact mitigation of the vehicle, follow-up traveling based on an inter-vehicle distance, vehicle speed maintained traveling, vehicle collision warning, vehicle lane departure warning, or the like.

Furthermore, the microcomputer 12051 can perform cooperative control for the purpose of automatic driving or the like in which the vehicle autonomously travels without depending on the operation of the driver by controlling the driving force generation device, the steering mechanism, the braking device, or the like on the basis of the information around the vehicle acquired by the vehicle exterior information detection unit 12030 or the vehicle interior information detection unit 12040.

Furthermore, the microcomputer 12051 can output a control command to the body system control unit 12020 on the basis of the vehicle exterior information acquired by the vehicle exterior information detection unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound/image output unit 12052 sends an output signal of at least one of a sound or an image to an output device capable of visually or audibly notifying an occupant of the vehicle or the outside of the vehicle of information. In the example of FIG. 79, an audio speaker 12061, a display unit 12062, and an instrument panel 12063 are illustrated as an output device. The display unit 12062 can include, for example, at least one of an on-board display or a head-up display.

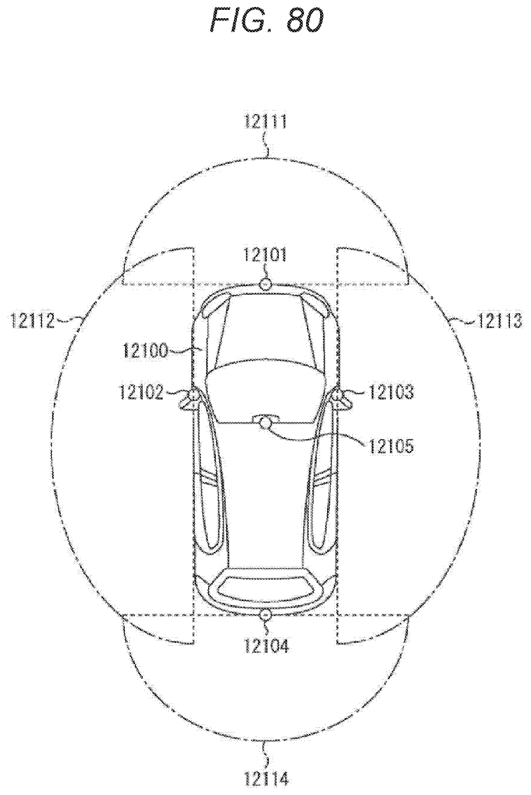

FIG. 80 is a diagram illustrating an example of an installation position of the imaging unit 12031.

In FIG. 80, the vehicle 12100 has imaging units 12101, 12102, 12103, 12104, and 12105 as the imaging unit 12031.

The imaging units 12101, 12102, 12103, 12104, and 12105 are provided, for example, at positions such as a front nose, a side mirror, a rear bumper, a back door, and an upper part of a windshield in a vehicle interior of the vehicle 12100. The imaging unit 12101 provided at the front nose and the imaging unit 12105 provided at the upper part of the windshield in the vehicle interior mainly acquire images in front of the vehicle 12100. The imaging units 12102 and 12103 provided at the side mirrors mainly acquire images of the side part of the vehicle 12100. The imaging unit 12104 provided on the rear bumper or the back door mainly acquires an image behind the vehicle 12100. The front images acquired by the imaging units 12101 and 12105 are mainly used for detecting a preceding vehicle, a pedestrian, an obstacle, a traffic light, a traffic sign, a lane, or the like.

Note that FIG. 80 illustrates an example of imaging ranges of the imaging units 12101 to 12104. An imaging range 12111 indicates an imaging range of the imaging unit 12101 provided at the front nose, imaging ranges 12112 and 12113 indicate imaging ranges of the imaging units 12102 and 12103 provided at the side mirrors, respectively, and an imaging range 12114 indicates an imaging range of the imaging unit 12104 provided at the rear bumper or the back door. For example, by superimposing image data imaged by the imaging units 12101 to 12104, an overhead view image of the vehicle 12100 viewed from above is obtained.

At least one of the imaging units 12101 to 12104 can have a function of acquiring distance information. For example, at least one of the imaging units 12101 to 12104 can be a stereo camera including a plurality of imaging elements, or can be an imaging element having pixels for phase difference detection.

For example, the microcomputer 12051 can extract, as a preceding vehicle, a three-dimensional object traveling at a predetermined speed (for example, 0 km/h or more) in substantially the same direction as the vehicle 12100, in particular, the closest three-dimensional object on a traveling path of the vehicle 12100 by obtaining a distance to each three-dimensional object in the imaging ranges 12111 to 12114 and a temporal change of the distance (relative speed with respect to the vehicle 12100) on the basis of the distance information obtained from the imaging units 12101 to 12104. Moreover, the microcomputer 12051 can set an inter-vehicle distance to be secured in advance in front of the preceding vehicle, and can perform automatic brake control (including follow-up stop control), automatic acceleration control (including follow-up start control), and the like. As described above, it is possible to perform cooperative control for the purpose of automatic driving or the like in which the vehicle autonomously travels without depending on the operation of the driver.

For example, the microcomputer 12051 can classify three-dimensional object data regarding three-dimensional objects into two-wheeled vehicles, ordinary vehicles, large vehicles, pedestrians, and other three-dimensional objects such as utility poles on the basis of the distance information obtained from the imaging units 12101 to 12104, extract the classified data, and use it for automatic avoidance of obstacles. For example, the microcomputer 12051 identifies obstacles around the vehicle 12100 as obstacles that can be visually recognized by the driver of the vehicle 12100 and obstacles that cannot be visually recognized. Then, the microcomputer 12051 determines a collision risk indicating a risk of collision with each obstacle, and in the case where the collision risk is not less than the set value and thus there is a possibility of collision, the microcomputer can perform driving assistance for collision avoidance by outputting an alarm to the driver via the audio speaker 12061 or the display unit 12062 or performing forced deceleration or avoidance steering via the drive system control unit 12010.

At least one of the imaging units 12101 to 12104 can be an infrared camera that detects infrared rays. For example, the microcomputer 12051 can recognize a pedestrian by determining whether or not a pedestrian is present in the imaged images of the imaging units 12101 to 12104. Such pedestrian recognition is performed by, for example, a procedure of extracting feature points in the imaged images of the imaging units 12101 to 12104 as infrared cameras and a procedure of performing pattern matching processing on a series of feature points indicating the outline of an object to determine whether or not the object is a pedestrian. If the microcomputer 12051 determines that a pedestrian is present in the imaged images of the imaging units 12101 to 12104 and recognizes the pedestrian, the sound/image output unit 12052 causes the display unit 12062 to superimpose and display a square contour line for emphasis on the recognized pedestrian. Furthermore, the sound/image output unit 12052 can cause the display unit 12062 to display an icon or the like indicating a pedestrian at a desired position.

An example of the vehicle control system to which the technology according to the present disclosure (present technology) can be applied has been described above. The technology according to the present disclosure can be applied to, for example, the imaging unit 12031 and the like among the configurations described above. Specifically, the solid-state image pickup device 111 of the present disclosure can be applied to the imaging unit 12031. By applying the technology according to the present disclosure to the imaging unit 12031, it is possible to improve the yield and reduce the manufacturing cost.

<50. Application Example to Endoscopic Surgery System>

The present technology can be applied to various products. For example, the technology according to the present disclosure (the present technology) can be applied to an endoscopic surgery system.

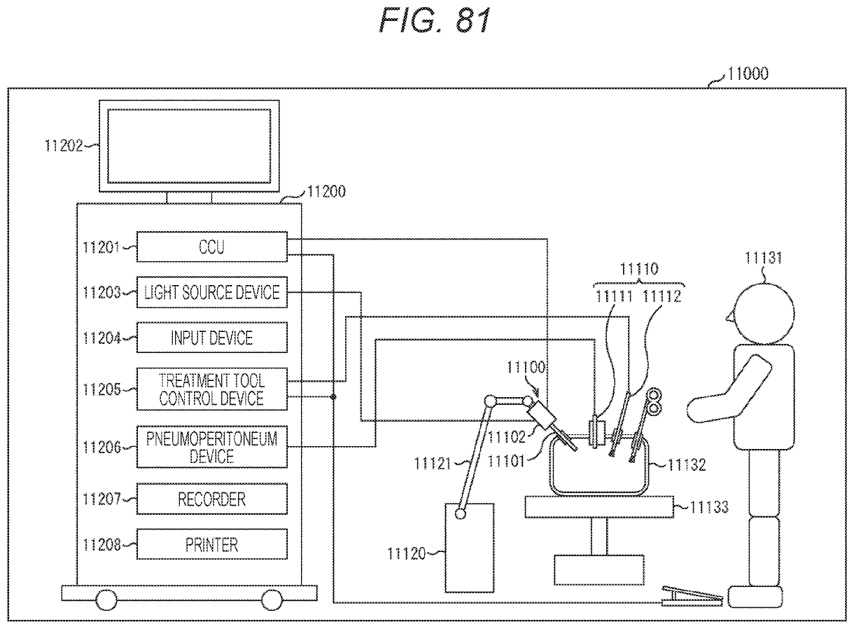

FIG. 81 is a diagram illustrating an example of a schematic configuration of an endoscopic surgery system to which the technology according to the present disclosure (the present technology) can be applied.

FIG. 81 illustrates a state in which an operator (doctor) 11131 is performing surgery on a patient 11132 on a patient bed 11133 using an endoscopic surgery system 11000. As illustrated, the endoscopic surgery system 11000 includes an endoscope 11100, other surgical tools 11110 such as a pneumoperitoneum tube 11111 and an energy treatment tool 11112, a support arm device 11120 that supports the endoscope 11100, and a cart 11200 on which various devices for endoscopic surgery are mounted.

The endoscope 11100 includes a lens barrel 11101 whose region of a predetermined length from the tip is inserted into the body cavity of the patient 11132, and a camera head 11102 that is connected to the base end of the lens barrel 11101. In the illustrated example, although the endoscope 11100 configured as a so-called rigid scope having the rigid lens barrel 11101 is illustrated, the endoscope 11100 can be configured as a so-called flexible scope having a flexible lens barrel.

An opening part into which an objective lens is fitted is provided at the tip of the lens barrel 11101. A light source device 11203 is connected to the endoscope 11100, and light produced by the light source device 11203 is guided to the tip of the lens barrel by a light guide that is provided to extend inside the lens barrel 11101, and is emitted toward an observation target in the body cavity of the patient 11132 via the objective lens. Note that the endoscope 11100 can be a forward-viewing endoscope, an oblique-viewing endoscope, or a side-viewing endoscope.

An optical system and an imaging element are provided inside the camera head 11102, and reflected light (observation light) from the observation target is condensed on the imaging element by the optical system. The observation light is photoelectrically converted by the imaging element, and an electrical signal corresponding to the observation light, that is, an image signal corresponding to the observation image is produced. The image signal is sent to a camera control unit (CCU) 11201 as RAW data.

The CCU 11201 includes a Central Processing Unit (CPU), a Graphics Processing Unit (GPU), and the like, and integrally controls operation of the endoscope 11100 and the display device 11202. Moreover, the CCU 11201 receives an image signal from the camera head 11102, and performs various types of image processing for displaying an image based on the image signal, such as, for example, development processing (demosaic processing), on the image signal.

The display device 11202 displays an image based on the image signal subjected to the image processing by the CCU 11201 under the control of the CCU 11201.

The light source device 11203 includes a light source such as a Light Emitting Diode (LED), for example, and supplies irradiation light for imaging a surgical site or the like to the endoscope 11100.

An input device 11204 is an input interface for the endoscopic surgery system 11000. The user can input various types of information and instructions to the endoscopic surgery system 11000 via the input device 11204. For example, the user inputs an instruction or the like to change imaging conditions (type, magnification, focal length, and the like of irradiation light) by the endoscope 11100.

A treatment tool control device 11205 controls driving of the energy treatment tool 11112 for cauterization and incision of tissue, sealing of a blood vessel, or the like. A pneumoperitoneum device 11206 feeds gas into the body cavity of the patient 11132 via the pneumoperitoneum tube 11111 in order to inflate the body cavity for the purpose of securing a visual field for the endoscope 11100 and securing a working space of the operator. A recorder 11207 is a device capable of recording various types of information regarding surgery. A printer 11208 is a device capable of printing various types of information regarding surgery in various formats such as text, image, and graph.

Note that the light source device 11203 that supplies the endoscope 11100 with the irradiation light at the time of imaging the surgical site can include, for example, an LED, a laser light source, or a white light source including a combination thereof. In a case where the white light source includes a combination of RGB laser light sources, the output intensity and the output timing of each color (each wavelength) can be controlled with high accuracy, and thus adjustment of the white balance of the imaged image can be performed in the light source device 11203. Furthermore, in this case, by irradiating the observation target with the laser light from each of the RGB laser light sources in a time division manner and controlling the driving of the imaging element of the camera head 11102 in synchronization with the irradiation timing, it is also possible to image an image corresponding to each of RGB in a time division manner. According to this method, a color image can be obtained without providing a color filter in the imaging element.

Furthermore, the driving of the light source device 11203 can be controlled to change the intensity of light to be output every predetermined time. By controlling the driving of the imaging element of the camera head 11102 in synchronization with the timing of the change of the intensity of the light to acquire images in a time division manner and synthesizing the images, it is possible to produce an image of a high dynamic range without a so-called block spot or white spot.

Furthermore, the light source device 11203 can be configured to be capable of supplying light in a predetermined wavelength band corresponding to special light observation. In the special light observation, for example, so-called narrow band imaging is performed in which a predetermined tissue such as a blood vessel in a mucosal surface layer is imaged with high contrast by emitting light in a narrower band than irradiation light (that is, white light) at the time of normal observation using wavelength dependency of light absorption in a body tissue. Alternatively, in the special light observation, fluorescence observation in which an image is obtained by fluorescence generated by irradiation with excitation light can be performed. In the fluorescence observation, it is possible to irradiate a body tissue with excitation light to observe fluorescence from the body tissue (autofluorescence observation), or to locally inject a reagent such as indocyanine green (ICG) into a body tissue and irradiate the body tissue with excitation light corresponding to a fluorescence wavelength of the reagent to obtain a fluorescent image, for example. The light source device 11203 can be configured to be capable of supplying narrow band light and/or excitation light corresponding to such special light observation.

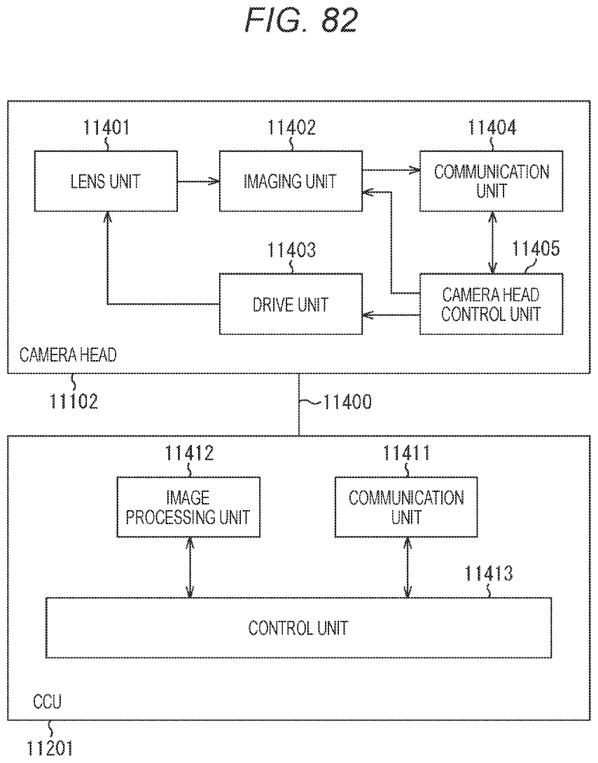

FIG. 82 is a block diagram illustrating an example of functional configurations of the camera head 11102 and the CCU 11201 illustrated in FIG. 81.

The camera head 11102 has a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicably connected to each other by a transmission cable 11400.

The lens unit 11401 is an optical system provided at a connecting part with the lens barrel 11101. Observation light taken in from the tip of the lens barrel 11101 is guided to the camera head 11102 and enters the lens unit 11401. The lens unit 11401 is configured by combining a plurality of lenses including a zoom lens and a focus lens.

The imaging unit 11402 includes an imaging element. The number of imaging elements that constitute the imaging unit 11402 can be one (so-called single-plate type) or more than one (so-called multi-plate type). In a case where the imaging unit 11402 is configured as a multi-plate type, a color image can be obtained by, for example, an image signal corresponding to each of RGB being produced by each imaging element and being synthesized. Alternatively, the imaging unit 11402 can be configured to have a pair of imaging elements for acquiring right-eye and left-eye image signals corresponding to Three-Dimensional (3D) display. By performing the 3D display, the operator 11131 can more accurately grasp the depth of the living tissue in the surgical site. Note that, in a case where the imaging unit 11402 is configured as a multi-plate type, a plurality of lens units 11401 can be provided corresponding to each imaging element.

Furthermore, the imaging unit 11402 need not necessarily be provided in the camera head 11102. For example, the imaging unit 11402 can be provided immediately after the objective lens inside the lens barrel 11101.

The drive unit 11403 includes an actuator, and moves the zoom lens and the focus lens of the lens unit 11401 by a predetermined distance along the optical axis under the control of the camera head control unit 11405. Therefore, the magnification and focus of the image imaged by the imaging unit 11402 can be appropriately adjusted.

The communication unit 11404 includes a communication device for sending and receiving various types of information to and from the CCU 11201. The communication unit 11404 sends the image signal obtained from the imaging unit 11402 to the CCU 11201 as RAW data via the transmission cable 11400.

Furthermore, the communication unit 11404 receives a control signal for controlling driving of the camera head 11102 from the CCU 11201, and supplies the control signal to the camera head control unit 11405. The control signal includes, for example, information associated with information regarding imaging conditions such as information for specifying a frame rate of an imaged image, information for specifying an exposure value at the time of imaging, and/or information for specifying a magnification and a focus of an imaged image.

Note that the imaging conditions such as the frame rate, the exposure value, the magnification, and the focus can be appropriately specified by the user, or can be automatically set by the control unit 11413 of the CCU 11201 on the basis of the acquired image signal. In the latter case, a so-called Auto Exposure (AE) function, an Auto Focus (AF) function, and an Auto White Balance (AWB) function are installed in the endoscope 11100.

The camera head control unit 11405 controls driving of the camera head 11102 on the basis of the control signal from the CCU 11201 received via the communication unit 11404.

The communication unit 11411 includes a communication device for sending and receiving various types of information to and from the camera head 11102. The communication unit 11411 receives an image signal sent from the camera head 11102 via the transmission cable 11400.

Furthermore, the communication unit 11411 sends a control signal for controlling driving of the camera head 11102 to the camera head 11102. The image signal and the control signal can be sent by electric communication, optical communication, or the like.

The image processing unit 11412 performs various types of image processing on the image signal which is RAW data sent from the camera head 11102.

The control unit 11413 performs various types of control related to imaging of a surgical site or the like by the endoscope 11100 and display of an imaged image obtained by imaging of the surgical site or the like. For example, the control unit 11413 produces a control signal for controlling driving of the camera head 11102.

Furthermore, the control unit 11413 makes the display device 11202 display an imaged image of a surgical site or the like on the basis of the image signal subjected to the image processing by the image processing unit 11412. At this time, the control unit 11413 can recognize various objects in the imaged image using various image recognition technologies. For example, the control unit 11413 can recognize a surgical tool such as forceps, a specific body part, bleeding, mist at the time of using the energy treatment tool 11112, and the like by detecting the shape, color, and the like of the edge of the object included in the imaged image. When the imaged image is displayed on the display device 11202, the control unit 11413 can superimpose and display various types of surgery support information on the image of the surgical site using the recognition result. Because the surgery support information is superimposed and displayed, and presented to the operator 11131, the burden on the operator 11131 can be reduced and the operator 11131 can reliably proceed with the surgery.

The transmission cable 11400 that connects the camera head 11102 and the CCU 11201 is an electrical signal cable compatible with electrical signal communication, an optical fiber compatible with optical communication, or a composite cable thereof.

Here, although in the illustrated example, communication is performed by wire using the transmission cable 11400, communication between the camera head 11102 and the CCU 11201 can be performed wirelessly.

An example of the endoscopic surgery system to which the technology according to the present disclosure can be applied has been described above. The technology according to the present disclosure can be applied to the endoscope 11100, (the imaging unit 11402 of) the camera head 11102, and the like among the configurations described above. Specifically, the solid-state image pickup device 111 of the present disclosure can be applied to the imaging unit 10402. By applying the technology according to the present disclosure to the endoscope 11100, (the imaging unit 11402 of) the camera head 11102, and the like, it is possible to improve the yield and reduce the cost related to manufacturing.

Here, although the endoscopic surgery system has been described as an example, the technology according to the present disclosure can be applied to others, for example, a microscopic surgery system or the like.

Furthermore, the present technology can also have the following configurations.

(1) A solid-state image pickup device, including:

at least one photoelectric converter formed in a semiconductor substrate; and

a thermal conductive layer that is arranged on one surface side and/or another surface side of the semiconductor substrate and includes a material having a thermal conductivity higher than that of SiO₂.

(2) The solid-state image pickup device according to (1), in which the thermal conductive layer has a thermal conductivity that is equal to or higher than a thermal conductivity of Si.

(3) The solid-state image pickup device according to (1) or (2), in which the at least one photoelectric converter has a PN junction.

(4) The solid-state image pickup device according to any one of (1) to (3), in which the at least one photoelectric converter has an electron multiplication region.

(5) The solid-state image pickup device according to any one of (1) to (4), in which light is incident on the at least one photoelectric converter from the one surface side, and the thermal conductive layer has a light transmission property and is arranged on the one surface side.

(6) The solid-state image pickup device according to (5), further including an insulating layer having a light transmission property on the one surface side, in which at least a part of the insulating layer is arranged between the semiconductor substrate and the thermal conductive layer.

(7) The solid-state image pickup device according to (5) or (6), in which the thermal conductive layer includes a material containing any one of indium tin oxide, SiN, Al₂O₃, ZnO—Al, AlN, SiC, fullerene, graphene, titanium oxide, MgO, and ZnO.

(8) The solid-state image pickup device according to any one of (1) to (7), in which light is incident on the at least one photoelectric converter from the one surface side, and the solid-state image pickup device further includes a logic substrate that is arranged on the another surface side and includes another semiconductor substrate.

(9) The solid-state image pickup device according to (8), in which the thermal conductive layer is arranged between the semiconductor substrate and the another semiconductor substrate.

(10) The solid-state image pickup device according to (8 or 9), in which an insulating layer is arranged between the semiconductor substrate and the another semiconductor substrate, and the thermal conductive layer is arranged in the insulating layer.

(11) The solid-state image pickup device according to any one of (1) to (10), in which the thermal conductive layer includes a carbon nanomaterial or a material containing fullerene.

(12) The solid-state image pickup device according to any one of (1) to (11), in which the thermal conductive layer includes a material containing graphene.

(13) The solid-state image pickup device according to any one of (1) to (12), in which the thermal conductive layer includes a material containing any one of Ti, Sn, Pt, Fe, Ni, Zn, Mg, Si, W, Al, Au, Cu, and Ag.

(14) The solid-state image pickup device according to any one of (1) to (13), in which the at least one photoelectric converter includes a plurality of photoelectric converters, and includes a partition wall that separates adjacent photoelectric converters of the plurality of photoelectric converters.

(15) The solid-state image pickup device according to (14), in which the partition wall is in contact with the thermal conductive layer.

(16) The solid-state image pickup device according to (14) or (15), in which the partition wall includes a material containing a metal.

(17) The solid-state image pickup device according to any one of (14) to (16), in which the partition wall penetrates the thermal conductive layer.

(18) The solid-state image pickup device according to claim 17, in which a tip of the partition wall that penetrates the thermal conductive layer is exposed to an outside.

(19) The solid-state image pickup device according to any one of (1) to (18), in which the at least one photoelectric converter includes a plurality of photoelectric converters, and the thermal conductive layer is provided to extend across at least two photoelectric converters of the plurality of photoelectric converters.

(20) The solid-state image pickup device according to any one of (1) to (19), in which the thermal conductive layer extends across the one surface side and the another surface side of the semiconductor substrate.

(21) The solid-state image pickup device according to (6), in which the thermal conductive layer constitutes at least a surface layer.

(22) The solid-state image pickup device according to (6), in which the thermal conductive layer constitutes at least an inner layer.

(23) The solid-state image pickup device according to (21), further including a lens layer immediately below the thermal conductive layer.

(24) The solid-state image pickup device according to (23), further including a color filter layer arranged between the lens layer and the insulating layer.

(25) The solid-state image pickup device according to (21), further including a color filter layer immediately below the thermal conductive layer.

(26) The solid-state image pickup device according to (22), further including a lens layer as a surface layer, in which the thermal conductive layer is arranged between the lens layer and the insulating layer.

(27) The solid-state image pickup device according to (22), further including a lens layer as a surface layer, in which the thermal conductive layer is arranged in the insulating layer.

(28) The solid-state image pickup device according to (27), in which the insulating layer is arranged immediately below the lens layer.

(29) The solid-state image pickup device according to (22), further including a color filter layer as a surface layer, in which the thermal conductive layer is arranged between the color filter layer and the insulating layer.

(30) The solid-state image pickup device according to (22), further including a color filter layer as a surface layer, in which the thermal conductive layer is arranged in the insulating layer.

(31) The solid-state image pickup device according to (22), further including: a lens layer as a surface layer; and a color filter layer arranged between the lens layer and the insulating layer, in which the thermal conductive layer is arranged between the lens layer and the color filter layer.

(32) The solid-state image pickup device according to (22), further including: a lens layer as a surface layer; and a color filter layer arranged between the lens layer and the insulating layer, in which the thermal conductive layer is arranged between the insulating layer and the color filter layer.

(33) The solid-state image pickup device according to (22), further including: a lens layer as a surface layer; and a color filter layer arranged between the lens layer and the insulating layer, in which the thermal conductive layer is arranged in the insulating layer.

(34) The solid-state image pickup device according to (21), in which the insulating layer is arranged immediately below the thermal conductive layer.

(35) The solid-state image pickup device according to (22), in which at least a part of the insulating layer is a surface layer.

(36) The solid-state image pickup device according to (35), in which the thermal conductive layer is arranged in the insulating layer.

(37) An electronic apparatus, including the solid-state image pickup device according to any one of (1) to (36).

(38) A method for manufacturing a solid-state image pickup device, including the steps of:

forming an opening in a semiconductor substrate in which a photoelectric converter is to be formed;

embedding an insulating material in a peripheral part in the opening;

arranging an insulating film on the semiconductor substrate;

forming another opening that communicates with a central part in the opening in the insulating film;

embedding a metal material in the central part in the opening and the another opening; and

arranging a thermal conductive film on a side opposite to the semiconductor substrate of the insulating film.

(39) The method for manufacturing a solid-state image pickup device according to (38), in which in the step of arranging a thermal conductive film, the thermal conductive film is arranged to be connected to the metal material embedded in the another opening directly or via another metal material.

### REFERENCE SIGNS LIST

100, 100β, 240 Semiconductor substrate
105, 105M Photoelectric converter
110d, 110d1, 110d2, 110d3, 110d4, 110d5, 110d6, 110d7, 110d8, 110d9, 110d10, 110d11, 110d12, 110d13, 110d14, 110d15, 110d16, 110d17, 110d18, 110d19, 110d20, 110d21, 250, 260, 270, 281, 282, 283, 284, 285, 286, 287, 288, 291, 292, 293, 294, 295, 296, 297, 298 Thermal conductive layer
110a, 110a1 Second insulating layer (insulating layer)
110b, 110b1 Color filter layer
110c Lens layer
120 First insulating layer (insulating layer)
120A Insulating layer
120B Insulating layer
150, 150A, 150B, 150C, 150E, 150F, 150H, 150G, 150I, 150J, 150K, 150L, 150M, 150N, 150P, 150Q, 150R, 150S, 150T, 150U, 150V, 150W, 150X, 150Y, 150Z, 150η, 150θ, 150ι, 150κ, 150σ, 150μ, 150ξ, 150ρ, 150∘, 150π, 151 Partition wall
180 Logic substrate
180b Semiconductor substrate (another semiconductor substrate)
105de Electron multiplication region
216, 216A, 216B, 216C, 216Y, 216Z Thermal conductive film.

1. A solid-state image pickup device, comprising:
at least one photoelectric converter formed in a semiconductor substrate; and
a thermal conductive layer that is arranged on one surface side and/or another surface side of the semiconductor substrate and includes a material having a thermal conductivity higher than that of SiO₂.

2. The solid-state image pickup device according to claim 1, wherein the thermal conductive layer has a thermal conductivity that is equal to or higher than a thermal conductivity of Si.

3. The solid-state image pickup device according to claim 1, wherein the at least one photoelectric converter has a PN junction.

4. The solid-state image pickup device according to claim 1, wherein the at least one photoelectric converter has an electron multiplication region.

5. The solid-state image pickup device according to claim 1, wherein
light is incident on the at least one photoelectric converter from the one surface side, and
the thermal conductive layer has a light transmission property and is arranged on the one surface side.

6. The solid-state image pickup device according to claim 5, further comprising
an insulating layer having a light transmission property on the one surface side,
wherein at least a part of the insulating layer is arranged between the semiconductor substrate and the thermal conductive layer.

7. The solid-state image pickup device according to claim 5, wherein the thermal conductive layer includes a material containing any one of indium tin oxide, SiN, Al₂O₃, ZnO—Al, AlN, SiC, fullerene, graphene, titanium oxide, MgO, and ZnO.

8. The solid-state image pickup device according to claim 1, wherein
light is incident on the at least one photoelectric converter from the one surface side, and
the solid-state image pickup device further comprises a logic substrate that is arranged on the another surface side and includes another semiconductor substrate.

9. The solid-state image pickup device according to claim 8, wherein the thermal conductive layer is arranged between the semiconductor substrate and the another semiconductor substrate.

10. The solid-state image pickup device according to claim 9, wherein
an insulating layer is arranged between the semiconductor substrate and the another semiconductor substrate, and
the thermal conductive layer is arranged in the insulating layer.

11. The solid-state image pickup device according to claim 1, wherein the thermal conductive layer includes a carbon nanomaterial or a material containing fullerene.

12. The solid-state image pickup device according to claim 11, wherein the thermal conductive layer includes a material containing graphene.

13. The solid-state image pickup device according to claim 1, wherein the thermal conductive layer includes a material containing any one of Ti, Sn, Pt, Fe, Ni, Zn, Mg, Si, W, Al, Au, Cu, and Ag.

14. The solid-state image pickup device according to claim 1, wherein the at least one photoelectric converter includes a plurality of photoelectric converters, and includes a partition wall that separates adjacent photoelectric converters of the plurality of photoelectric converters.

15. The solid-state image pickup device according to claim 14, wherein the partition wall is in contact with the thermal conductive layer.

16. The solid-state image pickup device according to claim 14, wherein the partition wall includes a material containing a metal.

17. The solid-state image pickup device according to claim 15, wherein the partition wall penetrates the thermal conductive layer.

18. The solid-state image pickup device according to claim 17, wherein a tip of the partition wall that penetrates the thermal conductive layer is exposed to an outside.

19. The solid-state image pickup device according to claim 1, wherein
the at least one photoelectric converter includes a plurality of photoelectric converters, and
the thermal conductive layer is provided to extend across at least two photoelectric converters of the plurality of photoelectric converters.

20. The solid-state image pickup device according to claim 1, wherein the thermal conductive layer extends across the one surface side and the another surface side of the semiconductor substrate.

21. The solid-state image pickup device according to claim 6, wherein the thermal conductive layer constitutes at least a surface layer.

22. The solid-state image pickup device according to claim 6, wherein the thermal conductive layer constitutes at least an inner layer.

23. The solid-state image pickup device according to claim 21, further comprising a lens layer immediately below the thermal conductive layer.

24. The solid-state image pickup device according to claim 23, further comprising a color filter layer arranged between the lens layer and the insulating layer.

25. The solid-state image pickup device according to claim 21, further comprising a color filter layer immediately below the thermal conductive layer.

26. The solid-state image pickup device according to claim 22, further comprising
a lens layer as a surface layer,
wherein the thermal conductive layer is arranged between the lens layer and the insulating layer.

27. The solid-state image pickup device according to claim 22, further comprising
a lens layer as a surface layer,
wherein the thermal conductive layer is arranged in the insulating layer.

28. The solid-state image pickup device according to claim 27, wherein the insulating layer is arranged immediately below the lens layer.

29. The solid-state image pickup device according to claim 22, further comprising
a color filter layer as a surface layer,
wherein the thermal conductive layer is arranged between the color filter layer and the insulating layer.

30. The solid-state image pickup device according to claim 22, further comprising
a color filter layer as a surface layer,
wherein the thermal conductive layer is arranged in the insulating layer.

31. The solid-state image pickup device according to claim 22, further comprising:
a lens layer as a surface layer; and
a color filter layer arranged between the lens layer and the insulating layer,
wherein the thermal conductive layer is arranged between the lens layer and the color filter layer.

32. The solid-state image pickup device according to claim 22, further comprising:
a lens layer as a surface layer; and
a color filter layer arranged between the lens layer and the insulating layer,
wherein the thermal conductive layer is arranged between the insulating layer and the color filter layer.

33. The solid-state image pickup device according to claim 22, further comprising:
a lens layer as a surface layer; and
a color filter layer arranged between the lens layer and the insulating layer,
wherein the thermal conductive layer is arranged in the insulating layer.

34. The solid-state image pickup device according to claim 21, wherein the insulating layer is arranged immediately below the thermal conductive layer.

35. The solid-state image pickup device according to claim 22, wherein at least a part of the insulating layer is a surface layer.

36. The solid-state image pickup device according to claim 35, wherein the thermal conductive layer is arranged in the insulating layer.

37. An electronic apparatus, comprising the solid-state image pickup device according to claim 1.

38. A method for manufacturing a solid-state image pickup device, comprising the steps of:
forming an opening in a semiconductor substrate in which a photoelectric converter is to be formed;
embedding an insulating material in a peripheral part in the opening;
arranging an insulating film on the semiconductor substrate;
forming another opening that communicates with a central part in the opening in the insulating film;
embedding a metal material in the central part in the opening and the another opening; and
arranging a thermal conductive film on a side opposite to the semiconductor substrate of the insulating film.

39. The method for manufacturing a solid-state image pickup device according to claim 38, wherein in the step of arranging a thermal conductive film, the thermal conductive film is arranged to be connected to the metal material embedded in the another opening directly or via another metal material.
